(19) United States
(12) Patent Application Publication
(10) Pub. No.: US 2026/0033005 A1
(43) Pub. Date: Jan. 29, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Masami JINTYOU, Shimotsuga, Tochigi (JP); Junichi KOEZUKA, Tochigi, Tochigi (JP); Masataka NAKADA, Tochigi, Tochigi (JP); Yukinori SHIMA, Tatebayashi, Gunma (JP); Masakatsu OHNO, Utsunomiya, Tochigi (JP); Masayoshi DOBASHI, Shimotsuga, Tochigi (JP)

(21) Appl. No.: 18/995,208

(22) PCT Filed: Jul. 10, 2023
(86) PCT No.: PCT/IB2023/057049

§ 371 Date: Jan. 16, 2025

(30) Foreign Application Priority Data
Jul. 22, 2022 (JP) 2022-117419

(51) Int. Cl. H10D 86/40

(52) U.S. Cl. CPC H10D 86/451; H10D 86/421

(57) ABSTRACT

A semiconductor device that has both low power consumption and high performance is provided. The semiconductor device includes a first and second transistors. The first transistor includes a first conductive layer, a first insulating layer over the first conductive layer, a second conductive layer over the first insulating layer, a second insulating layer over the second conductive layer, a third insulating layer over the second insulating layer, a third conductive layer over the third insulating layer, and a first semiconductor layer. The second conductive layer includes a first opening reaching the first insulating layer in a region overlapping with the first conductive layer. The first to third insulating layers and the third conductive layer include a second opening reaching the first conductive layer in a region overlapping with the first opening. The first semiconductor layer is in contact with a top surface of the first conductive layer, a side surface of the first insulating layer, a side surface of the second insulating layer, a side surface of the third insulating layer, and a top surface and a side surface of the third conductive layer. The second transistor includes a fourth conductive layer, the first to third insulating layers over the fourth conductive layer, and a second semiconductor layer over the third insulating layer.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device including a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

Note that in this specification and the like, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display device, a light-emitting apparatus, a lighting device, and an electronic device themselves are semiconductor devices and each of them includes a semiconductor device in some cases.

### BACKGROUND ART

Semiconductor devices that include transistors are applied to a wide range of electronic devices. In a display device, for example, when the area occupied by transistors is reduced, the pixel size can be reduced and the resolution can be increased. Thus, minute transistors have been required.

As devices requiring high-resolution display devices, for example, devices for virtual reality (VR), augmented reality (AR), substitutional reality (SR), or mixed reality (MR) have been actively developed.

As a display device, a light-emitting apparatus including an organic EL (Electro Luminescence) element or a light-emitting diode (LED) has been developed.

Patent Document 1 discloses a high-resolution display device using an organic EL element.

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a semiconductor device including a transistor having a minute size. Another object is to provide a semiconductor device including a transistor having a short channel length. Another object is to provide a semiconductor device including a transistor having a high on-state current. Another object is to provide a semiconductor device including a transistor having a low cutoff current. Another object is to provide a semiconductor device including a highly reliable transistor. Another object is to provide a semiconductor device including a transistor having favorable electrical characteristics. Another object is to provide a semiconductor device that occupies a small area.

Another object of one embodiment of the present invention is to provide a high-performance semiconductor device. Another object is to provide a semiconductor device with low power consumption. Another object is to provide a highly reliable semiconductor device. Another object is to provide a semiconductor device with high productivity. Another object is to provide a novel semiconductor device.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a semiconductor device including a first transistor, a second transistor, and a substrate. The first transistor includes a first conductive layer over the substrate, a first insulating layer over the first conductive layer, a second conductive layer over the first insulating layer, a second insulating layer over the second conductive layer, a third insulating layer over the second insulating layer, a third conductive layer over the third insulating layer, and a first semiconductor layer. The second conductive layer includes a first opening reaching the first insulating layer in a region overlapping with the first conductive layer. The second insulating layer is in contact with a top surface and a side surface of the second conductive layer and a top surface of the first insulating layer. The first insulating layer, the second insulating layer, the third insulating layer, and the third conductive layer include a second opening reaching the first conductive layer in a region overlapping with the first opening. In the second opening, the first semiconductor layer is in contact with a top surface of the first conductive layer, a side surface of the first insulating layer, a side surface of the second insulating layer, a side surface of the third insulating layer, and a top surface and a side surface of the third conductive layer. The second transistor includes a fourth conductive layer over the substrate, the first insulating layer over the fourth conductive layer, the second insulating layer over the first insulating layer, the third insulating layer over the second insulating layer, and a second semiconductor layer over the third insulating layer. The second semiconductor layer includes a region overlapping with the fourth conductive layer with the first insulating layer, the second insulating layer, and the third insulating layer therebetween.

In the above-described semiconductor device, the first conductive layer and the fourth conductive layer preferably include the same material.

One embodiment of the present invention is a semiconductor device including a first transistor, a second transistor, and a substrate. The first transistor includes a first conductive layer over the substrate, a first insulating layer over the first conductive layer, a second conductive layer over the first insulating layer, a second insulating layer over the second conductive layer, a third conductive layer over the second insulating layer, and a first semiconductor layer. The second conductive layer includes a first opening reaching the first insulating layer in a region overlapping 30) with the first conductive layer. The second insulating layer is in contact with a top surface and a side surface of the second conductive layer and a top surface of the first insulating layer. The first insulating layer, the second insulating layer, and the third conductive layer include a second opening reaching the first conductive layer in a region overlapping with the first opening. In the second opening, the first semiconductor layer is in contact with a top surface of the first conductive layer, a side surface of the first insulating layer, a side surface of the second insulating layer, and a top surface and a side surface of the third conductive layer. The second transistor includes a fourth conductive layer over the substrate, the first insulating layer over the fourth conductive layer, the second insulating layer over the first insulating layer, a third insulating layer over the second insulating layer, and a second semiconductor layer over the third insulating layer. An end portion of the second semiconductor layer is in contact with a top surface of the third insulating layer. The second semiconductor layer includes a region overlapping with the fourth conductive layer with the first insulating layer, the second insulating layer, and the third insulating layer therebetween.

In the above-described semiconductor device, the first conductive layer and the fourth conductive layer preferably include the same material.

One embodiment of the present invention is a semiconductor device including a first transistor, a second transistor, and a substrate. The first transistor includes a first conductive layer over the substrate, a first insulating layer over the first conductive layer, a second conductive layer over the first insulating layer, a second insulating layer over the second conductive layer, a third conductive layer over the second insulating layer, a third insulating layer over the third conductive layer, and a first semiconductor layer. The second conductive layer includes a first opening 20) reaching the first insulating layer in a region overlapping with the first conductive layer. The second insulating layer is in contact with a top surface and a side surface of the second conductive layer and a top surface of the first insulating layer. The third insulating layer is in contact with a top surface and a side surface of the third conductive layer and a top surface of the second insulating layer. The first insulating layer, the second insulating layer, the third conductive layer, and the third insulating layer include a second opening reaching the first conductive layer in a region overlapping with the first opening. In the second opening, the first semiconductor layer is in contact with a top surface of the first conductive layer, a side surface of the first insulating layer, a side surface of the second insulating layer, a side surface of the third conductive layer, and a top surface and a side surface of the third insulating layer. The second transistor includes a fourth conductive layer over the substrate, the first insulating layer over the fourth conductive layer, the second insulating layer over the first insulating layer, the third insulating layer over the second insulating layer, and a second semiconductor layer over the third insulating layer. The second semiconductor layer includes a region overlapping with the fourth conductive layer with the first insulating layer, the second insulating layer, and the third insulating layer therebetween.

In the above-described semiconductor device, the first conductive layer and the fourth conductive layer include the same material.

One embodiment of the present invention is a semiconductor device including a first transistor, a second transistor, and a substrate. The first transistor includes a first conductive layer over the substrate, a first insulating layer over the first conductive layer, a second conductive layer over the first insulating layer, a second insulating layer over the second conductive layer, a third conductive layer over the second insulating layer, and a first semiconductor layer. The second conductive layer includes a first opening reaching the first insulating layer in a region overlapping with the first conductive layer. The second insulating layer is in contact with a top surface and a side surface of the second conductive layer and a top surface of the first insulating layer. The first insulating layer, the second insulating layer, and the third conductive layer include a second opening reaching the first conductive layer in a region overlapping with the first opening. In the second opening, the first semiconductor layer is in contact with a top surface of the first conductive layer, a side surface of the first insulating layer, a side surface of the second insulating layer, and a top surface and a side surface of the third conductive layer. The second transistor includes a fourth conductive layer over the first insulating layer, the second insulating layer over the fourth conductive layer, a third insulating layer over the second insulating layer, and a second semiconductor layer over the third insulating layer. An end portion of the second semiconductor layer is in contact with a top surface of the third insulating layer. The second semiconductor layer includes a region overlapping with the fourth conductive layer with the second insulating layer and the third insulating layer therebetween.

In the above-described semiconductor device, the second conductive layer and the fourth conductive layer preferably include the same material.

In the above-described semiconductor device, conductivity of the second conductive layer is preferably higher than conductivity of the first conductive layer.

In the above-described semiconductor device, each of the first semiconductor layer and the second semiconductor layer preferably includes a metal oxide.

In the above-described semiconductor device, the first semiconductor layer and the second semiconductor layer preferably include the same material.

In the above-described semiconductor device, the first semiconductor layer and the second semiconductor layer preferably include different materials from each other.

In the above-described semiconductor device, the first transistor preferably includes a fourth insulating layer and a fifth conductive layer over the fourth insulating layer. The fifth conductive layer preferably includes a region overlapping with the first semiconductor layer with the fourth insulating layer therebetween. The second transistor preferably includes the fourth insulating layer and a sixth conductive layer over the fourth insulating layer. The sixth conductive layer preferably includes a region overlapping with the second semiconductor layer with the fourth insulating layer therebetween.

In the above-described semiconductor device, the fifth conductive layer and the sixth conductive layer preferably include the same material.

### Effect of the Invention

With one embodiment of the present invention, a semiconductor device including a transistor having a minute size can be provided. A semiconductor device including a transistor having a short channel length can be provided. A semiconductor device including a transistor having a high on-state current can be provided. A semiconductor device including a transistor having a low cutoff current can be provided. A semiconductor device including a highly reliable transistor can be provided. A semiconductor device including a transistor having favorable electrical characteristics can be provided. A semiconductor device that occupies a small area can be provided. With one embodiment of the present invention, a high-performance semiconductor device can be provided. A semiconductor device with low power consumption can be provided. A highly reliable semiconductor device can be provided. A semiconductor device with high productivity can be provided. A novel semiconductor device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views illustrating the example of the semiconductor device.

FIG. 2 is a perspective view illustrating an example of a semiconductor device.

FIG. 3A and FIG. 3B are perspective views illustrating the structure example of the semiconductor device.

FIG. 4A and FIG. 4B are perspective views illustrating the structure example of the semiconductor device.

FIG. 5 is a cross-sectional view illustrating an example of a semiconductor device.

FIG. 6A is a top view illustrating an example of a semiconductor device. FIG. 6B is a cross-sectional view illustrating the example of the semiconductor device.

FIG. 7A and FIG. 7B are cross-sectional views illustrating examples of a semiconductor device.

FIG. 8A is a top view illustrating an example of a semiconductor device. FIG. 8B and FIG. 8C are cross-sectional views illustrating the example of the semiconductor device.

FIG. 9A to FIG. 9C are cross-sectional views illustrating examples of a semiconductor device.

FIG. 10A and FIG. 10B are cross-sectional views illustrating an example of a semiconductor device.

FIG. 11A and FIG. 11B are cross-sectional views illustrating examples of a semiconductor device.

FIG. 12 is a cross-sectional view illustrating an example of a semiconductor device.

FIG. 13A and FIG. 13B are cross-sectional views illustrating an example of a semiconductor device.

FIG. 14A and FIG. 14B are cross-sectional views illustrating an example of a semiconductor device.

FIG. 15A is a top view illustrating an example of a semiconductor device. FIG. 15B is a cross-sectional view illustrating the example of the semiconductor device.

FIG. 16A is a top view illustrating an example of a semiconductor device. FIG. 16B and FIG. 16C are cross-sectional views illustrating the example of the semiconductor device.

FIG. 17A is a top view illustrating an example of a semiconductor device. FIG. 17B is a cross-sectional view illustrating an example of a semiconductor device.

FIG. 18A and FIG. 18B are cross-sectional views illustrating an example of a semiconductor device.

FIG. 19A and FIG. 19B are cross-sectional views illustrating examples of a semiconductor device.

FIG. 20A is a top view illustrating an example of a semiconductor device. FIG. 20B and FIG. 20C are cross-sectional views illustrating the example of the semiconductor device.

FIG. 21A is a top view illustrating an example of a semiconductor device. FIG. 21B and FIG. 21C are cross-sectional views illustrating the example of the semiconductor device.

FIG. 22A and FIG. 22B are cross-sectional views illustrating an example of a semiconductor device.

FIG. 23A and FIG. 23B are cross-sectional views illustrating an example of a semiconductor device.

FIG. 24A and FIG. 24B are cross-sectional views illustrating an example of a semiconductor device.

FIG. 25A to FIG. 25E are cross-sectional views illustrating an example of a method for manufacturing a semiconductor device.

FIG. 26A to FIG. 26D are cross-sectional views illustrating the example of the method for manufacturing the semiconductor device.

FIG. 27A to FIG. 27C are cross-sectional views illustrating the example of the method for manufacturing the semiconductor device.

FIG. 28A to FIG. 28C are cross-sectional views illustrating the example of the method for manufacturing the semiconductor device.

FIG. 29A to FIG. 29D are cross-sectional views illustrating an example of a method for manufacturing a semiconductor device.

FIG. 30A to FIG. 30C are cross-sectional views illustrating an example of a method for manufacturing a semiconductor device.

FIG. 31A to FIG. 31C are cross-sectional views illustrating an example of a method for manufacturing a semiconductor device.

FIG. 32A and FIG. 32B are cross-sectional views illustrating the example of the method for manufacturing the semiconductor device.

FIG. 33A to FIG. 33C are cross-sectional views illustrating an example of a method for manufacturing a semiconductor device.

FIG. 34 is a cross-sectional view illustrating the example of the method for manufacturing the semiconductor device.

FIG. 35A to FIG. 35C are cross-sectional views illustrating an example of a method for manufacturing a semiconductor device.

FIG. 36A to FIG. 36C are cross-sectional views illustrating the example of the method for manufacturing the semiconductor device.

FIG. 37A to FIG. 37C are cross-sectional views illustrating the example of the method for manufacturing the semiconductor device.

FIG. 38A is a perspective view illustrating an example of a display device. FIG. 38B is a block diagram of the display device.

FIG. 39A is a circuit diagram of a latch circuit. FIG. 39B is a circuit diagram of an inverter circuit.

FIG. 40A and FIG. 40B are circuit diagrams of a pixel circuit. FIG. 40C is a cross-sectional view illustrating an example of a pixel circuit.

FIG. 41 is a cross-sectional view illustrating an example of a display device.

FIG. 42 is a cross-sectional view illustrating an example of a display device.

FIG. 43 is a cross-sectional view illustrating an example of a display device.

FIG. 44A to FIG. 44C are cross-sectional views illustrating examples of a display device.

FIG. 45 is a cross-sectional view illustrating an example of a display device.

FIG. 46 is a cross-sectional view illustrating an example of a display device.

FIG. 47 is a cross-sectional view illustrating an example of a display device.

FIG. 48A to FIG. 48F are cross-sectional views illustrating an example of a method for manufacturing a display device.

FIG. 49A to FIG. 49D are diagrams illustrating examples of electronic devices.

FIG. 50A to FIG. 50F are diagrams illustrating examples of electronic devices.

FIG. 51A to FIG. 51G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and description thereof is not repeated. The same hatching pattern is used for portions having similar functions, and the portions are not especially denoted by reference numerals in some cases. The position, size, range, or the like of each component illustrated in drawings does not represent the actual position, size, range, or the like in some cases for easy understanding. Therefore, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the SCOPE OF CLAIMS in some cases.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

A transistor is a kind of semiconductor element and can achieve a function of amplifying a current or a voltage, a switching operation for controlling conduction or non-conduction, and the like. An IGFET (Insulated Gate Field Effect Transistor) and a thin film transistor (TFT) are in the category of a transistor in this specification.

Functions of a “source” and a “drain” are sometimes replaced with each other when a transistor of opposite polarity is used or when the direction of current is changed in circuit operation, for example. Therefore, the terms “source” and “drain” can be switched in this specification.

In this specification and the like, “electrically connected” includes the case where connection is made through an “object having any electric function”. Here, there is no particular limitation on the “object having any electric function” as long as electric signals can be transmitted and received between components that are connected through the object. Examples of the “object having any electric function” include a switching element such as a transistor, a resistor, a coil, a capacitor, and other elements with a variety of functions as well as an electrode and a wiring.

Unless otherwise specified, an off-state current in this specification and the like refers to a leakage current between a source and a drain of a transistor in an off state (also referred to as a non-conduction state or a cut-off state). Unless otherwise specified, an off state refers to, in an n-channel transistor, a state where a voltage V_{gs} between its gate and source is lower than a threshold voltage Vₜₕ (in a p-channel transistor, higher than Vₜₕ).

In this specification and the like, the expression “top surface shapes are substantially the same” means that outlines of stacked layers at least partly overlap with each other. For example, the case of processing the upper layer and the lower layer with use of the same mask pattern or mask patterns that are partly the same is included. However, in some cases, the outlines do not completely overlap with each other and the upper layer is positioned inside the lower layer or the upper layer is positioned outside the lower layer: such a case is also represented by the expression “top surface shapes are substantially the same”. In the case where top surface shapes are the same or substantially the same, it can be said that end portions are aligned with each other or substantially aligned with each other”.

In this specification and the like, a tapered shape refers to such a shape that at least part of a side surface of a component is inclined with respect to a substrate surface or a formation surface. For example, the tapered shape preferably includes a region where the angle formed between the inclined side surface and the substrate surface or the formation surface (such an angle is also referred to as a taper angle) is less than 90°. Note that the side surface, the substrate surface, and the formation surface of the component are not necessarily completely flat and may be substantially flat with a slight curvature or substantially flat with slight unevenness.

In this specification and the like, a device manufactured using a metal mask or an FMM (fine metal mask, high-resolution metal mask) may be referred to as a device having an MM (metal mask) structure.

In this specification and the like, a device manufactured without using a metal mask or an FMM is sometimes referred to as a device having an MML (metal maskless) structure. In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (may be referred to as a mask layer) is positioned above at least a light-emitting layer (specifically, a layer processed into an island shape among layers included in an EL layer) and has a function of protecting the light-emitting layer in the manufacturing process.

Note that in this specification and the like, step disconnection refers to a phenomenon in which a layer, a film, or an electrode is split because of the shape of the formation surface (e.g., a step).

### Embodiment 1

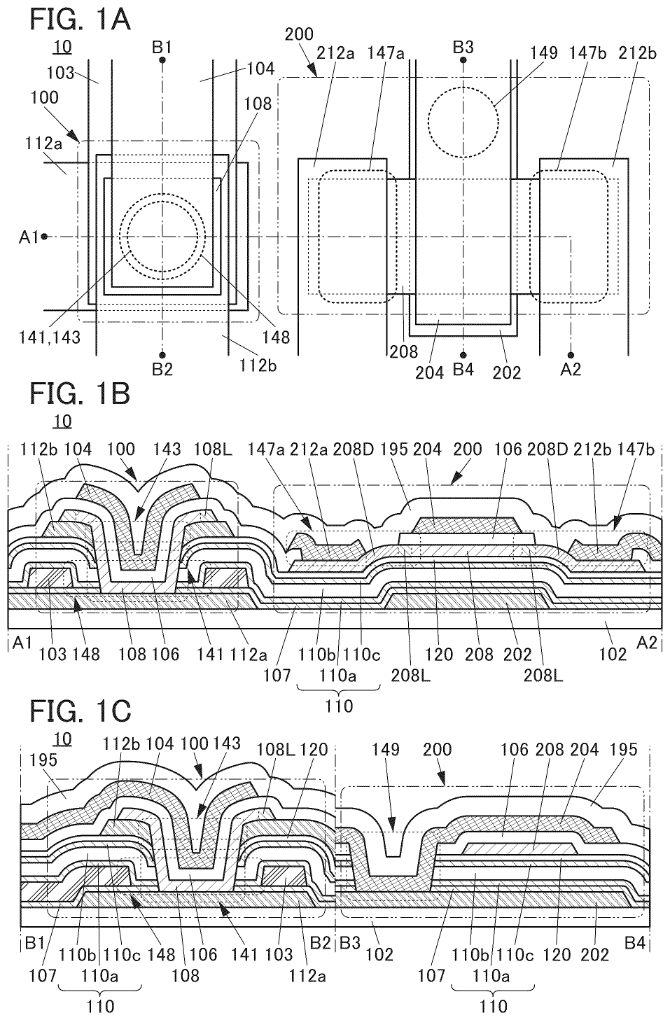

In this embodiment, semiconductor devices of embodiments of the present invention are described with reference to FIG. 1 to FIG. 24.

### Structure Example 1

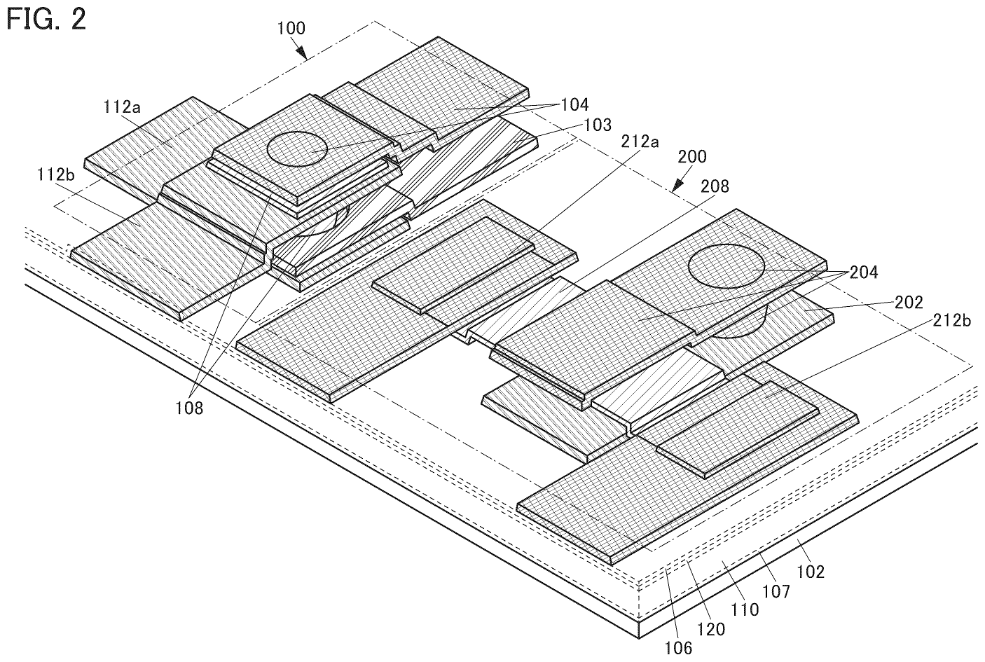

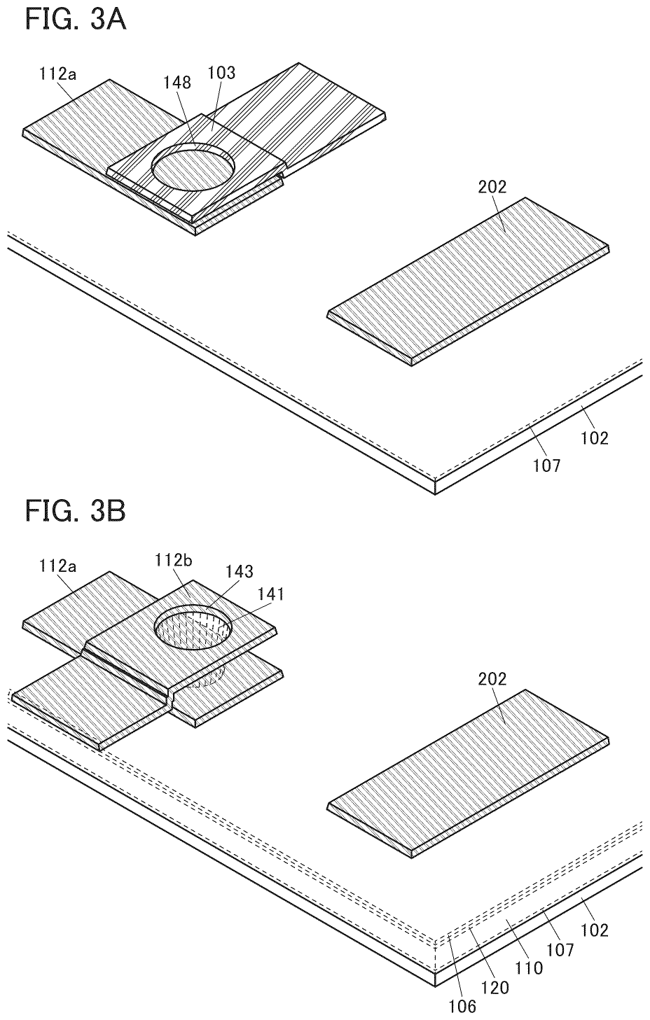

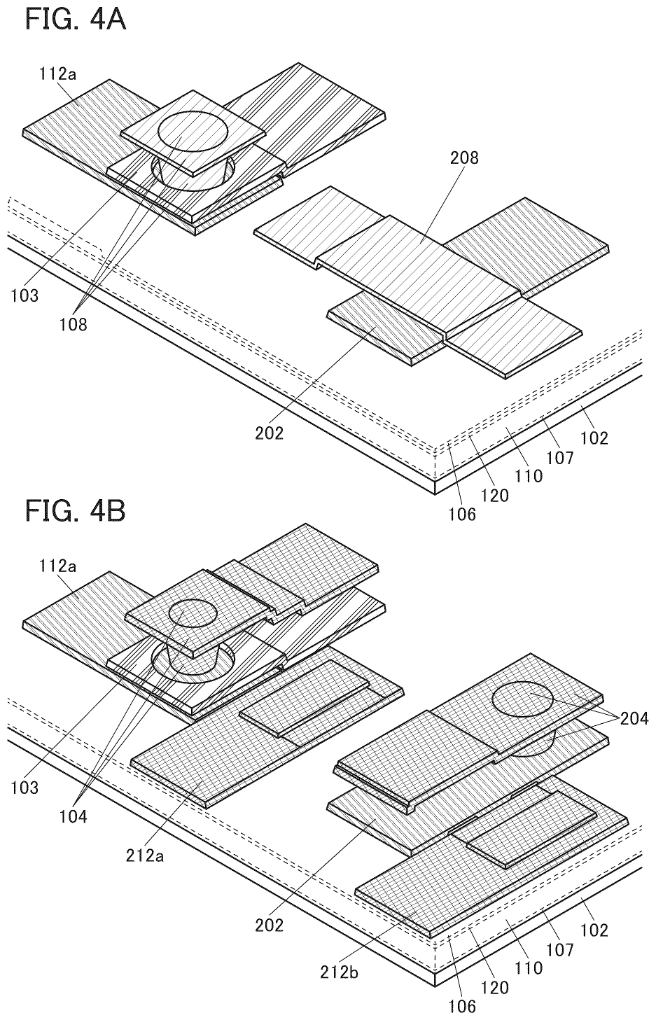

A semiconductor device of one embodiment of the present invention is described. FIG. 1A is a top view (also referred to as a plan view) of a semiconductor device 10. FIG. 1B is a cross-sectional view of a cross section along the dashed-dotted line A1-A2 in FIG. 1A, and FIG. 1C is a cross-sectional view of cross sections along the dashed-dotted line B1-B2 and the dashed-dotted line B3-B4 in FIG. 1A. FIG. 2 is a perspective view of the semiconductor device 10. FIG. 3A to FIG. 4B are perspective views illustrating some components of the semiconductor device 10. Note that in FIG. 1A, some components (e.g., an insulating layer) of the semiconductor device 10 are not illustrated. Some components are not illustrated also in the following top views of semiconductor devices, as in FIG. 1A. In FIG. 2 to FIG. 4B, insulating layers are transparent and their outlines are indicated by dashed lines.

The semiconductor device 10 includes a transistor 100 and a transistor 200. The transistor 100 and the transistor 200 have different structures and are each provided over a substrate 102. Some of the formation steps of the transistor 100 can be the same as some of the formation steps of the transistor 200.

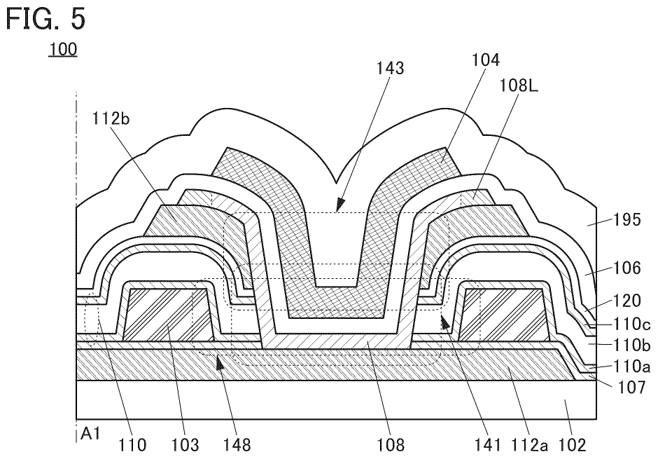

FIG. 5 is an enlarged view of the transistor 100 illustrated in FIG. 1B. The transistor 100 includes a conductive layer 112a, a conductive layer 103, an insulating layer 107, an insulating layer 110, an insulating layer 120, a semiconductor layer 108, a conductive layer 112b, an insulating layer 106, and a conductive layer 104. The layers included in the transistor 100 may each have a single-layer structure or a stacked-layer structure.

The conductive layer 112a is provided over the substrate 102. The conductive layer 112a functions as one of a source electrode and a drain electrode of the transistor 100.

The insulating layer 107 is positioned over the conductive layer 112a. The insulating layer 107 is provided so as to cover the upper and side surfaces of the conductive layer 112a.

The conductive layer 103 is positioned over the insulating layer 107. The conductive layer 112a and the conductive layer 103 are electrically insulated from each other by the insulating layer 107. In the conductive layer 103, an opening 148 reaching the insulating layer 107 is provided in a region overlapping with the conductive layer 112a.

The insulating layer 110 is provided over the insulating layer 107 and the conductive layer 103. The insulating layer 110 is provided so as to cover the tope and side surfaces of the conductive layer 103 and the top surface of the insulating layer 107.

The insulating layer 110 preferably has a stacked-layer structure. FIG. 1B and the like illustrate an example in which the insulating layer 110 has a stacked-layer structure of an insulating layer 110a, an insulating layer 110b over the insulating layer 110a, and an insulating layer 110c over the insulating layer 110b.

The insulating layer 110a is positioned over the insulating layer 107 and the conductive layer 103. The insulating layer 110a is provided so as to cover the top and side surfaces of the conductive layer 103. The insulating layer 110a is provided so as to cover part of the opening 148. The insulating layer 110a is in contact with the insulating layer 107 through the opening 148.

The insulating layer 110b is provided over the insulating layer 110a, and the insulating layer 110c is provided over the insulating layer 110b. Furthermore, the insulating layer 120 is provided over the insulating layer 110c. An opening 141 reaching the conductive layer 112a is provided in the insulating layer 107, the insulating layer 110, and the insulating layer 120.

The conductive layer 112b is positioned over the insulating layer 120. An opening 143 overlapping with the opening 141 is provided in the conductive layer 112b. Note that in FIG. 3B, the opening 141 is denoted by a dashed line. The conductive layer 112b functions as the other of the source electrode and the drain electrode of the transistor 100. The conductive layer 112b includes a region overlapping with the conductive layer 112a with the insulating layer 107, the insulating layer 110, and the insulating layer 120 therebetween.

There is no limitation on the top surface shapes of the opening 141, the opening 143, and the opening 148. The top surface shapes of the opening 141, the opening 143, and the opening 148 can each be a circle, an ellipse, a polygon such as a triangle, a quadrangle (including a rectangle, a rhombus, and a square), or a pentagon, or any of these polygons whose corners are rounded, for example. Note that the polygon may be a concave polygon (a polygon at least one of the interior angles of which is greater than) 180° or a convex polygon (a polygon all the interior angles of which are less than or equal to) 180°. Each of the top surface shapes of the opening 141, the opening 143, and the opening 148 is preferably a circle as illustrated in FIG. 1A and the like. When the top surface shapes of the openings are circles, processing accuracy at the time of formation of the openings can be high, whereby the openings can be formed to have minute sizes. Note that in this specification and the like, a circular shape is not necessarily a perfect circular shape.

In this specification and the like, the top surface shape of the opening 141 refers to the shape of an end portion on the opening 141 side of the top surface of the insulating layer interposed between the conductive layer 112a and the conductive layer 112b. For example, in the structure illustrated in FIG. 1B and the like, the top surface shape of the opening 141 refers to the shape of an end portion on the opening 141 side of the top surface of the insulating layer 120. The top surface shape of the opening 143 refers to the shape of an end portion on the opening 143 side of the bottom surface of the conductive layer 112b. The top surface shape of the opening 148 refers to the shape of an end portion on the opening 148 side of the top surface or the bottom surface of the conductive layer 103.

As illustrated in FIG. 1A, the top surface shape of the opening 141 and the top surface shape of the opening 143 can be the same or substantially the same. In that case, it is preferable that the end portion on the opening 143 side of the bottom surface of the conductive layer 112b be aligned with or substantially aligned with an end portion on the opening 141 side of the top surface of the insulating layer 110 as illustrated in FIG. 1B, FIG. 1C, and FIG. 5. The bottom surface of the conductive layer 112b refers to the surface thereof on the insulating layer 120 side. The top surface of the insulating layer 120 refers to the surface thereof on the conductive layer 112b side.

Note that the top surface shape of the opening 141 and the top surface shape of the opening 143 are not necessarily the same. In the case where the top surface shapes of the opening 141 and the opening 143 are circular, the opening 141 and the opening 143 may be concentrically arranged, but not necessarily concentrically arranged.

When the top surface shape of each of the opening 141 and the opening 148 is a circle, the opening 141 and the opening 148 are preferably concentrically arranged. In that case, the shortest distances between the semiconductor layer 108 and the conductive layer 103 on the left and right sides of the opening 141 can be equal to each other in the cross-sectional view. The opening 141 and the opening 148 are not concentrically arranged in some cases.

The semiconductor layer 108 is in contact with the top surface of the conductive layer 112a, the side surface of the insulating layer 107, the side surface of the insulating layer 110, the side surface of the insulating layer 120, and the top and side surfaces of the conductive layer 112b. The semiconductor layer 108 is provided so as to cover the opening 141 and the opening 143. The semiconductor layer 108 is provided in contact with the side surfaces on the opening 141 side of the insulating layer 107, the insulating layer 110, and the insulating layer 120 and the end portion on the opening 143 side of the conductive layer 112b (which can also be referred to as part of the top surface of the conductive layer 112b and the side surface on the opening 143 side of the conductive layer 112b). The semiconductor layer 108 is in contact with the conductive layer 112a through the opening 141 and the opening 143.

Although an example where an end portion of the semiconductor layer 108 is in contact with the top surface of the conductive layer 112b is illustrated in FIG. 1B, the present invention is not limited to this example. The semiconductor layer 108 may cover an end portion of the conductive layer 112b, and the end portion of the semiconductor layer 108 may be in contact with the top surface of the insulating layer 120.

The insulating layer 106 is positioned over the insulating layer 120, the semiconductor layer 108, and the conductive layer 112b. The insulating layer 106 is provided so as to cover the opening 141 and the opening 143 with the semiconductor layer 108 therebetween. Part of the insulating layer 106 functions as a gate insulating layer of the transistor 100.

The conductive layer 104 is positioned over the insulating layer 106. The conductive layer 104 overlaps with the semiconductor layer 108 with the insulating layer 106 therebetween. The conductive layer 104 functions as a gate electrode of the transistor.

In the transistor 100, a region of the semiconductor layer 108 overlaps with the conductive layer 104 with the insulating layer 106 provided between the region and the conductive layer 104 and overlaps with the conductive layer 103 with part (specifically, the insulating layers 110a and 110b) of the insulating layer 110 provided between the region and the conductive layer 103. In other words, a region of the semiconductor layer 108 is interposed between the conductive layer 104 and the conductive layer 103 with the insulating layer 106 positioned between the region and the conductive layer 104 and with part of the insulating layer 110 (specifically, the insulating layer 110a and the insulating layer 110b) positioned between the region and the conductive layer 103.

The conductive layer 103 functions as a back gate electrode of the transistor 100. Part of the insulating layer 110 and part of the insulating layer 120 function as a back gate insulating layer of the transistor 100. Note that the conductive layer 103 is not necessarily provided.

Providing the back gate electrode for the transistor 100 enables the potential on the back channel side of the semiconductor layer 108 to be fixed, so that the saturation of the Id-Vd characteristics of the transistor 100 can be improved.

In this specification and the like, the state where the change in current is small in the saturation region of the Id-Vd characteristics of a transistor is sometimes described using the expression “favorable saturation”.

Since the transistor 100 includes the back gate electrode, the potential on the back channel side of the semiconductor layer 108 can be fixed and a shift of the threshold voltage can be inhibited. A shift in the threshold voltage of the transistor might increase the drain current flowing at a gate voltage of 0 V (hereinafter, also referred to as cut-off current). When the threshold voltage shift of the transistor 100 is inhibited, the cut-off current can be reduced in the transistor. Note that characteristics with low cut-off current are sometimes referred to as normally-off characteristics.

The transistor 100 is what is called a top-gate transistor including the gate electrode above the semiconductor layer 108. Furthermore, since the bottom surface of the semiconductor layer 108 is in contact with the source electrode and the drain electrode, the transistor 100 can be referred to as a TGBC (Top Gate Bottom Contact) transistor. In the transistor 100, the source electrode and the drain electrode are positioned at different levels with respect to the surface of the substrate 102 over which the transistor 100 is formed, and a drain current flows in a direction perpendicular or substantially perpendicular to the surface of the substrate 102. In the transistor 100, a drain current can also be regarded as flowing in the vertical direction or the substantially vertical direction. Accordingly, the transistor of one embodiment of the present invention can be referred to as a vertical-channel transistor or a vertical field-effect transistor (VFET).

The channel length of the transistor 100 can be controlled by the thickness of the insulating layers provided between the conductive layer 112a and the conductive layer 112b (here, the insulating layer 107, the insulating layer 110, and the insulating layer 120). Accordingly, a transistor with a channel length smaller than the resolution limit of a light exposure apparatus used for manufacturing the transistor can be manufactured with high accuracy. Furthermore, variations in characteristics among the transistors 100 are also reduced. Accordingly, the operation of the semiconductor device including the transistor 100 can be stabilized and the reliability thereof can be improved. When the variations in characteristics are reduced, the circuit design flexibility is increased and the operation voltage of the semiconductor device can be reduced. Thus, power consumption of the semiconductor device can be reduced.

In the transistor 100, since the source electrode, the semiconductor layer, and the drain electrode can be provided to overlap with each other, the area occupied by the transistor can be significantly reduced as compared with a so-called planar transistor in which a semiconductor layer is positioned over a flat surface.

The conductive layer 112a, the conductive layer 112b, and the conductive layer 104 can each function as a wiring, and the transistor 100 can be provided in a region where these wirings overlap with each other. That is, the areas occupied by the transistor 100 and the wirings can be reduced in the circuit including the transistor 100 and the wirings. Accordingly, the area occupied by the circuit can be reduced, which makes it possible to provide a small semiconductor device.

When the semiconductor device of one embodiment of the present invention is used for a pixel circuit of a display device, the area occupied by the pixel circuit can be reduced and a high-resolution display device can be provided, for example. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel, for example.

Although the semiconductor layer 108, the insulating layer 106, and the conductive layer 104 cover the opening 141 and the opening 143 in FIG. 1B or the like, for example, one embodiment of the present invention is not limited to this example. A step may be formed between the conductive layer 112a and each of the insulating layer 107, the insulating layer 110, the insulating layer 120, and the conductive layer 112b; and the semiconductor layer 108, the insulating layer 106, and the conductive layer 104 may be provided along the step.

The transistor 200 includes a conductive layer 202, the insulating layer 107, the insulating layer 110, the insulating layer 120, a semiconductor layer 208, the insulating layer 106, and a conductive layer 204. The layers constituting the transistor 200 may each have a single-layer structure or a stacked-layer structure.

The conductive layer 202 is provided over the substrate 102. The conductive layer 202 functions as a back gate electrode of the transistor 200. For the conductive layer 202, the same material as the conductive layer 112a can be used, for example. Furthermore, the conductive layer 202 can be formed through the same step as the conductive layer 112a. For example, the conductive layer 112a and the conductive layer 202 can be formed by forming and processing a conductive film to be the conductive layer 112a and the conductive layer 202.

The insulating layer 107 is provided over the conductive layer 202, the insulating layer 110 is provided over the insulating layer 107, and the insulating layer 120 is provided over the insulating layer 110. Parts of the insulating layer 107, the insulating layer 110, and the insulating layer 120 function as a back gate insulating layer of the transistor 200. Note that the conductive layer 202 is not necessarily provided.

The semiconductor layer 208 is provided over the insulating layer 120. The semiconductor layer 208 includes a region overlapping with the conductive layer 202 with the insulating layer 107, the insulating layer 110, and the insulating layer 120 therebetween. For the semiconductor layer 208, the same material as the semiconductor layer 108 can be used, for example. Furthermore, the semiconductor layer 208 can be formed through the same steps as the semiconductor layer 108. For example, the semiconductor layer 108 and the semiconductor layer 208 can be formed by forming and processing a semiconductor film to be the semiconductor layer 108 and the semiconductor layer 208.

The insulating layer 106 is provided over the insulating layer 120 and the semiconductor layer 208. Part of the insulating layer 106 functions as a gate insulating layer of the transistor 200. Furthermore, the insulating layer 106 includes an opening 147a and an opening 147b reaching the semiconductor layer 208.

The conductive layer 204, a conductive layer 212a, and a conductive layer 212b are provided over the insulating layer 106. The conductive layer 204, the conductive layer 212a, and the conductive layer 212b can include the same material as the conductive layer 104, for example. Furthermore, the conductive layer 204, the conductive layer 212a, and the conductive layer 212b can be formed in the same steps as the conductive layer 104. For example, the conductive layer 104, the conductive layer 204, the conductive layer 212a, and the conductive layer 212b can be formed by forming and processing a conductive film to be the conductive layer 104, the conductive layer 204, the conductive layer 212a, and the conductive layer 212b.

The conductive layer 204 includes a region overlapping with the semiconductor layer 208 with the insulating layer 106 therebetween and functions as a gate electrode of the transistor 200. An end portion of the conductive layer 204 is positioned inside an end portion of the insulating layer 106. It can be said that the end portion of the conductive layer 204 is in contact with the top surface of the insulating layer 106. In other words, the insulating layer 106 includes a portion extending beyond the end portion of the conductive layer 204 over at least the semiconductor layer 208.

The conductive layer 212a and the conductive layer 212b are provided to cover part of the opening 147a and part of the opening 147b and are in contact with the semiconductor layer 208 through the opening 147a and the opening 147b. The conductive layer 212a functions as one of a source electrode and a drain electrode of the transistor 200, and the conductive layer 212b functions as the other thereof.

In the semiconductor layer 208 between the source electrode and the drain electrode, the whole region overlapping with the gate electrode with the gate insulating layer therebetween functions as a channel formation region. The semiconductor layer 208 includes a pair of regions 208L between which the channel formation region is interposed and a pair of regions 208D outside the pair of regions 208L.

The region 208D can also be referred to as a region having a higher carrier concentration or a lower resistance than the channel formation region or an n-type region. In the semiconductor layer 208, a region in contact with the conductive layer 212a and the region 208D adjacent to the region function as one of a source region and a drain region. In the semiconductor layer 208, a region in contact with the conductive layer 212b and the region 208D adjacent to the region function as the other of the source region and the drain region.

The region 208L can be referred to as a region whose electric resistance is substantially equal to or lower than that of the channel formation region, a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. Furthermore, the region 208L can be referred to as a region whose electric resistance is substantially equal to or higher than that of the region 208D, a region whose carrier concentration is substantially equal to or lower than that of the region 208D, a region whose oxygen vacancy density is substantially equal to or lower than that of the region 208D, or a region whose impurity concentration is substantially equal to or lower than that of the region 208D.

The region 208L functions as a buffer region that relieves a drain electric field. The region 208L is a region not overlapping with the conductive layer 204 and thus is a region where a channel is hardly formed by application of a gate voltage to the conductive layer 204. The region 208L preferably has a higher carrier concentration than the channel formation region. Thus, the region 208L can function as an LDD (Lightly Doped Drain) region. The region 208L functioning as the LDD region provided between the channel formation region and the region 208D enables the transistor 200 to have high reliability and achieve both a high drain breakdown voltage and a high on-state current.

The carrier concentration in the semiconductor layer 208 preferably has a distribution such that the concentration is the lowest in the channel formation region and increases in the order of the region 208L and the region 208D. Providing the region 208L between the channel formation region and the region 208D can keep the carrier concentration of the channel formation region extremely low even when impurities such as hydrogen diffuse from the region 208D during the manufacturing process, for example.

Note that the carrier concentration is not necessarily uniform in the region 208L: the region 208L sometimes has a carrier concentration gradient that decreases from the region 208D side to the channel formation region side. For example, one or both of the hydrogen concentration and the oxygen vacancy concentration of the region 208L may have a gradient that decreases from the region 208D side to the channel formation region side.

For example, after the conductive layer 204, the conductive layer 212a, and the conductive layer 212b are formed, an impurity element can be added to the semiconductor layer 208 using these conductive layers as masks, so that the region 208L and the region 208D can be formed. The region 208L is a region that is of the semiconductor layer 208, overlaps with the insulating layer 106, and does not overlap with the conductive layer 204. The region 208D is a region that is of the semiconductor layer 208 and overlaps with neither the insulating layer 106 nor the conductive layer 204.

As illustrated in FIG. 1B and FIG. 1C, it is preferable that end portions of the conductive layer 212a and the conductive layer 212b be partly positioned inside the opening 147a and the opening 147b, respectively. In other words, it is preferable that the end portions of the conductive layer 212a and the conductive layer 212b be partly in contact with the semiconductor layer 208 in the opening 147a and the opening 147b, respectively. Accordingly, the region in contact with the conductive layer 212a can be adjacent to one of the pair of regions 208D, and the region in contact with the conductive layer 212b can be adjacent to the other of the pair of regions 208D.

There is no limitation on the top surface shapes of the opening 147a and the opening 147b. Although FIG. 1A and the like illustrate a structure where the top surface shapes of the opening 147a and the opening 147b are different from the top surface shapes of the opening 141 and the opening 143, one embodiment of the present invention is not limited thereto. The top surface shapes of the opening 147a and the opening 147b may be the same as the top surface shapes of the opening 141 and the opening 143.

The region 208L and the region 208D are regions containing an impurity element.

Examples of the impurity element include one or more of hydrogen, boron, carbon, nitrogen, fluorine, phosphorus, sulfur, arsenic, aluminum, magnesium, silicon, and a noble gas. Note that typical examples of a noble gas include helium, neon, argon, krypton, and xenon. It is particularly preferable to use one or more of boron, phosphorus, aluminum, magnesium, and silicon as the impurity element.

When the region 208L and the region 208D are formed by adding the impurity element to the semiconductor layer 208, the impurity element may be supplied to the semiconductor layer 108 through the insulating layer 106 with use of the conductive layer 104 as a mask. Consequently, a region 108L is formed in a region that is of the semiconductor layer 108 and does not overlap with the conductive layer 104. Note that in the transistor 100, a region that is of the semiconductor layer 108 and in contact with the conductive layer 112b functions as a source region or a drain region. The region 108L is formed in part of the source region or the drain region. The region 108L is not necessarily formed. For example, in the case where the conductive layer 104 is extended to cover the end portion of the semiconductor layer 108, the conductive layer 104 masks the whole semiconductor layer 108 to preclude the supply of the impurity element to the semiconductor layer 108, and the region 108L is not formed.

As illustrated in FIG. 1C, the conductive layer 204 may be electrically connected to the conductive layer 202 through an opening 149 provided in the insulating layer 106, the insulating layer 120, the insulating layer 110, and the insulating layer 107. In that case, the conductive layer 204 and the conductive layer 202 can be supplied with the same potential. When the same potential is applied to the conductive layer 204 and the conductive layer 202, the amount of current that can flow in the transistor 200 in the on state can be increased.

Note that there is no particular limitation on the top surface shape of the opening 149. The top-surface shape of the opening 149 can be a circle or an ellipse, for example. Examples of the top surface shape of the opening 149 include polygons such as a triangle, a tetragon (including a rectangle, a rhombus, and a square), and a pentagon; and polygons with rounded corners. The top surface shape of the opening 149 may be the same as or different from the top surface shapes of the opening 141, the opening 143, and the opening 148. The top surface shape of the opening 149 may be the same as or different from the top surface shapes of the opening 147a and the opening 147b.

As illustrated in FIG. 1A and FIG. 1C, the conductive layer 204 and the conductive layer 202 preferably extend beyond an end portion of the semiconductor layer 208 in the channel width direction of the transistor 200. In that case, as illustrated in FIG. 1C, the whole of the semiconductor layer 208 in the channel width direction is covered with the conductive layer 204 with the insulating layer 106 therebetween and also covered with the conductive layer 202 with the insulating layer 110, the insulating layer 120, and the insulating layer 107 therebetween. In such a structure, the semiconductor layer 208 can be electrically surrounded by electric fields generated by the pair of gate electrodes. In that case, it is particularly preferable that the same potential be supplied to the conductive layer 204 and the conductive layer 202. In that case, electric fields for inducing a channel can be effectively applied to the semiconductor layer 208, whereby the on-state current of the transistor 200 can be increased. Thus, the transistor 200 can also be miniaturized.

Note that a structure where the conductive layer 204 and the conductive layer 202 are not connected to each other may be employed. In that case, a constant potential may be applied to one of the pair of gate electrodes, and a signal for driving the transistor 200 may be applied to the other. In this case, the potential applied to one of the gate electrodes can control the threshold voltage at the time of driving the transistor 200 with the other gate electrode.

The conductive layer 202 may be electrically connected to the conductive layer 212a or the conductive layer 212b. In that case, the conductive layer 212a or the conductive layer 212b and the conductive layer 202 may be electrically connected to each other through an opening provided in the insulating layer 106, the insulating layer 120, the insulating layer 110, and the insulating layer 107.

The transistor 200 is what is called a top-gate transistor including the gate electrode above the semiconductor layer 208. For example, an impurity element is added to the semiconductor layer 208 by using the conductive layer 204 functioning as the gate electrode as a mask, so that the regions 208D functioning as the source region and the drain region can be formed in a self-aligned manner. The transistor 200 can be referred to as a TGSA (Top Gate Self-Aligned) transistor.

The channel length of the transistor 200 can be controlled by the length of the conductive layer 204. Accordingly, the channel length of the transistor 200 is greater than or equal to the resolution limit of a light exposure apparatus used for manufacturing the transistor. The transistor with a long channel length can have favorable saturation.

As described above, the transistor 100 with a short channel length and the transistor 200 with a long channel length can be formed over the same substrate, and some of the formation steps of the transistor 100 can be the same as some of the formation steps of the transistor 200. For example, the transistor 100 is used as the transistor required to have a high on-state current and the transistor 200 is used as the transistor required to have favorable saturation, thereby providing a high-performance semiconductor device.

An insulating layer 195 is provided to cover the transistor 100 and the transistor 200. The insulating layer 195 functions as a protective layer for the transistor 100 and the transistor 200.

Components of the transistor 100 and the transistor 200 are described in detail.

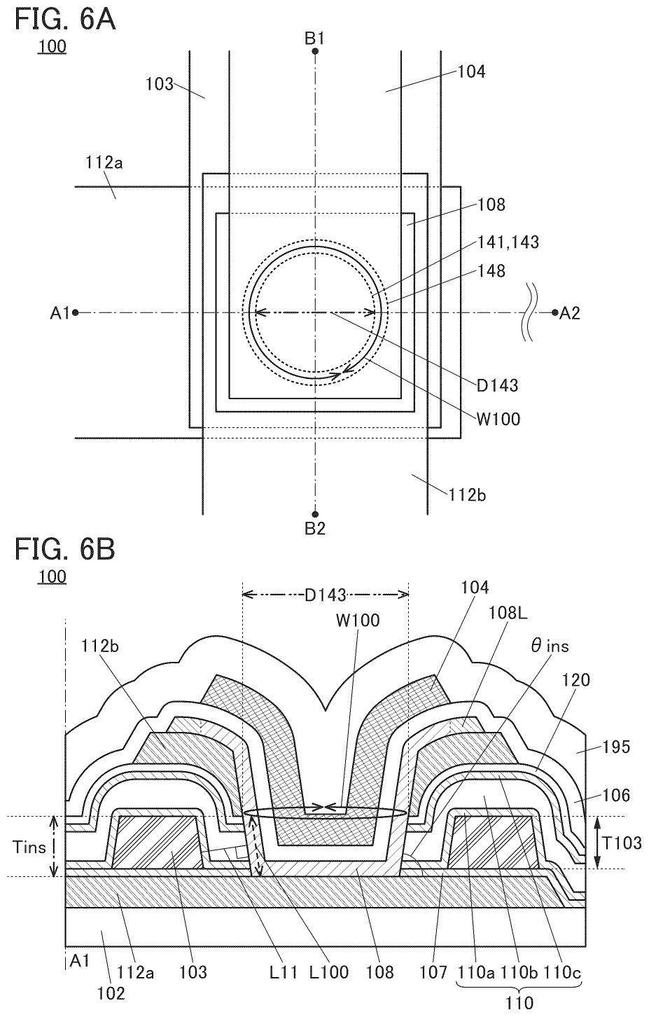

First, the channel length and the channel width of the transistor 100 are described with reference to FIG. 6A and FIG. 6B. FIG. 6A is an enlarged view of the transistor 100 illustrated in FIG. 1A, and FIG. 6B is an enlarged view of the transistor 100 illustrated in FIG. 1B.

In the semiconductor layer 108, a region in contact with the conductive layer 112a functions as one of the source region and the drain region, a region in contact with the conductive layer 112b functions as the other of the source region and the drain region, and a region between the source region and the drain region functions as the channel formation region.

The channel length of the transistor 100 is a distance between the source region and the drain region. In FIG. 6B, a channel length L100 of the transistor 100 is indicated by a dashed double-headed arrow. It can be said that in a cross-sectional view, the channel length L100 is the shortest distance between the region that is of the semiconductor layer 108 and in contact with the conductive layer 112a and the region that is of the semiconductor layer 108 and in contact with the conductive layer 112b.

The channel length L100 of the transistor 100 corresponds to the length of the side surface on the opening 141 side of the insulating layers interposed between the conductive layer 112a and the conductive layer 112b in a cross-sectional view. That is, the channel length L100 is determined by a thickness Tins of the insulating layers interposed between the conductive layer 112a and the conductive layer 112b (here, the sum of the thicknesses of the insulating layer 107, the insulating layer 110, and the insulating layer 120) and an angle θins formed between the side surfaces on the opening 141 side of those insulating layers and the formation surface (here, the top surface of the conductive layer 112a). Thus, the channel length L100 can be a value smaller than that of the resolution limit of a light-exposure apparatus, for example, which enables the transistor to have a minute size. Specifically, a transistor with an extremely short channel length that could not be achieved with a conventional light-exposure apparatus for mass production of flat panel displays (the minimum line width: approximately 2 μm or approximately 1.5 μm, for example) can be achieved. Moreover, it is also possible to provide a transistor with a channel length shorter than 10 nm without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

The reduction in the channel length L100 can increase the on-state current of the transistor 100. With the use of the transistor 100, a circuit capable of high-speed operation can be manufactured. Furthermore, the area occupied by the circuit can be reduced. Therefore, a semiconductor device with a small size can be obtained. The application of the semiconductor device of one embodiment of the present invention to a large display device or a high-resolution display device can reduce signal delay in wirings and reduce display unevenness even if the number of wirings is increased, for example. In addition, since the area occupied by the circuit can be reduced, the bezel of the display device can be narrowed.

By adjusting the thickness Tins and the angle θins, the channel length L100 can be controlled. Note that in FIG. 6B, the thickness Tins is indicated by a dashed-dotted double-headed arrow.

The thickness Tins can be, for example, greater than or equal to 10 nm, greater than or equal to 50 nm, greater than or equal to 100 nm, greater than or equal to 150 nm, greater than or equal to 200 nm, greater than or equal to 300 nm, greater than or equal to 400 nm, or greater than or equal to 500 nm and less than 3.0 μm, less than or equal to 2.5 μm, less than or equal to 2.0 μm, less than or equal to 1.5 μm, less than or equal to 1.2 μm, or less than or equal to 1.0 μm.

The side surfaces on the opening 141 side of the insulating layer 107, the insulating layer 110, and the insulating layer 120 preferably have tapered shapes. The angle θins formed between the side surfaces on the opening 141 side of the insulating layer 107, the insulating layer 110, and the insulating layer 120 and the formation surface of the insulating layer 110 (here, the top surface of the conductive layer 112a) is preferably smaller than 90°. By reducing the angle θins, the coverage with a layer (e.g., the semiconductor layer 108) provided over those insulating layers can be improved. The smaller the angle θins is, the larger the channel length L100 is. The larger the angle θins is, the smaller the channel length L100 is.

The angle θins can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than 90°, less than or equal to 85°, or less than or equal to 80°.

Although FIG. 6B and the like illustrate the structure where the side surfaces on the opening 141 side of the insulating layer 107, the insulating layer 110, and the insulating layer 120 are linear in the cross-sectional view, one embodiment of the present invention is not limited thereto. In the cross-sectional view, the side surfaces on the opening 141 side of the insulating layer 107, the insulating layer 110, and the insulating layer 120 may be curved, or the side surfaces may include both a linear region and a curved region.

In FIG. 6A and FIG. 6B, a width D143 of the opening 143 is indicated by a dashed double-dotted double-headed arrow. FIG. 6A illustrates an example where the top surface shape of each of the opening 141 and the opening 143 is a circle. In this case, the width D143 corresponds to the diameter of the circle and a channel width W100 of the transistor 100 is the length of the circumference of the circle. That is, the channel width W100 is π×D143. Accordingly, in the case where the opening 141 and the opening 143 have circular top surface shapes, the channel width W100 of the transistor can be smaller than that of the case where the opening 141 and the opening 143 have any other shape.

Note that the opening 141 and the opening 143 sometimes have different diameters. The inner diameter of each of the opening 141 and the opening 143 sometimes varies in the depth direction. As the diameter of the opening, for example, the average value of the following three diameters can be used: the diameter at the highest level in a cross-sectional view, the diameter at the lowest level in a cross-sectional view, and the diameter at the midpoint between these levels of the insulating layer 107, the insulating layer 110, and the insulating layer 120. For another example, any of the diameter at the highest level in a cross-sectional view, the diameter at the lowest level in a cross-sectional view, and the diameter at the midpoint between these levels of the insulating layer 107, the insulating layer 110, and the insulating layer 120 can be used as the diameter of the opening.

In the case where the opening 143 is formed by a photolithography method, the width D143 of the opening 143 is larger than or equal to the resolution limit of a light-exposure apparatus. The width D143 can be, for example, greater than or equal to 200 nm, greater than or equal to 300 nm, greater than or equal to 400 nm, or greater than or equal to 500 nm and less than 5.0 μm, less than or equal to 4.5 μm, less than or equal to 4.0 μm, less than or equal to 3.5 μm, less than or equal to 3.0 μm, less than or equal to 2.5 μm, less than or equal to 2.0 μm, less than or equal to 1.5 μm, or less than or equal to 1.0 μm.

Next, the conductive layer 103 functioning as the back gate electrode of the transistor 100 is described with reference to FIG. 6B.

A thickness T103 of the conductive layer 103 is preferably greater than or equal to 0.5 times, further preferably greater than or equal to 1.0 times, still further preferably greater than 1.0 times the channel length L100, and preferably less than or equal to 2.0 times, further preferably less than or equal to 1.5 times, still further preferably less than or equal to 1.2 times the channel length L100. In that case, a region that is of the semiconductor layer 108 and overlaps with the conductive layer 104 with the insulating layer 106 therebetween and overlaps with the conductive layer 103 with the insulating layer 110 and the insulating layer 120 therebetween can be sufficiently wide. As a result, the potential on the back channel side of the semiconductor layer 108 can be more surely controlled.

The thickness T103 of the conductive layer 103 may be larger than the thickness Tins. Accordingly, the potential on the back channel side of the semiconductor layer 108 can be fixed in a wide range between the source region and the drain region of the semiconductor layer 108.

The transistor 100 of one embodiment of the present invention includes a region where the conductive layer 103, the insulating layer 110, the insulating layer 120, the semiconductor layer 108, the insulating layer 106, and the conductive layer 104 are stacked in this order in one direction with no any other layer provided between these layers. The one direction can be perpendicular to the channel length L100. When the above region is wide, the potential on the back channel side of the semiconductor layer 108 can be controlled more reliably.

The thickness T103 of the conductive layer 103 can be larger than the sum of the thickness of a portion that is of the semiconductor layer 108 and in contact with the conductive layer 112a inside the opening 141 and the thickness of the insulating layer 106 in contact with the portion.

A distance L11, which is the shortest distance between the conductive layer 103 and the semiconductor layer 108 in a cross-sectional view, is preferably shorter than the channel length L100, further preferably less than or equal to 0.5 times the channel length L100, still further preferably less than or equal to 0.1 times the channel length L100. The shorter the distance between the conductive layer 103 and the semiconductor layer 108 is, the more favorable the saturation of the Id-Vd characteristics of the transistor 100 can be.

In a cross-sectional view; the shortest distance between the conductive layer 103 and the semiconductor layer 108 on the left side of the opening 141 may be different from that on the right side of the opening 141. In that case, the distance L11 satisfies the above-described range preferably on at least one of the left side and the right side of the opening 141, further preferably on both the left side and the right side of the opening 141. In a given cross section, the shortest distance between the conductive layer 103 and the semiconductor layer 108 on the left side of the opening 141 is preferably greater than or equal to 50% and less than or equal to 150%, further preferably greater than or equal to 30% and less than or equal to 130%, still further preferably greater than or equal to 10% and less than or equal to 110% of the shortest distance on the right side of the opening 141.

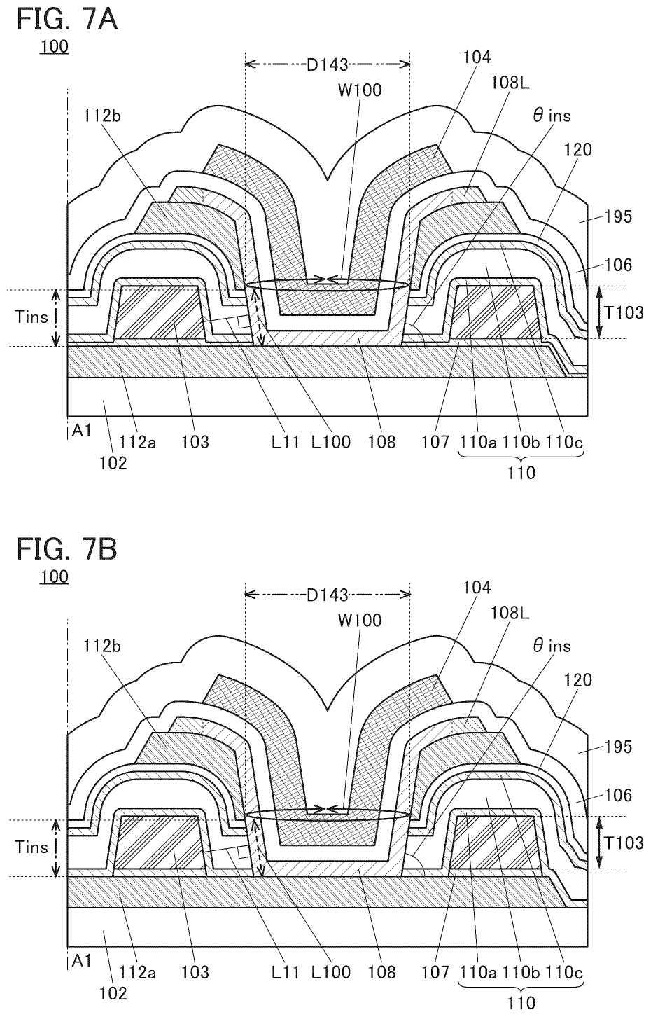

Although the thickness of the insulating layer 107 is entirely uniform in FIG. 6B and the like, one embodiment of the present invention is not limited to this example. The thickness of the insulating layer 107 may differ between a region overlapping with the conductive layer 103 and a region not overlapping with the conductive layer 103. For example, at the time of forming the conductive layer 103, the insulating layer 107 in the region not overlapping with the conductive layer 103 is sometimes partly removed to have a reduced thickness. Thus, as illustrated in FIG. 7A, the region that is of the insulating layer 107 and does not overlap with the conductive layer 103 is sometimes thinner than the region that is of the insulating layer 107 and overlaps with the conductive layer 103.

As illustrated in FIG. 7B, the insulating layer 107 in the region not overlapping with the conductive layer 103 may be removed, and the insulating layer 110a may include a region in contact with the conductive layer 112a. For example, the insulating layer 107 in the region not overlapping with the conductive layer 103 can be removed at the time of forming the conductive layer 103. In the case where the insulating layer 107 in the region not overlapping with the conductive layer 103 is removed, the thickness Tins is the sum of the thicknesses of the insulating layer 110a, the insulating layer 110b, the insulating layer 110c, and the insulating layer 120. The thickness Tins is preferably within the above-described range.

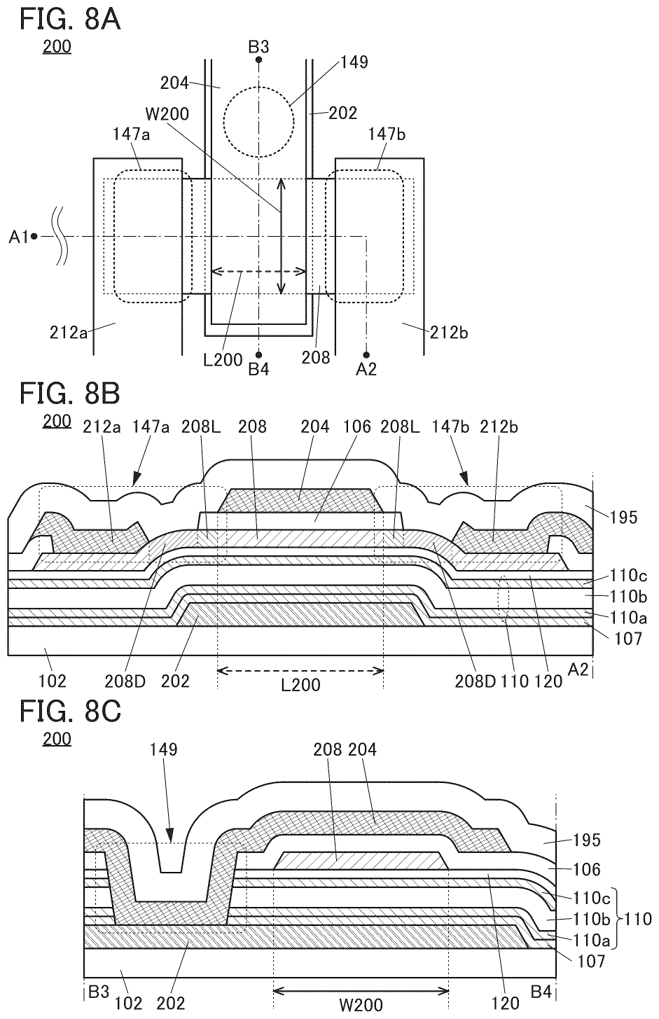

Next, the channel length and the channel width of the transistor 200 are described with reference to FIG. 8A to FIG. 8C. FIG. 8A is a top view of the transistor 200, FIG. 8B is an enlarged view of the transistor 200 illustrated in FIG. 1B, and FIG. 8C is an enlarged view of the transistor 200 illustrated in FIG. 1C.

In the semiconductor layer 208, the pair of regions 208D functions as the source region and the drain region, and the region between the source region and the drain region functions as the channel formation region. The channel formation region includes a region overlapping with the conductive layer 204 with the insulating layer 106 therebetween.

The channel length of the transistor 200 is the length of a region between the pair of regions 208D where the semiconductor layer 208 and the conductive layer 204 overlap with each other. In FIG. 8A and FIG. 8B, a channel length L200 of the transistor 200 is indicated by a dashed double-headed arrow. The channel length L200 of the transistor 200 is determined by the length of the conductive layer 204, which is greater than or equal to the resolution limit of a light exposure apparatus. For example, the channel length L200 can be greater than or equal to 1.5 μm. The transistor with a long channel length can have favorable saturation.

Here, the channel width of the transistor 200 is the width of the region where the semiconductor layer 208 overlaps with the conductive layer 204 in the direction orthogonal to the channel length direction. In FIG. 8A and FIG. 8C, a channel width W200 of the transistor 200 is indicated by a solid double-headed arrow.

As described above, the channel length L100 of the transistor 100 can have a smaller value than the resolution limit of the light exposure apparatus and the channel length L200 of the transistor 200 can have a value larger than or equal to the resolution limit of the light exposure apparatus. For example, the transistor 100 is used as the transistor required to have a high on-state current and the transistor 200 is used as the transistor required to have favorable saturation, so that the high-performance semiconductor device 10 utilizing the advantages of the transistors can be provided.

In the semiconductor device 10 of one embodiment of the present invention, the transistor 100 and the transistor 200 having different structures and different channel lengths can be formed over the substrate 102, and some of the formation steps of the transistor 100 can be the same as some of the formation steps of the transistor 200. Specifically, the conductive layer 112a and the conductive layer 202 can be formed in the same step. The semiconductor layer 108 and the semiconductor layer 208 can be formed in the same step. One part of the insulating layer 106 functions as the gate insulating layer of the transistor 100 and another part of the insulating layer 106 functions as the gate insulating layer of the transistor 200. The conductive layer 104, the conductive layer 204, the conductive layer 212a, and the conductive layer 212b can be formed in the same step. Thus, the productivity of the semiconductor device 10 can be increased and the manufacturing cost of the semiconductor device 10 can be made low.

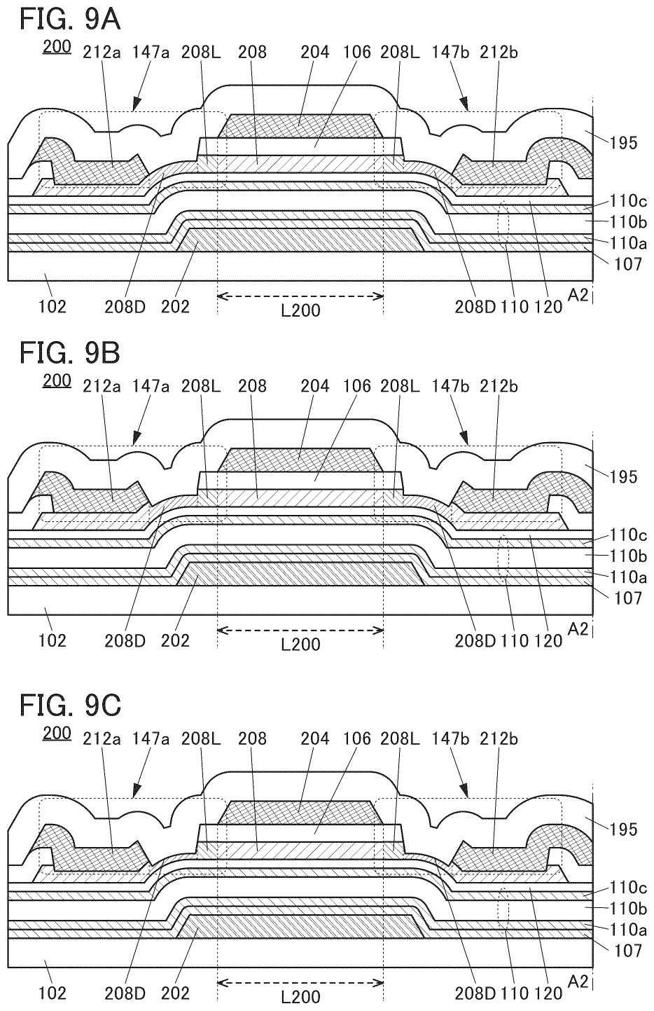

Although the thickness of the semiconductor layer 208 is entirely uniform in FIG. 8B and the like, one embodiment of the present invention is not limited to this example. As illustrated in FIG. 9A, the thickness of the semiconductor layer 208 in the region overlapping with the insulating layer 106 may be different from the thickness of the semiconductor layer 208 in the region not overlapping with the insulating layer 106. For example, when the opening 147a and the opening 147b are formed, the semiconductor layer 208 is partly removed, so that the semiconductor layer 208 in the region not overlapping with the insulating layer 106 sometimes has a smaller thickness than the semiconductor layer 208 in the region overlapping with the insulating layer 106. Alternatively, as illustrated in FIG. 9B, the semiconductor layer 208 in the region overlapping with any of the insulating layer 106, the conductive layer 212a, and the conductive layer 212b may differ in thickness from the semiconductor layer 208 in the region not overlapping with any of them. For example, when the conductive layer 212a and the conductive layer 212b are formed, the semiconductor layer 208 is partly removed, so that the semiconductor layer 208 in the region not overlapping with any of the insulating layer 106, the conductive layer 212a, and the conductive layer 212b sometimes has a smaller thickness than the semiconductor layer 208 in the region overlapping with any of them. Alternatively, as illustrated in FIG. 9C, there may be a difference in the thickness of the semiconductor layer 208 among the region overlapping with the insulating layer 106, the region overlapping with any of the insulating layer 106, the conductive layer 212a, and the conductive layer 212b, and the region not overlapping with any of them.

Components included in the semiconductor device of this embodiment are described below:

### [Semiconductor Layer 108, Semiconductor Layer 208]

Semiconductor materials that can be used for the semiconductor layer 108 and the semiconductor layer 208 are not particularly limited. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor. These semiconductor materials may contain an impurity as a dopant.

There is no particular limitation on the crystallinity of the semiconductor materials used for the semiconductor layer 108 and the semiconductor layer 208, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The semiconductor layer 108 and the semiconductor layer 208 each preferably include a metal oxide (also referred to as an oxide semiconductor) exhibiting semiconductor characteristics.

The band gaps of metal oxides used for the semiconductor layer 108 and the semiconductor layer 208 are each preferably 2.0 eV or more, further preferably 2.5 eV or more.

Examples of the metal oxides that can be used for the semiconductor layer 108 and the semiconductor layer 208 include indium oxide, gallium oxide, and zinc oxide. The metal oxide preferably contains at least indium or zinc. The metal oxide preferably contains two or three selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element” and a “metal element” in this specification and the like may refer to a metalloid element.

For example, the semiconductor layer 108 and the semiconductor layer 208 can be formed using indium zinc oxide (In—Zn oxide, also referred to as IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide, also referred to as ITZO (registered trademark)), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO, IGZAO, or IAGZO). Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased. In addition, the transistor can have a high on-state current.

Instead of indium or in addition to indium, the metal oxide may contain one or more kinds of metal elements with large period numbers in the periodic table. The larger the overlap between orbits of metal elements is, the more likely it is that the metal oxide will have high carrier conductivity. Thus, when the transistor includes metal elements with larger period numbers, the field-effect mobility of the transistor can be increased in some cases. As examples of the metal element with a large period number, the metal elements belonging to Period 5 and those belonging to Period 6 are given. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. By containing a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

Electrical characteristics and reliability of the transistors depend on the composition of the metal oxide used for the semiconductor layer 108 and the semiconductor layer 208. Therefore, by determining the composition of the metal oxide in accordance with the electrical characteristics and reliability required for the transistors, the semiconductor device can have both excellent electrical characteristics and high reliability.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

When a metal oxide is an In-M-Zn oxide, the atomic ratio of In is preferably higher than or equal to the atomic ratio of the element M in the In-M-Zn oxide. Examples of the atomic ratio of the metal elements of such an In-M-Zn oxide include In:M:Zn=1:1:1, In:M:Zn=1:1:1.2, In: M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 and a composition in the neighborhood of any of the above atomic ratios. Note that a composition in the neighborhood of an atomic ratio includes ±30% of an intended atomic ratio. By increasing the proportion of the number of indium atoms in the metal oxide, the on-state current, field-effect mobility, or the like of the transistor can be improved.

The atomic ratio of In may be less than the atomic ratio of the element M in the In-M-Zn oxide. Examples of the atomic ratio of the metal elements of such an In-M-Zn oxide include In: M:Zn=1:3:2, In:M:Zn=1:3:3, and In: M:Zn=1:3:4 and a composition in the neighborhood of any of these atomic ratios. By increasing the proportion of the number of M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

A sputtering method or an atomic layer deposition (ALD) method can be suitably used for forming the metal oxide. Note that in the case where the metal oxide is formed by a sputtering method, the composition of the deposited metal oxide may be different from the composition of a target. In particular, the content percentage of zinc in the deposited metal oxide may be reduced to approximately 50% of that of the target.

The semiconductor layer 108 and the semiconductor layer 208 may have a stacked-layer structure of two or more metal oxide layers. The two or more metal oxide layers included in the semiconductor layer 108 and the semiconductor layer 208 may have the same composition or substantially the same compositions. Employing a stacked-layer structure of metal oxide layers having the same composition can, for example, reduce the manufacturing cost because the metal oxide layers can be formed using the same sputtering target.

The two or more metal oxide layers included in the semiconductor layer 108 and the semiconductor layer 208 may have different compositions. For example, a stacked-layer structure of a first metal oxide layer having In: M:Zn=1:3:4 [atomic ratio] or a composition in the neighborhood thereof and a second metal oxide layer having In: M:Zn=1:1:1 [atomic ratio] or a composition in the neighborhood thereof and being formed over the first metal oxide layer can be suitably employed. In particular, gallium, aluminum, or tin is preferably used as the element M. A stacked-layer structure of one selected from indium oxide, indium gallium oxide, and IGZO, and one selected from IAZO, IAGZO, and ITZO (registered trademark) may be employed, for example.

It is preferable that the semiconductor layer 108 and the semiconductor layer 208 each include a metal oxide having crystallinity. Examples of the structure of a metal oxide having crystallinity include a c-axis aligned crystal (CAAC) structure, a polycrystalline structure, and a nano-crystal (nc) structure. With use of a metal oxide having crystallinity for the semiconductor layer 108, the density of defect states in the semiconductor layer 108 can be reduced, which enables the semiconductor device to have high reliability.

The higher the crystallinity of the metal oxide layers used for the semiconductor layer 108 and the semiconductor layer 208 is, the lower the density of defect states in the semiconductor layer 108 can be. By contrast, the use of a metal oxide layer having low crystallinity enables a transistor to flow a large amount of current.

In the case where the metal oxide layer is formed by a sputtering method, the crystallinity of the formed metal oxide layer can be increased as the substrate temperature at the time of formation is higher. For example, the substrate temperature at the time of formation can be adjusted by the temperature of the stage on which the substrate is placed. The crystallinity of the formed metal oxide layer can be increased with a higher proportion of the flow rate of an oxygen gas to the total flow rate of the film formation gas used at the time of formation (hereinafter also referred to as a higher oxygen flow rate ratio) or with higher oxygen partial pressure in a processing chamber.

The semiconductor layer 108 and the semiconductor layer 208 may have a stacked-layer structure of two or more metal oxide layers having different crystallinities. For example, a stacked-layer structure of a first metal oxide layer and a second metal oxide layer provided over the first metal oxide layer can be employed: the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

The thicknesses of the semiconductor layer 108 and the semiconductor layer 208 are each preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm.

In the case where the semiconductor layer 108 and the semiconductor layer 208 are formed using an oxide semiconductor, hydrogen contained in the oxide semiconductor reacts with oxygen bonded to a metal atom to be water, and thus sometimes forms an oxygen vacancy (V_{O}) in the oxide semiconductor. In some cases, a defect that is an oxygen vacancy into which hydrogen enters (hereinafter referred to as V_{O}H) functions as a donor and generates an electron serving as a carrier. In other cases, bonding of part of hydrogen to oxygen bonded to a metal atom generates electrons serving as carriers. Thus, a transistor using an oxide semiconductor that contains a large amount of hydrogen is likely to have normally-on characteristics. Moreover, hydrogen in an oxide semiconductor is easily transferred by a stress such as heat or an electric field; thus, a large amount of hydrogen in an oxide semiconductor might cause a reduction of the transistor reliability.

In the case where an oxide semiconductor is used for the semiconductor layer 108 and the semiconductor layer 208, the amount of VoH in the semiconductor layer 108 and the semiconductor layer 208 is preferably reduced as much as possible so that the semiconductor layer 108 and the semiconductor layer 208 become highly purified intrinsic or substantially highly purified intrinsic semiconductor layers. In order to obtain such an oxide semiconductor with sufficiently reduced VoH, it is important to remove impurities such as water and hydrogen in the oxide semiconductor (which is sometimes described as dehydration or dehydrogenation treatment) and to fill oxygen vacancies by supplying oxygen to the oxide semiconductor. When an oxide semiconductor with a sufficiently reduced amount of impurities such as VoH is used for the channel formation region of the transistor, the transistor can have stable electrical characteristics. Note that filling oxygen vacancies by supplying oxygen to an oxide semiconductor is sometimes referred to as oxygen adding treatment.

When an oxide semiconductor is used for the semiconductor layer 108 and the semiconductor layer 208, the carrier concentration of the oxide semiconductor in the region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1× 10⁻⁹ cm⁻³.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be retained for a long period. Furthermore, a semiconductor device can have lower power consumption by including the OS transistor.

A change in electrical characteristics of an OS transistor due to irradiation with radiation is small: in other words, an OS transistor has high resistance to radiation. Thus, an OS transistor can be suitably used even in an environment where radiation might enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, neutron beams, and proton beams).

Examples of silicon that can be used for the semiconductor layer 108 and the semiconductor layer 208 include single crystal silicon, polycrystalline silicon, microcrystalline silicon, and amorphous silicon. An example of polycrystalline silicon is low-temperature polysilicon (LTPS).

The transistors using amorphous silicon for the semiconductor layer 108 and the semiconductor layer 208 can be formed over a large glass substrate, and can be manufactured at low cost. The transistors including polycrystalline silicon in the semiconductor layer 108 and the semiconductor layer 208 have high field-effect mobility and enable high-speed operation. The transistors including microcrystalline silicon in the semiconductor layer 108 and the semiconductor layer 208 have higher field-effect mobility and enables higher speed operation than the transistor including amorphous silicon.

The semiconductor layer 108 and the semiconductor layer 208 may include a layered material functioning as a semiconductor. The layered material generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe2), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layer 110]

The layers constituting the insulating layer 110 are preferably formed using inorganic insulating films. Examples of the inorganic insulating films include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The composition can be analyzed by secondary ion mass spectrometry (SIMS), X-ray photoelectron spectroscopy (XPS), auger electron spectrometry (AES), or energy dispersive X-ray spectroscopy (EDX), for example. For example, in the case where the content percentage of a target element is high (e.g., higher than or equal to 0.5 atomic %, or higher than or equal to 1 atomic %), XPS can be suitably used. While in the case where the content percentage of a target element is low (e.g., lower than 0.5 atomic %, or lower than 1 atomic %), SIMS can be suitably used. For the composition analysis, a plurality of analysis methods are further preferably used. For example, it is further preferable to perform a combined analysis of SIMS and XPS.

The insulating layer 110 includes a portion that is in contact with the semiconductor layer 108. In the case where the semiconductor layer 108 is formed using an oxide semiconductor, at least part of the portion that is of the insulating layer 110 and in contact with the semiconductor layer 108 is preferably formed using an oxide or an oxynitride to improve the characteristics of the interface between the semiconductor layer 108 and the insulating layer 110. Specifically, the portion that is of the insulating layer 110 and in contact with the channel formation region of the semiconductor layer 108 is preferably formed using an oxide or an oxynitride. The channel formation region is a high-resistance region having a low carrier concentration. The channel formation region can be regarded as being i-type (intrinsic) or substantially i-type.

As the insulating layer 110b, a layer containing oxygen is preferably used. It is preferable that the insulating layer 110b include a region having a higher oxygen content than at least one of the insulating layers 110a and 110c. It is particularly preferable that the insulating layer 110b include a region having a higher oxygen content than each of the insulating layers 110a and 110c.

The insulating layer 110b is preferably formed using any one or more of the oxide insulating films and oxynitride insulating films described above. Specifically, as the insulating layer 110b, one or both of a silicon oxide film and a silicon oxynitride film are preferably used. By having a high oxygen content, the insulating layer 110b can facilitate formation of an i-type region in the region of the semiconductor layer 108 that is in contact with the insulating layer 110b and the vicinity of this region.

It is further preferable that a film which releases oxygen by heating be used as the insulating layer 110b. When the insulating layer 110b releases oxygen by heat applied during the manufacturing process of the transistor 100, the oxygen can be supplied to the semiconductor layer 108. Supplying oxygen from the insulating layer 110b to the semiconductor layer 108, particularly to the channel formation region in the semiconductor layer 108, can allow the amount of oxygen vacancies (V_{O}) and V_{O}H to be reduced in the semiconductor layer 108, so that a highly reliable transistor having favorable electrical characteristics can be provided.

For example, the insulating layer 110b can be supplied with oxygen when heat treatment in an oxygen-containing atmosphere or plasma treatment in an oxygen-containing atmosphere is performed. Alternatively, an oxide film may be formed over the top surface of the insulating layer 110b by a sputtering method in an oxygen atmosphere to supply oxygen. After that, the oxide film may be removed.

The insulating layer 110b is preferably formed by a film formation method such as a sputtering method or a plasma-enhanced chemical vapor deposition (PECVD) method. In particular, a sputtering method does not need to use a gas containing hydrogen as a film formation gas, so that a film having an extremely low hydrogen content can be formed. In that case, supply of hydrogen to the semiconductor layer 108 is inhibited and the electrical characteristics of the transistor 100 can be stabilized.

As described above, the channel length L100 of the transistor 100 can be extremely short. Particularly in the case where the channel length L100 is short, oxygen vacancies (V_{O}) and V_{O}H in the channel formation region greatly affect electrical characteristics and reliability. However, supply of oxygen from the insulating layer 110b to the semiconductor layer 108 can at least inhibit an increase in oxygen vacancies (V_{O}) and V_{O}H in the region that is of the semiconductor layer 108 and in contact with the insulating layer 110b. Thus, the transistor with a short channel length having favorable electrical characteristics and high reliability can be provided.

For each of an insulating layer 110a and the insulating layer 110c, a film into which oxygen hardly diffuses is preferably used. Accordingly, it is possible to prevent oxygen included in the insulating layer 110b from being transmitted toward the substrate 102 side through the insulating layer 107 and the insulating layer 110a and being transmitted toward the insulating layer 106 side through the insulating layer 110c due to heating. In other words, when the upper and lower sides of the insulating layer 110b are interposed between the insulating layer 110a and the insulating layer 110c into which oxygen hardly diffuses, oxygen included in the insulating layer 110b can be enclosed. Accordingly, oxygen can be effectively supplied to the semiconductor layer 108.

For each of the insulating layer 110a and the insulating layer 110c, a film into which hydrogen hardly diffuses is preferably used. In that case, hydrogen can be inhibited from diffusing from the outside of the transistor to the semiconductor layer 108 through the insulating layer 110a or the insulating layer 110c.

For each of the insulating layer 110a and the insulating layer 110c, any one or more of the oxide insulating film, nitride insulating film, oxynitride insulating film, and nitride oxide insulating film described above are preferably used, and any one or more of a silicon nitride film, a silicon nitride oxide film, a silicon oxynitride film, an aluminum oxide film, an aluminum oxynitride film, an aluminum nitride film, a hafnium oxide film, and a hafnium aluminate film are preferably used. The silicon nitride film and the silicon nitride oxide film can be particularly suitably used for the insulating layer 110a and the insulating layer 110c because the silicon nitride film and the silicon nitride oxide film release fewer impurities (e.g., water and hydrogen) and are less likely to transmit oxygen and hydrogen. Note that the insulating layer 110b and the insulating layer 110c may be formed using the same material or different materials.

Note that in this specification and the like, different materials mean materials having different constituent elements or materials having the same constituent elements and different compositions.

The conductive layer 103, the conductive layer 112a, and conductive layer 112b are oxidized by oxygen contained in the insulating layer 110c and have high electric resistance in some cases. Providing the insulating layer 110a between the insulating layer 110b and the conductive layer 112a can inhibit the conductive layer 112a from being oxidized and having high electric resistance. In a similar manner, providing the insulating layer 110a between the insulating layer 110b and the conductive layer 103 can inhibit the conductive layer 103 from being oxidized and having high electric resistance. In addition, providing the insulating layer 110c between the insulating layer 110b and the conductive layer 112b can inhibit the conductive layer 112b from being oxidized and having high electric resistance. Accordingly, the amount of oxygen supplied from the insulating layer 110b to the semiconductor layer 108 is increased, whereby the amount of oxygen vacancies in the semiconductor layer 108 can be reduced.

The thicknesses of the insulating layer 110a and the insulating layer 110c are each preferably greater than or equal to 5 nm and less than or equal to 150 nm, further preferably greater than or equal to 5 nm and less than or equal to 100 nm, still further preferably greater than or equal to 5 nm and less than or equal to 70 nm, yet still further preferably greater than or equal to 10 nm and less than or equal to 70 nm, yet still further preferably greater than or equal to 10 nm and less than or equal to 50 nm, yet still further preferably greater than or equal to 20 nm and less than or equal to 50 nm. When the thicknesses of the insulating layer 110a and the insulating layer 110c are in the above-described range, the amount of oxygen vacancies in the semiconductor layer 108, or specifically in the channel formation region, can be reduced.

It is preferable that, for example, the insulating layer 110a and the insulating layer 110c be formed using silicon nitride films and the insulating layer 110a be formed using a silicon oxynitride film.

Note that although a structure where the insulating layer 110 has a four-layer structure is described in this embodiment, one embodiment of the present invention is not limited to this. The insulating layer 110 may have a single-layer structure or a stacked-layer structure of two layers, three layers, or five or more layers. The insulating layer 110 preferably includes at least the insulating layer 110b.

### [Insulating Layer 107]

For the insulating layer 107, a material that can be used for the insulating layer 110 can be used. As the insulating layer 107 in contact with the conductive layer 112a, an insulating layer containing nitrogen is preferably used. For the insulating layer 107, a material that can be used for the insulating layer 110a and the insulating layer 110c can be suitably used. For example, silicon nitride can be suitably used for the insulating layer 107.

Although the insulating layer 107 has a single-layer structure in this embodiment, one embodiment of the present invention is not limited thereto. The insulating layer 107 may have a stacked-layer structure of two or more layers.

### [Insulating Layer 120]

For the insulating layer 120, a material that can be used for the insulating layer 110 can be used. The insulating layer 120 in contact with the semiconductor layer 208 is preferably formed using an insulating layer containing oxygen. For the insulating layer 120, a material that can be used for the insulating layer 110b can be suitably used. For example, silicon oxide or silicon oxynitride can be suitably used for the insulating layer 120.

Although the insulating layer 120 has a single-layer structure in this embodiment, one embodiment of the present invention is not limited thereto. The insulating layer 120 may have a stacked-layer structure of two or more layers. Alternatively, a structure not provided with the insulating layer 120 may be employed.

[Conductive Layer 112a, Conductive Layer 112b, Conductive Layer 103, Conductive Layer 104, Conductive Layer 202, Conductive Layer 204, Conductive Layer 212a, Conductive Layer 212b]

The conductive layer 112a, the conductive layer 112b, the conductive layer 103, the conductive layer 104, the conductive layer 202, the conductive layer 204, the conductive layer 212a, and the conductive layer 212b may each have a single-layer structure or a stacked-layer structure of two or more layers. As a material that can be used for each of the conductive layer 112a, the conductive layer 112b, the conductive layer 103, the conductive layer 104, the conductive layer 202, the conductive layer 204, the conductive layer 212a, and the conductive layer 212b, for example, one or more of chromium, copper, aluminum, gold, silver, zinc, tantalum, titanium, tungsten, manganese, nickel, iron, cobalt, molybdenum, ruthenium, and niobium, or an alloy containing one or more of these metals as its components can be given. For each of the conductive layer 112a, the conductive layer 112b, the conductive layer 103, the conductive layer 104, the conductive layer 202, the conductive layer 204, the conductive layer 212a, and the conductive layer 212b, a conductive material with low resistance that contains one or more of copper, silver, gold, and aluminum can be suitably used. Copper or aluminum is particularly preferable because of its high mass-productivity.

For the conductive layer 112a, the conductive layer 112b, the conductive layer 103, the conductive layer 104, the conductive layer 202, the conductive layer 204, the conductive layer 212a, and the conductive layer 212b, a conductive metal oxide (also referred to as an oxide conductor) can be used. Examples of the oxide conductor (OC) include indium oxide, zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. An oxide conductor containing indium is particularly preferable because of its high conductivity.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 112a, the conductive layer 112b, the conductive layer 103, the conductive layer 104, the conductive layer 202, the conductive layer 204, the conductive layer 212a, and the conductive layer 212b may have a stacked-layer structure of a conductive film containing the oxide conductor (the metal oxide) and a conductive film containing a metal or an alloy. The use of the conductive film containing a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, the conductive layer 103, the conductive layer 104, the conductive layer 202, the conductive layer 204, the conductive layer 212a, and the conductive layer 212b. The use of a Cu—X alloy film enables the manufacturing cost to be reduced because a wet etching method can be used in the processing.

Note that all of the conductive layer 112a, the conductive layer 112b, the conductive layer 103, the conductive layer 104, the conductive layer 202, the conductive layer 204, the conductive layer 212a, and the conductive layer 212b may be formed using the same material or at least one of them may be formed using a different material.

Each of the conductive layer 112a and the conductive layer 112b has a region that is in contact with the semiconductor layer 108. In the case where the semiconductor layer 108 is formed using an oxide semiconductor, when the conductive layer 112a or the conductive layer 112b is formed using a metal that is likely to be oxidized (e.g., aluminum), an insulating oxide (e.g., aluminum oxide) is formed between the conductive layer 112a or the conductive layer 112b and the semiconductor layer 108, which might prevent electrical continuity between the conductive layer 112a or a conductive layer 112b and the semiconductor layer 108. Thus, a conductive material that is less likely to be oxidized or a conductive material that maintains low electric resistance even after being oxidized is preferably used for the conductive layer 112a and the conductive layer 112b.

For each of the conductive layer 112a and the conductive layer 112b, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or conductive materials that maintain low electric resistance even when being oxidized.

The above-described oxide conductor can be used for each of the conductive layer 112a and the conductive layer 112b. Specifically, one or more of indium oxide, zinc oxide, ITO, In—Zn oxide, In—W oxide, In—W—Zn oxide, In—Ti oxide, In—Ti—Sn oxide, In—Sn oxide containing silicon, or zinc oxide to which gallium is added can be used.

For each of the conductive layer 112a and the conductive layer 112b, a nitride conductor may be used. For example, one or more of tantalum nitride and titanium nitride can be used.

The conductive layer 112a and the conductive layer 112b may each have a stacked-layer structure. In the case of the stacked-layer structure, at least a layer on the side that is in contact with the semiconductor layer 108 is preferably formed using a conductive material that is less likely to be oxidized or a conductive material that maintains low electric resistance even after being oxidized. For example, the conductive layer 112a can have a stacked-layer structure of an aluminum film and a titanium film over the aluminum film. The titanium film includes a region in contact with the semiconductor layer 108. The conductive layer 112a can have a stacked-layer structure of a first titanium film, an aluminum film over the first titanium film, and a second titanium film over the aluminum film. The second titanium film includes a region in contact with the semiconductor layer 108.

### [Insulating Layer 106]

The insulating layer 106 may have a single-layer structure or a stacked-layer structure of two or more layers. The insulating layer 106 preferably includes one or more inorganic insulating films. Examples of the inorganic insulating film include an oxide insulating film, a nitride insulating film, an oxynitride insulating film, and a nitride oxide insulating film. For the insulating layer 106, a material that can be used for the insulating layer 110 can be used.

The insulating layer 106 includes a region in contact with the semiconductor layer 108 and the semiconductor layer 208. In the case where the semiconductor layer 108 and the semiconductor layer 208 are formed using an oxide semiconductor, at least the film that is included in the insulating layer 106 and in contact with the semiconductor layer 108 and the semiconductor layer 208 is preferably any of the above-described oxide insulating films and oxynitride insulating films. A film which releases oxygen by heating is further preferably used as the insulating layer 106.

Specifically, in the case where the insulating layer 106 has a single-layer structure, the insulating layer 106 is preferably formed using a silicon oxide film or a silicon oxynitride film.

The insulating layer 106 can have a stacked-layer structure of an oxide insulating film or an oxynitride insulating film on the side that is in contact with the semiconductor layer 108 and the semiconductor layer 208 and a nitride insulating film or a nitride oxide insulating film on the side that is in contact with the conductive layer 104 and the conductive layer 204. As the oxide insulating film or the oxynitride insulating film, for example, a silicon oxide film or a silicon oxynitride film is preferably used. As the nitride insulating film or the nitride oxide insulating film, a silicon nitride film or a silicon nitride oxide film is preferably used.

A silicon nitride film and a silicon nitride oxide film can be suitably used as the insulating layer 106 because the amount of impurities (e.g., water and hydrogen) released from the silicon nitride film and the silicon nitride oxide film themselves is small and the silicon nitride film and the silicon nitride oxide film have a feature of not easily transmitting oxygen and hydrogen. Diffusion of impurities from the insulating layer 106 to the semiconductor layer 108 and the semiconductor layer 208 is inhibited, whereby the transistors can have favorable electrical characteristics and high reliability.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Insulating Layer 195]

It is preferable to use a material that does not easily allow diffusion of impurities for the insulating layer 195 functioning as a protective layer of the transistor 100 and the transistor 200. Providing the insulating layer 195 can effectively inhibit diffusion of impurities into the transistors from the outside and increase the reliability of the display device. Examples of the impurities include water and hydrogen.

The insulating layer 195 can be an insulating layer including an inorganic material or an insulating layer including an organic material. For example, an inorganic material such as an oxide, an oxynitride, a nitride oxide, or a nitride can be suitably used for the insulating layer 195. More specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or more of an acrylic resin and a polyimide resin can be used. As the organic material, a photosensitive material may be used. A stack including two or more of the above insulating films may also be used. The insulating layer 195 may have a stacked-layer structure of an insulating layer including an inorganic material and an insulating layer including an organic material.

### [Substrate 102]

Although there is no significant limitation on the material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. Note that the shape of the semiconductor substrate and an insulating substrate may be circular or square.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of a semiconductor device formed thereover can be separated from the substrate 102 and transferred onto another substrate. In that case, the transistor 100 and the like can be transferred onto a substrate having low heat resistance or a flexible substrate as well.

Structure examples of the semiconductor device and the transistors whose structures are partly different from those of Structure Example 1 described above are described below. Note that description of the same portions as those in Structure Example 1 described above is omitted below in some cases. Furthermore, in drawings that are referred to later, the same hatching pattern is applied to portions having functions similar to those in Structure Example 1 described above, and the portions are not denoted by reference numerals in some cases.

### Structure Example 2

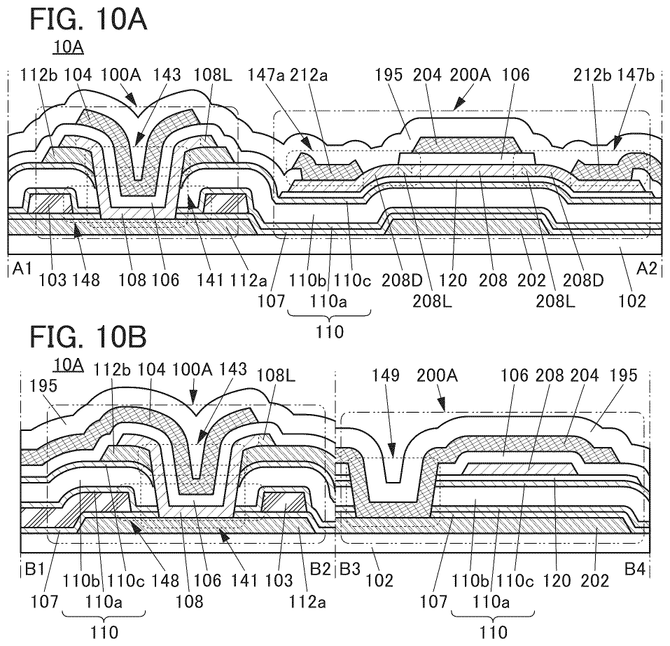

Cross-sectional views of a semiconductor device 10A that is one embodiment of the present invention are illustrated in FIG. 10A and FIG. 10B. FIG. 1A can be referred to for a top view of the semiconductor device 10A. FIG. 10A is a cross-sectional view of a cross section along the dashed-dotted line A1-A2 in FIG. 1A, and FIG. 10B is a cross-sectional view of cross sections along the dashed-dotted line B1-B2 and the dashed-dotted line B3-B4 in FIG. 1A.

The semiconductor device 10A includes a transistor 100A and a transistor 200A. The transistor 100A is different from the transistor 100 illustrated in FIG. 1B and the like mainly in not including the insulating layer 120. The transistor 200A is different from the transistor 200 illustrated in FIG. 1B and the like mainly in that the insulating layer 120 has an island shape. Note that in this specification and the like, an island shape refers to a state where two or more layers formed using the same material in the same step are physically separated from each other.

In the transistor 100A, the conductive layer 112b is provided in contact with the insulating layer 110 (here, the insulating layer 110c). The semiconductor layer 108 is in contact with the top surface of the conductive layer 112a, the side surface of the insulating layer 110, and the top and side surfaces of the conductive layer 112b.

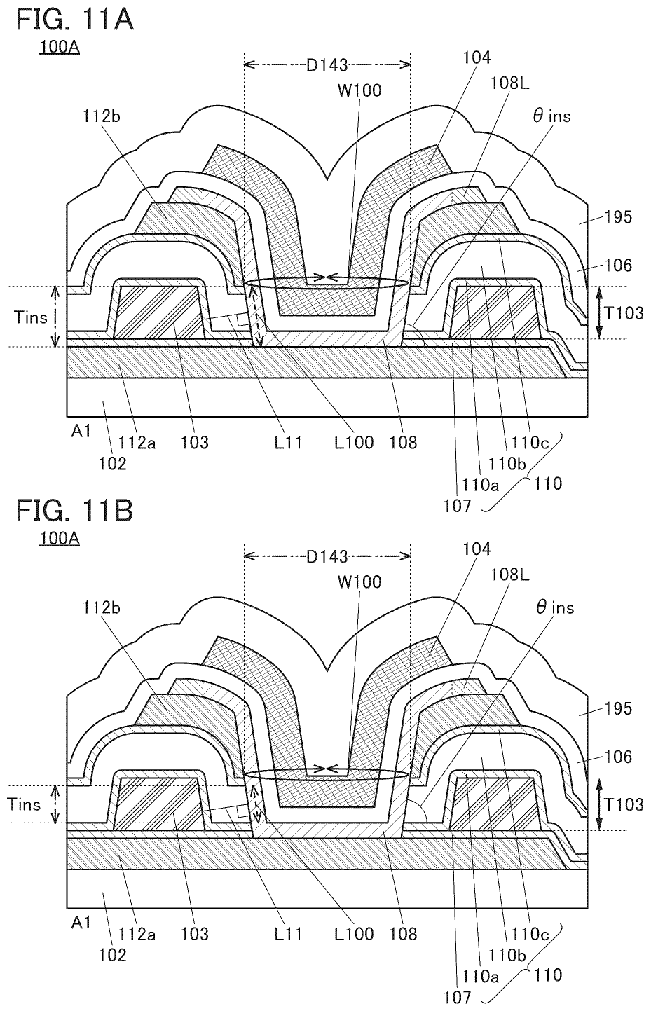

FIG. 11A is an enlarged view of the transistor 100A illustrated in FIG. 10A. In the semiconductor layer 108, a region in contact with the insulating layer 110 functions as the channel formation region. In FIG. 11A, the channel length L100 of the transistor 100A is indicated by a dashed double-headed arrow. The channel length L100 of the transistor 100A is determined by the thickness Tins of the insulating layers in contact with the channel formation region (here, the sum of the thicknesses of the insulating layer 107 and the insulating layer 110) and the angle θins formed between the side surfaces on the opening 141 side of the insulating layers and the formation surface (here, the top surface of the conductive layer 112a) in a cross-sectional view. The thickness Tins and the angle θins are each preferably within the above-described range.

Note that at least one of a region that is of the semiconductor layer 108 and in contact with the insulating layer 107, a region that is of the semiconductor layer 108 and in contact with the insulating layer 110a, and a region that is of the semiconductor layer 108 and in contact with the insulating layer 110c may have a higher carrier concentration and lower resistance than the channel formation region. That is, the region that is of the semiconductor layer 108 and in contact with the insulating layer 107, the region that is of the semiconductor layer 108 and in contact with the insulating layer 110a, and the region that is of the semiconductor layer 108 and in contact with the insulating layer 110c each function as the source region or the drain region in some cases.

For example, when a material that releases impurities (e.g., water or hydrogen) is used for the insulating layer 110c, the region that is of the semiconductor layer 108 and in contact with the insulating layer 110c can function as the source region or the drain region. The same applies to the insulating layer 107 and the insulating layer 110a.

For each of the insulating layer 107, the insulating layer 110a, and the insulating layer 110c, a material that releases impurities (e.g., water or hydrogen) may be used. FIG. 11B illustrates a structure where the region in contact with the insulating layer 107, the region in contact with the insulating layer 110a, and the region in contact with the insulating layer 110c each function as the source region or the drain region. In that case, the region that is of the semiconductor layer 108 and in contact with the insulating layer 110b functions as the channel formation region. The channel length L100 of the transistor 100A is determined by the thickness Tins of the insulating layer in contact with the channel formation region (here, the thickness of the insulating layer 110b) and the angle θins formed between the side surface on the opening 141 side of the insulating layer 110b and the formation surface (here, the top surface of the insulating layer 110a) in a cross-sectional view. The thickness Tins is preferably within the above-described range. The angle θins is preferably within the above-described θins range.

The amount of impurities (e.g., water or hydrogen) released from the insulating layer 107, the amount of impurities released from the insulating layer 110a, and the amount of impurities released from the insulating layer 110c may be different from each other. For example, a material that releases more impurities than the material for the insulating layer 110a can be used for the insulating layer 107. The insulating layer 107 preferably releases hydrogen from itself by heat applied during the process. Hydrogen is supplied from the insulating layer 107 to the region that is of the semiconductor layer 108 and is in contact with the insulating layer 107, so that the electric resistance of the region becomes lower. The region (hereinafter also referred to as a low-resistance region) can function as the source region or the drain region. Providing the low-resistance region on the conductive layer 112a side in the semiconductor layer 108 can make the distance from the source region to the gate electrode and the distance from the drain region to the gate electrode more uniform. Thus, the electric field of the gate electrode applied to the channel formation region can be more uniform.

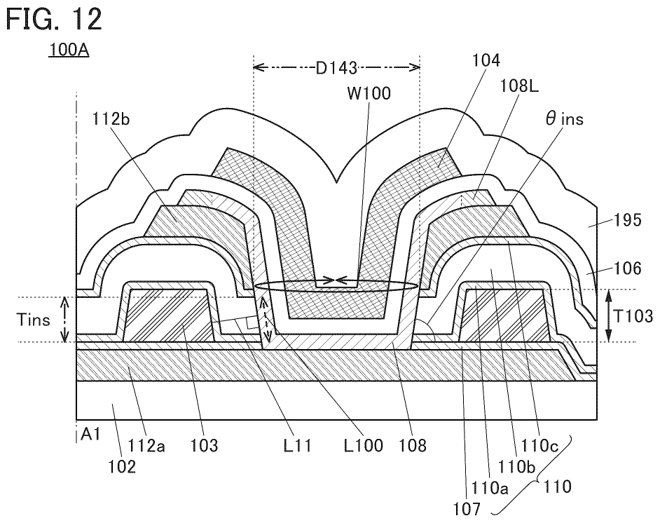

FIG. 12 illustrates a structure where the region in contact with the insulating layer 107 and the region in contact with the insulating layer 110c function as the source region and the drain region. The channel length L100 of the transistor 100A is determined by the thickness Tins of the insulating layers in contact with the channel formation region (here, the sum of the thicknesses of the insulating layer 110a and the insulating layer 110b) and the angle θins formed between the side surface on the opening 141 side of the insulating layer 110a and the formation surface (here, the top surface of the insulating layer 107) in a cross-sectional view. The thickness Tins is preferably within the above-described range. The angle θins is preferably within the above-described θins range.

It is preferable that the amount of impurities released from the insulating layer 110a should be small and impurities should not easily pass through the insulating layer 110a. This inhibits impurities from diffusing into the channel formation region and its vicinity of the semiconductor layer 108 through the insulating layer 110a and the insulating layer 110b, whereby the transistor can have excellent electrical characteristics and high reliability.

The insulating layer 107 preferably includes a region including more hydrogen than the insulating layer 110a. The hydrogen content of the insulating layer 110 (the insulating layer 107, the insulating layer 110a, the insulating layer 110b, and the insulating layer 110c) can be analyzed by secondary ion mass spectrometry (SIMS), for example.

When the film formation conditions for the insulating layer 107 are different from those for the insulating layer 110a, the amount of released hydrogen can be adjusted. Specifically, the film formation conditions for the insulating layer 107 may be different from those for the insulating layer 110a in any one or more of the film formation power (film formation power density), the film formation pressure, the kind of film formation gas, the flow rate ratio of a film formation gas, the film formation temperature, and the distance between the substrate and the electrode during formation. For example, the film formation power density for the insulating layer 110a may be lower than that for the insulating layer 107, in which case the insulating layer 107 can have a higher hydrogen content than the insulating layer 110a. Accordingly, the amount of hydrogen released from the insulating layer 107 due to heat applied thereto can be increased.

The film formation gas used for the formation of the insulating layer 107 preferably contains more hydrogen than the film formation gas used for the formation of the insulating layer 110a. Specifically, in the case of using a PECVD method for forming the insulating layer 110, the proportion of the flow rate of an ammonia gas to the whole film formation gas used for forming the insulating layer 107 (hereinafter also referred to as ammonia flow rate ratio) is preferably higher than the proportion of the flow rate of an ammonia gas to the whole film formation gas used for forming the insulating layer 110a. The formation of the insulating layer 107 under the condition where the ammonia flow rate ratio is high can increase the hydrogen content in the insulating layer 107. Furthermore, the amount of hydrogen released from the insulating layer 107 due to heat applied thereto can be increased.

The film density of the insulating layer 110a is preferably higher than that of the insulating layer 107. The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low: Thus, the transmission electron (TE) image of the insulating layer 110a is a dark-colored (dark) image compared to the insulating layer 107 in some cases. Note that since the insulating layer 107 and the insulating layer 110c have different film densities even when including the same materials, it is sometimes possible to identify the boundary between the insulating layer 107 and the insulating layer 110c by a difference in contrast in a TEM image of a cross section.

In the transistor 200A, the semiconductor layer 208 is provided over the insulating layer 120. As illustrated in FIG. 10A and the like, the insulating layer 120 is preferably provided at least in a region in contact with the channel formation region of the semiconductor layer 208. Alternatively, the insulating layer 120 is preferably provided in a region where the semiconductor layer 208 is provided such that the bottom surface of the semiconductor layer 208 is entirely in contact with the insulating layer 120. It can also be said that the end portion of the semiconductor layer 208 is in contact with the top surface of the insulating layer 120. Note that the entire bottom surface of the semiconductor layer 208 is not necessarily in contact with the insulating layer 120. The end portion of the semiconductor layer 208 may be in contact with the top surface of the insulating layer 110.

Here, as the insulating layer 120 in contact with the semiconductor layer 208, a film which releases oxygen by heating is further preferably used. When the insulating layer 120 releases oxygen by heat applied during the manufacturing process of the transistor 200, the oxygen can be supplied to the semiconductor layer 208. The oxygen supply from the insulating layer 120 to the semiconductor layer 208, particularly to the channel formation region of the semiconductor layer 208, can allow the amount of oxygen vacancies to be reduced in the semiconductor layer 208, so that the transistor can have favorable electrical characteristics and high reliability. However, in the case where the insulating layer 120 includes a region in contact with the conductive layer 112b, the conductive layer 112b might be oxidized by oxygen released from the insulating layer 120 and the conductive layer 112b might have high electric resistance. When the insulating layer 120 does not include the region in contact with the conductive layer 112b, an increase in the electric resistance of the conductive layer 112b can be inhibited.

Note that the structure of the insulating layer 120 described in <Structure Example 2> can also be applied to other structure examples.

### Structure Example 3

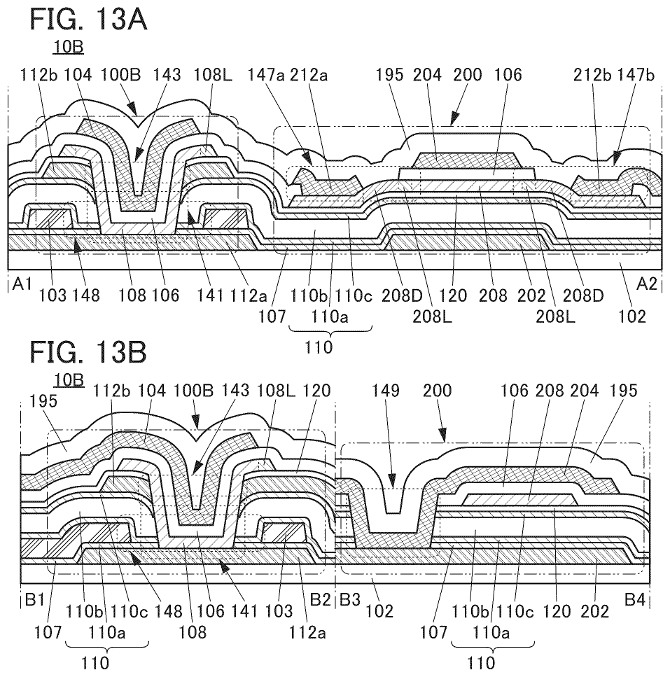

Cross-sectional views of a semiconductor device 10B that is one embodiment of the present invention are illustrated in FIG. 13A and FIG. 13B. FIG. 1A can be referred to for a top view of the semiconductor device 10B. FIG. 13A is a cross-sectional view of a cross section along the dashed-dotted line A1-A2 in FIG. 1A, and FIG. 13B is a cross-sectional view of cross sections along the dashed-dotted line B1-B2 and the dashed-dotted line B3-B4 in FIG. 1A.

The semiconductor device 10B includes a transistor 100B and the transistor 200. The transistor 100B is different from the transistor 100 illustrated in FIG. 1B and the like mainly in that the insulating layer 120 is provided between the semiconductor layer 108 and the conductive layer 112b.

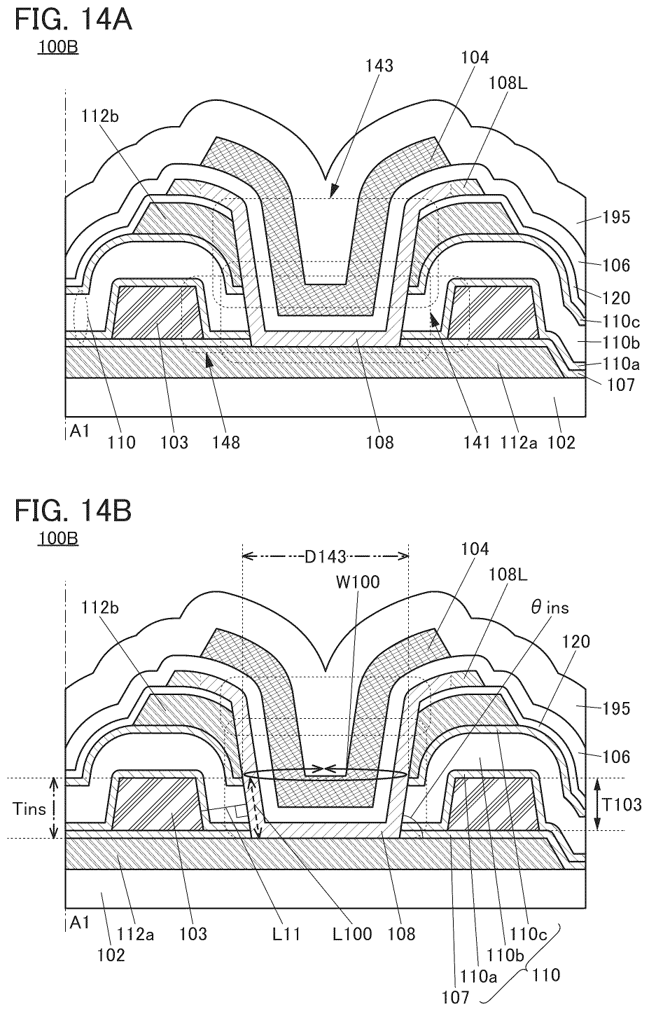

FIG. 14A is an enlarged view of the transistor 100A illustrated in FIG. 13A. The insulating layer 120 is in contact with the top surface of the insulating layer 110 (here, the insulating layer 110c) and the top and side surfaces of the conductive layer 112b. The opening 143 is provided in the conductive layer 112b and the insulating layer 120. For example, after a conductive film to be the conductive layer 112b and an insulating film to be the insulating layer 120 are formed, the conductive film and the insulating film are partly removed, so that the opening 143 can be provided. Note that the opening provided in the insulating layer 120 and the opening provided in the conductive layer 112b may be formed in different steps.

In the semiconductor layer 108, a region in contact with the insulating layer 110 functions as the channel formation region. In FIG. 14B, the channel length L100 of the transistor 100B is indicated by a dashed double-headed arrow: The channel length L100 of the transistor 100B is determined by the thickness Tins of the insulating layer in contact with the channel formation region (here, the thickness of the insulating layer 110) and the angle θins formed between the side surface on the opening 141 side of the insulating layer 110 and the formation surface of the insulating layer 110 (here, the top surface of the conductive layer 112a) in a cross-sectional view. The thickness Tins and the angle θins are each preferably within the above-described range.

Note that when a material that releases impurities (e.g., water or hydrogen) is used for the insulating layer 110c, the region that is of the semiconductor layer 108 and in contact with the insulating layer 110c may function as the source region or the drain region. The same applies to the insulating layer 107 and the insulating layer 110a.

For example, a material that releases impurities (e.g., water or hydrogen) may be used for each of the insulating layer 107, the insulating layer 110a, and the insulating layer 110c so that the region in contact with the insulating layer 107, the region in contact with the insulating layer 110a, and the region in contact with the insulating layer 110c can each function as the source region or the drain region. In that case, as illustrated in FIG. 11B, the region that is of the semiconductor layer 108 and in contact with the insulating layer 110b functions as the channel formation region.

The above description can be referred to for the transistor 200; thus, the detailed description thereof is omitted.

Note that the structure of the insulating layer 120 described in <Structure Example 3> can also be applied to other structure examples.

### Structure Example 4

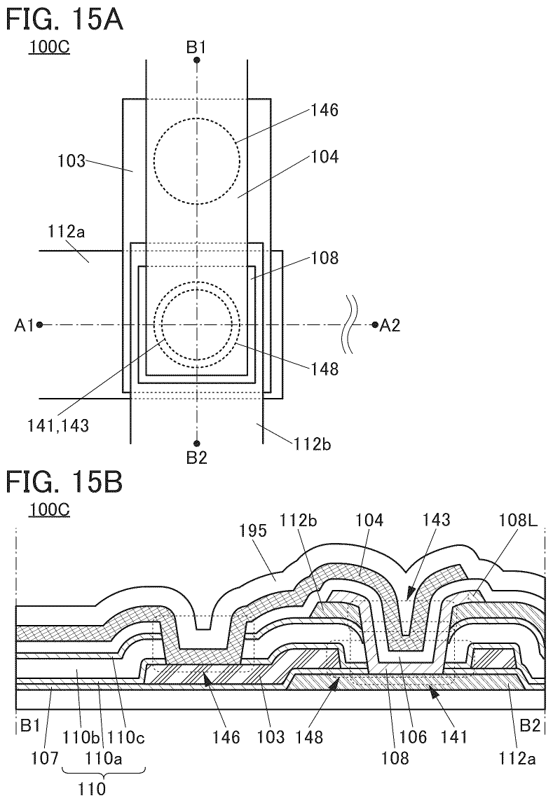

A transistor 100C having a structure different from that of the above-described transistor 100A is described with reference to FIG. 15A and FIG. 15B. FIG. 15A is a top view of the transistor 100C, and FIG. 15B is a cross-sectional view of a cross section along the dashed-dotted line B1-B2 in FIG. 15A. The transistor 100A illustrated in FIG. 10A can be referred to for a cross-sectional view of a cross section along the dashed-dotted line A1-A2.

The transistor 100C is different from the transistor 100A illustrated in FIG. 10A and the like mainly in that the conductive layer 103 and the conductive layer 104 are electrically connected to each other.

As illustrated in FIG. 15B, an opening 146 reaching the conductive layer 103 is provided in the insulating layer 110 and the insulating layer 106. The conductive layer 104 is provided so as to cover the opening 146 and is electrically connected to the conductive layer 103 through the opening 146. When the conductive layer 104 functioning as the gate electrode and the conductive layer 103 functioning as the back gate electrode are electrically connected to each other, the back gate electrode and the gate electrode can have the same potential, so that the on-state current of the transistor 100C can be increased.

Note that the structures of the conductive layer 103 and the conductive layer 104 described in <Structure Example 4> can also be applied to other structure examples.

### Structure Example 5

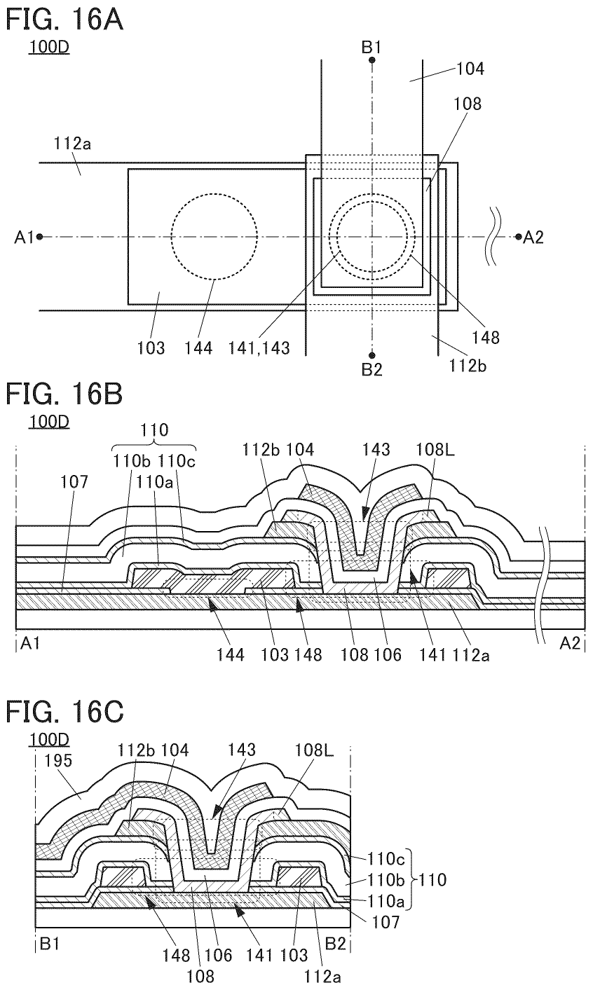

A transistor 100D having a structure different from that of the above-described transistor 100A is described with reference to FIG. 16A to FIG. 16C. FIG. 16A is a top view of the transistor 100D, FIG. 16B is a cross-sectional view of a cross section along the dashed-dotted line A1-A2 in FIG. 16A, and FIG. 16C is a cross-sectional view of a cross section along the dashed-dotted line B1-B2 in FIG. 16A.

The transistor 100D is different from the transistor 100A illustrated in FIG. 10A and the like mainly in that the conductive layer 103 and the conductive layer 112a are electrically connected to each other.

As illustrated in FIG. 16B, an opening 144 reaching the conductive layer 112a is provided in the insulating layer 107. The conductive layer 103 is provided so as to cover the opening 144 and is electrically connected to the conductive layer 112a through the opening 144. When the conductive layer 112a functioning as the source electrode or the drain electrode and the conductive layer 103 functioning as the back gate electrode are electrically connected to each other, the source electrode or the drain electrode can have the same potential as the gate electrode. For example, in the case where the conductive layer 112a functions as the source electrode, the threshold voltage shift of the transistor 100D can be inhibited. Furthermore, the reliability of the transistor 100D can be improved.

Although a structure in which the conductive layer 112a and the conductive layer 103 are electrically connected to each other is described here, one embodiment of the present invention is not limited thereto. An opening reaching the conductive layer 103 may be formed in the insulating layer 110, and the conductive layer 112b may be provided so as to cover the opening. Thus, the conductive layer 112b functioning as the source electrode or the drain electrode is electrically connected to the conductive layer 103 functioning as the back gate electrode.

Note that the structures of the conductive layer 103 and the conductive layer 112a described in <Structure Example 5> can also be applied to other structure examples.

### Structure Example 6

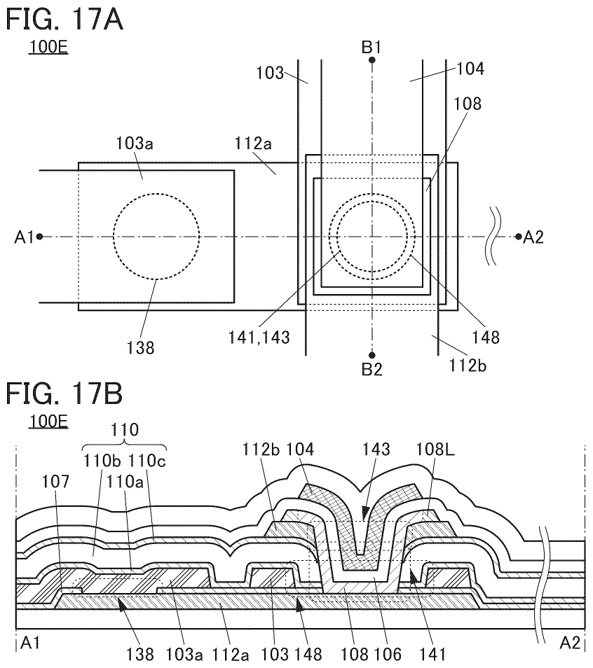

A transistor 100E having a structure different from that of the above-described transistor 100A is described with reference to FIG. 17A and FIG. 17B. FIG. 17A is a top view of the transistor 100E, and FIG. 17B is a cross-sectional view of a cross section along the dashed-dotted line A1-A2 in FIG. 17A. The transistor 100A illustrated in FIG. 10B can be referred to for a cross-sectional view of a cross section along the dashed-dotted line B1-B2.

The transistor 100E is different from the transistor 100A illustrated in FIG. 10A and the like mainly in including a conductive layer 103a.

As illustrated in FIG. 17B, the conductive layer 103a is provided over the insulating layer 107 and includes a region overlapping with the conductive layer 112a. For the conductive layer 103a, a material that can be used for the conductive layer 103 can be used. The conductive layer 103a can be formed in the same steps as the conductive layer 103, for example. For example, the conductive layer 103 and the conductive layer 103a can be formed by forming and processing a conductive film to be the conductive layer 103 and the conductive layer 103a. An opening 138 reaching the conductive layer 112a is provided in the insulating layer 107. The conductive layer 103a is provided so as to cover the opening 138 and is electrically connected to the conductive layer 112a through the opening 138.

The conductive layer 103a functions as an auxiliary wiring of the conductive layer 112a. The conductive layer 103a is preferably formed using a material having higher conductivity than that of the conductive layer 112a. In that case, the conductive layer 103a has a reduced electric resistance and can effectively function as the auxiliary wiring of the conductive layer 112a. For the conductive layer 103a, one or more of copper, aluminum, titanium, tungsten, and molybdenum or an alloy containing one or more of these metals as its components can be suitably used, for example. Note that in the case where the conductive layer 103a is formed through the same steps as the conductive layer 103, the conductive layer 103 is also formed using the material having higher conductivity than that of the conductive layer 112a.

Note that the structure of the conductive layer 103a described in <Structure Example 6> can also be applied to other structure examples.

### Structure Example 7

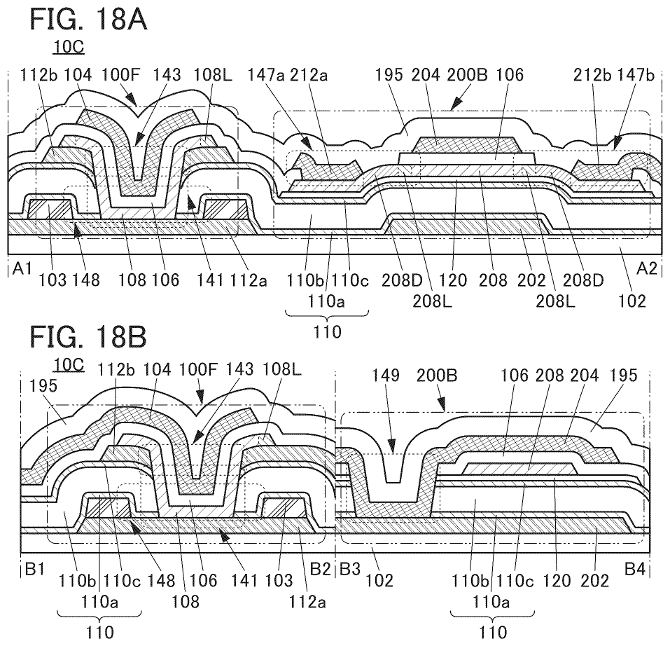

Cross-sectional views of a semiconductor device 10C that is one embodiment of the present invention are illustrated in FIG. 18A and FIG. 18B. FIG. 1A can be referred to for a top view of the semiconductor device 10C. FIG. 18A is a cross-sectional view of a cross section along the dashed-dotted line A1-A2 in FIG. 1A, and FIG. 18B is a cross-sectional view of cross sections along the dashed-dotted line B1-B2 and the dashed-dotted line B3-B4 in FIG. 1A.

The semiconductor device 10F includes a transistor 100F and a transistor 200B. The semiconductor device 10C is different from the semiconductor device 10A illustrated in FIG. 10A and the like mainly in not including the insulating layer 107.

The transistor 100F is different from the above-described transistor 100A mainly in not including the insulating layer 107 between the conductive layer 112a and the conductive layer 103. The conductive layer 103 is provided in contact with the conductive layer 112a. In the transistor 100F, the insulating layer 110 is provided so as to cover the top and side surfaces of the conductive layer 103 and the top and side surfaces of the conductive layer 112a. When the conductive layer 112a functioning as the source electrode or the drain electrode and the conductive layer 103 functioning as the back gate electrode are electrically connected to each other, the source electrode or the drain electrode can have the same potential as the gate electrode.

In the transistor 200B, the insulating layer 110 is provided so as to cover the top and side surfaces of the conductive layer 202.

For example, the conductive layer 103 can be formed in the following manner: a first conductive film to be the conductive layer 112a and the conductive layer 202 is formed, the first conductive film is processed to form the conductive layer 112a and the conductive layer 202, a second conductive film to be the conductive layer 103 is formed, and the second conductive film is processed to form the conductive layer 103. Alternatively, for example, the conductive layer 112a and the conductive layer 103 can be formed in the following manner: a first conductive film to be the conductive layer 112a and the conductive layer 202 and a second conductive film to be the conductive layer 103 are formed, the second conductive film is processed to form the conductive layer 103, and then the first conductive film is processed. For each of the processing of the first conductive film and the processing of the second conductive film, either or both of a wet etching method and a dry etching method can be used. The first conductive film and the second conductive film are preferably formed using different materials. It is further preferable to use a material having high selectivity with respect to the first conductive film in processing the second conductive film. This can inhibit a reduction in the thicknesses of the conductive layer 112a and the conductive layer 202 or the thickness of the first conductive film in processing the second conductive film. Note that the method for processing the first conductive film and the method for processing the second conductive film may be different from each other. For example, a wet etching method can be used for the processing of the first conductive film, and a dry etching 30) method can be used for the processing of the second conductive film. Note that the same processing method but different processing conditions may be used for these processings. Note that the structures of the insulating layer 110, the conductive layer 103, and the conductive layer 112a described in <Structure Example 7> can also be applied to other structure examples.

### Structure Example 8

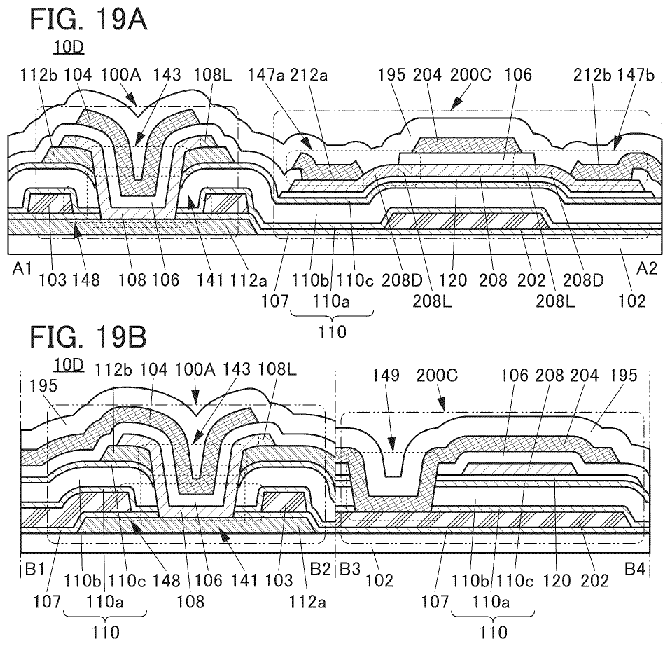

Cross-sectional views of a semiconductor device 10D that is one embodiment of the present invention are illustrated in FIG. 19A and FIG. 19B. FIG. 1A can be referred to for a top view of the semiconductor device 10D. FIG. 19A is a cross-sectional view of a cross section along the dashed-dotted line A1-A2 in FIG. 1A, and FIG. 19B is a cross-sectional view of cross sections along the dashed-dotted line B1-B2 and the dashed-dotted line B3-B4 in FIG. 1A.

The semiconductor device 10D includes the transistor 100A and a transistor 200C. The semiconductor device 10D is different from the semiconductor device 10A illustrated in FIG. 10A and the like mainly in that the conductive layer 202 is provided between the insulating layer 107 and the insulating layer 110a.

The above description can be referred to for the transistor 100A: thus, the detailed description thereof is omitted.

In the transistor 200C, the conductive layer 202 is provided over the insulating layer 107. For the conductive layer 202, the same material as the conductive layer 103 can be used, for example. Furthermore, the conductive layer 202 can be formed in the same steps as the conductive layer 103. The insulating layer 110a is provided so as to cover the top and side surfaces of the conductive layer 202.

For example, in the case where a material having higher conductivity than that of the conductive layer 112a is used for the conductive layer 103, formation of the conductive layer 202 through the same steps as the conductive layer 103 makes the conductive layer 202 also formed of the material having higher conductivity, so that the electric resistance of the conductive layer 202 can be reduced. Furthermore, part of the insulating layer 110a, part of the insulating layer 110b, part of the insulating layer 110c, and part of the insulating layer 120 function as a back gate insulating layer in the transistor 200C. In the case where the conductive layer 202 is provided between the insulating layer 107 and the insulating layer 110a, the thickness of the back gate insulating layer can be reduced as compared with the case where the conductive layer 202 is provided between the substrate 102 and the insulating layer 107. Thus, the electric field of the back gate electrode can be intensified. Furthermore, the saturation of the Id-Vd characteristics of the transistor 200C can be improved. Moreover, the threshold voltage shift of the transistor 200C can be inhibited: accordingly, the cut-off current can be reduced.

Note that the structure of the conductive layer 202 described in <Structure Example 8> can also be applied to other structure examples.

### Structure Example 9

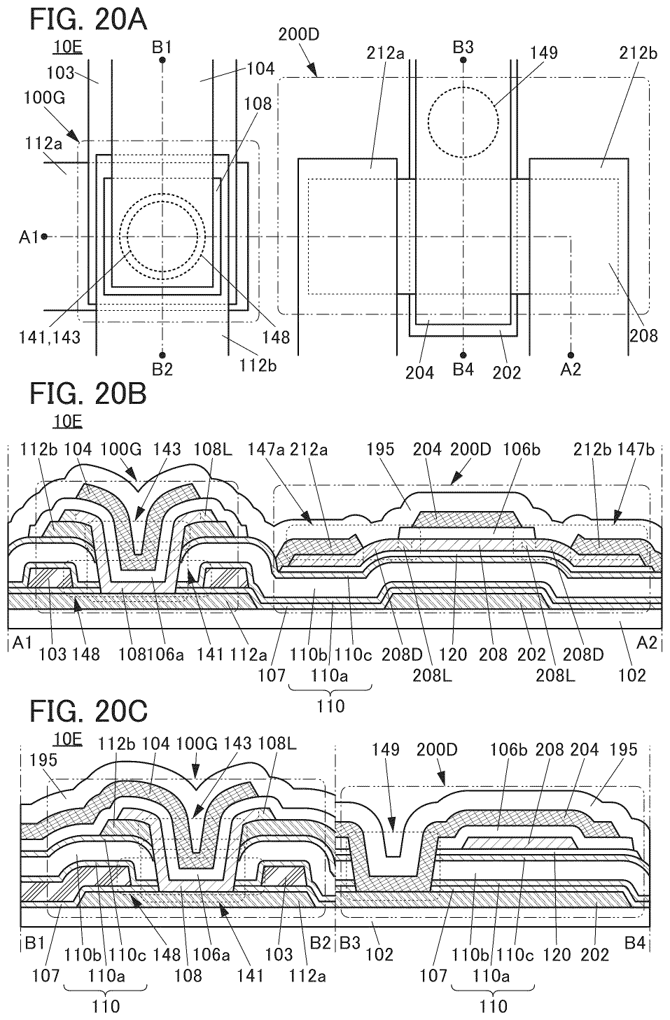

FIG. 20A is a top view of a semiconductor device 10E that is one embodiment of the present invention. FIG. 20B is a cross-sectional view of a cross section along the dashed-dotted line A1-A2 in FIG. 20A, and FIG. 20C is a cross-sectional view of cross sections along the dashed-dotted line B1-B2 and the dashed-dotted line B3-B4 in FIG. 20A.

The semiconductor device 10E includes a transistor 100G and a transistor 200D. The semiconductor device 10E is different from the semiconductor device 10A illustrated in FIG. 10A and the like mainly in including an insulating layer 106a and an insulating layer 106b instead of the insulating layer 106.

The transistor 100G includes the insulating layer 106a between the conductive layer 104 and the semiconductor layer 108. The insulating layer 106a functions as a gate insulating layer of the transistor 100G. The insulating layer 106a is provided at least in a region where the conductive layer 104 and the semiconductor layer 108 overlap with each other.

As illustrated in FIG. 20B and FIG. 20C, the insulating layer 106a may cover the end portion of the semiconductor layer 108. Furthermore, the end portion of the conductive layer 112b may be covered. Specifically, the insulating layer 106a is in contact with the top and side surfaces of the semiconductor layer 108 and the top and side surfaces of the conductive layer 112b. An end portion of the insulating layer 106a is in contact with the top surface of the insulating layer 110. When the insulating layer 106a covers the semiconductor layer 108 and the conductive layer 112b, the semiconductor layer 108 and the conductive layer 112b can be inhibited from being damaged at the time of forming the conductive layer 104, for example.

The transistor 200D includes the insulating layer 106b between the conductive layer 204 and the semiconductor layer 208. The insulating layer 106b functions as a gate insulating layer of the transistor 200D. The insulating layer 106b is provided at least in a region where the conductive layer 204 and the semiconductor layer 208 overlap with each other. The end portion of the conductive layer 204 is preferably in contact with the top surface of the insulating layer 106b. The insulating layer 106b and the insulating layer 106a can be formed through the same steps. For example, the insulating layer 106a and the insulating layer 106b can be formed by forming an insulating film to be the insulating layer 106a and the insulating layer 106b and processing the conductive film. For the insulating layer 106a and the insulating layer 106b, the material that can be used for the insulating layer 106 can be used.

Note that the structures of the insulating layer 106a and the insulating layer 106b described in <Structure Example 9> can also be applied to other structure examples.

### Structure Example 10

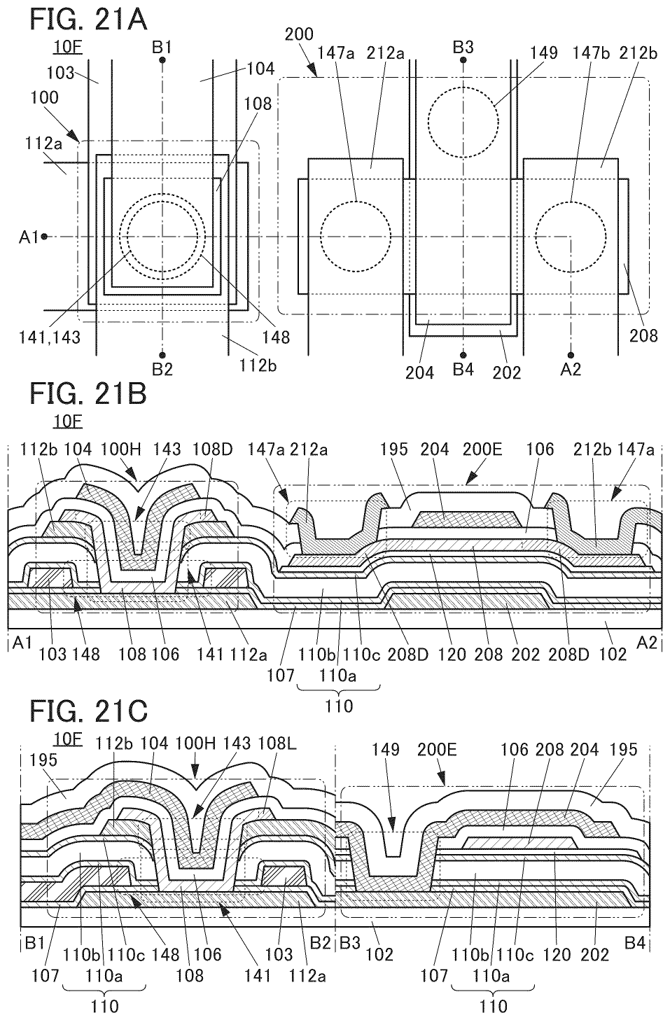

FIG. 21A is a top view of a semiconductor device 10F that is one embodiment of the present invention. FIG. 21B is a cross-sectional view of a cross section along the dashed-dotted line A1-A2 in FIG. 21A, and FIG. 21C is a cross-sectional view of cross sections along the dashed-dotted line B1-B2 and the dashed-dotted line B3-B4 in FIG. 21A.

The semiconductor device 10F includes a transistor 100H and a transistor 200E. The semiconductor device 10F is different from the semiconductor device 10A illustrated in FIG. 10A and the like mainly in the structures of the conductive layer 212a and the conductive layer 212b.

In the transistor 200E, the conductive layer 212a and the conductive layer 212b are provided so as to cover the opening 147a and the opening 147b provided in the insulating layer 106 and the insulating layer 195. The conductive layer 212a and the conductive layer 212b are formed through steps different from the steps for forming the conductive layer 104 and the conductive layer 204. Note that the conductive layer 212a and the conductive layer 212b may be formed using a material that is the same as or different from the material for the conductive layer 104 and the conductive layer 204.

For example, the conductive layer 204 can be formed over the insulating layer 106, the insulating layer 195 can be formed over the conductive layer 204, the opening 147a and the opening 147b can be formed in the insulating layer 106 and the insulating layer 195, and the conductive layer 212a and the conductive layer 212b can be formed so as to cover the opening 147a and the opening 147b. When the conductive layer 212a and the conductive layer 212b are provided on a surface different from the surface on which the conductive layer 204 is provided, the layout flexibility can be increased.

The regions 208D are provided in the regions that are of the semiconductor layer 208 and do not overlap with the conductive layer 204. For example, after the conductive layer 204 is formed, an impurity element is added to the semiconductor layer 208 with the conductive layer 204 as a mask, whereby the regions 208D can be formed. The impurity element is added to the regions that are of the semiconductor layer 208 and do not overlap with the conductive layer 204 through the insulating layer 106. The opening 147a and the opening 147b are provided in regions overlapping with the regions 208D, and the conductive layer 212a and the conductive layer 212b are in contact with the region 208D in the opening 147a and the opening 147b. Note that there is no particular limitation on the top surface shapes of the opening 147a and the opening 147b.

When the region 208D is formed by adding an impurity element to the semiconductor layer 208, the impurity element may be supplied to the semiconductor layer 108 through the insulating layer 106 with use of the conductive layer 104 as a mask. Consequently, a region 108D is formed in the region that is of the semiconductor layer 108 and does not overlap with the conductive layer 104.

Note that the structures of the conductive layer 212a and the conductive layer 212b described in <Structure Example 10> can also be applied to other structure examples.

### Structure Example 11

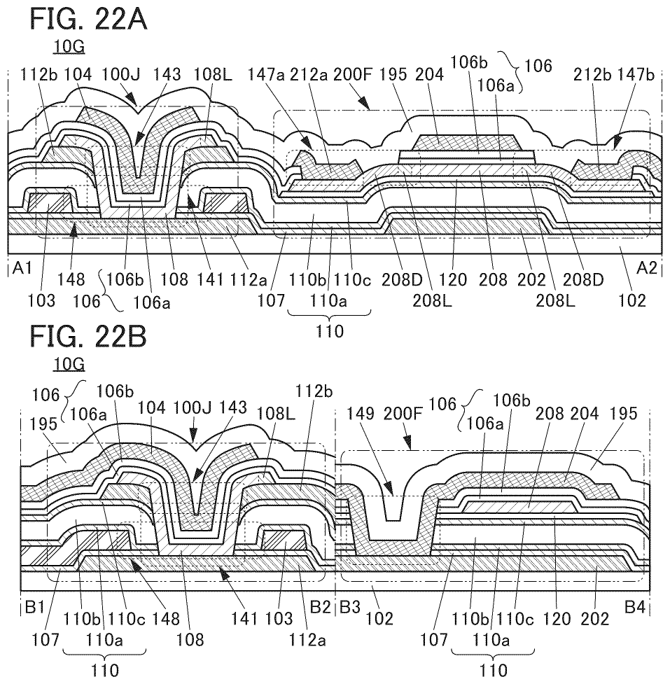

Cross-sectional views of a semiconductor device 10G that is one embodiment of the present invention are illustrated in FIG. 22A and FIG. 22B. FIG. 1A can be referred to for a top view of the semiconductor device 10G. FIG. 22A is a cross-sectional view of a cross section along the dashed-dotted line A1-A2 in FIG. 1A, and FIG. 22B is a cross-sectional view of cross sections along the dashed-dotted line B1-B2 and the dashed-dotted line B3-B4 in FIG. 1A.

The semiconductor device 10G includes a transistor 100J and a transistor 200F. The semiconductor device 10G is different from the semiconductor device 10A illustrated in FIG. 10A and the like mainly in that the insulating layer 106 has a stacked-layer structure.

The insulating layer 106 includes the insulating layer 106a and the insulating layer 106b over the insulating layer 106a. For each of the insulating layer 106a and the insulating layer 106b, the above-described material that can be used for the insulating layer 106 can be used.

It is preferable to use an aluminum oxide film as the insulating layer 106a. Examples of a method for forming the aluminum oxide film include an ALD method, a sputtering method using an aluminum oxide target, and a reactive sputtering method using an aluminum target. An ALD method is preferably used, in which case a dense film with few cracks and pinholes can be formed. The use of a sputtering method is preferable because of its high productivity. Alternatively, for example, an aluminum oxide film may be formed in the following manner: an aluminum film with a thickness greater than or equal to 0.1 nm and less than or equal to 5 nm is formed, and then the aluminum film is oxidized.

When an aluminum oxide film is used as the insulating layer 106a in contact with the semiconductor layer 108 and the semiconductor layer 208, aluminum can exist at an interface between the insulating layer 106 and the semiconductor layer 108, at an interface between the insulating layer 106 and the semiconductor layer 208, and in the vicinities of these interfaces. Specifically, aluminum might exist at the interface between the insulating layer 106 and the semiconductor layer 108 and in the vicinity thereof and at the interface between the insulating layer 106 and the semiconductor layer 208 and in the vicinity thereof. In addition, aluminum enters the semiconductor layer 108 and the semiconductor layer 208 in some cases. For example, in the case where IGZO is used for the semiconductor layer 108 and the semiconductor layer 208, aluminum enters the surface of the IGZO and the vicinity thereof, so that part of the semiconductor layer 108 and part of the semiconductor layer 208 sometimes contain IGZAO. Thus, the semiconductor layer 108 and the semiconductor layer 208 apparently have a stacked-layer structure of IGZO and IGZAO and have a wider band gap than the single-layer structure of IGZO; in other word, the wide-gap semiconductor layer 108 and the wide-gap semiconductor layer 208 are formed. When the band gaps of the semiconductor layer 108 and the semiconductor layer 208 are widened, the off-state current of the transistors can be reduced.

It is preferable to use, for example, a silicon oxynitride film as the insulating layer 106b. The silicon oxynitride film can be formed by a PECVD method, for example.

Note that although an example where the insulating layer 106 has a two-layer structure is described here, one embodiment of the present invention is not limited to this. The insulating layer 106 may have a stacked-layer structure of three or more layers.

For example, the insulating layer 106 can have a three-layer structure of the insulating layers 106a and 106b described above and an insulating layer over the insulating layer 106b. For the insulating layer, a material into which a metal element contained in the conductive layer 104 and the conductive layer 204 does not easily diffuse is preferably used. This can inhibit the metal element contained in the conductive layer 104 and the conductive layer 204 from diffusing into the channel formation regions and their vicinities of the semiconductor layer 108 and the semiconductor layer 208. A nitride insulating film or a nitride oxide insulating film can be suitably used as the insulating layer, for example. Specifically, the insulating layer 106 can have a three-layer structure in which an aluminum oxide film, a silicon oxynitride film, and a silicon nitride film are stacked in this order.

Note that the structure of the insulating layer 106 described in <Structure Example 11> can also be applied to other structure examples.

### Structure Example 12

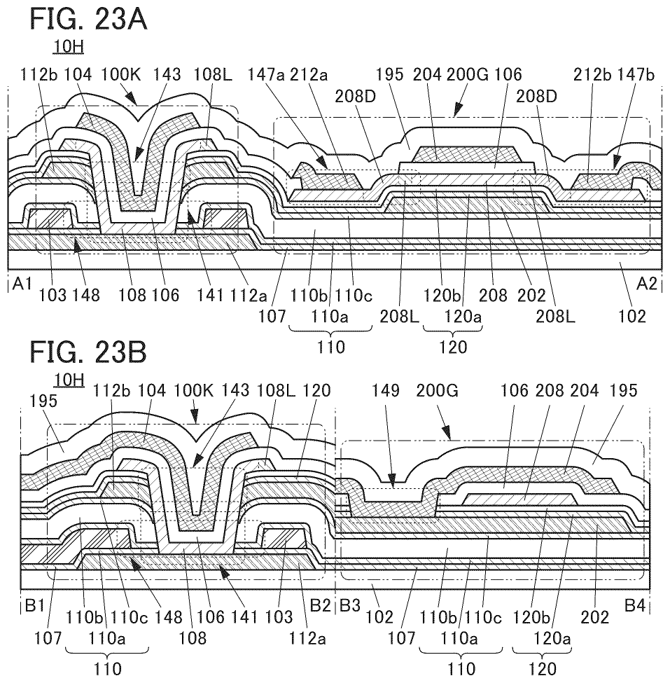

Cross-sectional views of a semiconductor device 10H that is one embodiment of the present invention are illustrated in FIG. 23A and FIG. 23B. FIG. 1A can be referred to for a top view of the semiconductor device 10H. FIG. 23A is a cross-sectional view of a cross section along the dashed-dotted line A1-A2 in FIG. 1A, and FIG. 23B is a cross-sectional view of cross sections along the dashed-dotted line B1-B2 and the dashed-dotted line B3-B4 in FIG. 1A.

The semiconductor device 10H includes a transistor 100K and a transistor 200G. The semiconductor device 10H is different from the semiconductor device 10B illustrated in FIG. 13A and the like mainly in that the conductive layer 202 is provided between the insulating layer 110 and the insulating layer 120.

In the transistor 200G, the conductive layer 202 is provided over the insulating layer 110. For the conductive layer 202, the same material as the conductive layer 112b can be used, for example. Furthermore, the conductive layer 202 can be formed through the same steps as the conductive layer 112b. The insulating layer 120 is provided so as to cover the top and side surfaces of the conductive layer 202. The semiconductor layer 208 is provided over the insulating layer 120.

In the transistor 200G, part of the insulating layer 120 functions as a back gate insulating layer. When the conductive layer 202 is provided between the insulating layer 110 and the insulating layer 120, the thickness of the back gate insulating layer of the transistor 200G can be reduced. Thus, the electric field of the back gate electrode can be intensified. Furthermore, the saturation of the Id-Vd characteristics of the transistor 200G can be improved. Moreover, the threshold voltage shift of the transistor 200G can be inhibited: accordingly, the cut-off current can be reduced.

The insulating layer 120 preferably has a stacked-layer structure. FIG. 23A and FIG. 23B illustrate an example in which the insulating layer 120 has a stacked-layer structure of an insulating layer 120a and an insulating layer 120b over the insulating layer 120a.

For the insulating layer 120a provided in contact with the conductive layer 202 and the conductive layer 112b, a material into which a metal element contained in the conductive layer 202 and the conductive layer 112b does not easily diffuse is preferably used. This inhibits the metal element contained in the conductive layer 202 and the conductive layer 112b from diffusing into the channel formation regions and their vicinities of the semiconductor layer 108 and the semiconductor layer 208. For the insulating layer 120a, a material that can be used for the insulating layer 110a and the insulating layer 110c can be suitably used. For the insulating layer 120a, silicon nitride can be suitably used, for example.

As the insulating layer 120b including the region in contact with the channel formation region of the semiconductor layer 208, an insulating layer containing oxygen is preferably used. For the insulating layer 120b, a material that can be used for the insulating layer 110b can be suitably used. For example, silicon oxide or silicon oxynitride can be suitably used for the insulating layer 120b.

In the transistor 100K, the insulating layer 120a is provided to cover the top and side surfaces of the conductive layer 112b. The insulating layer 120b is provided over the insulating layer 120a. Note that part of the insulating layer 120b may be removed so that the semiconductor layer 108 is not in contact with the insulating layer 120b. In this case, the end portion of the semiconductor layer 108 is in contact with the top surface of the insulating layer 120a. Alternatively, part of the insulating layer 120 may be removed so that the semiconductor layer 108 is not in contact with the insulating layer 120.

Although the insulating layer 120 has a stacked-layer structure of two layers in this embodiment, one embodiment of the present invention is not limited thereto. The insulating layer 120 may have a single-layer structure or a stacked-layer structure of three or more layers.

Note that the structure of the conductive layer 202 described in <Structure Example 12> can also be applied to other structure examples. The structure of the insulating layer 120 can also be applied to other structure examples.

### Structure Example 13

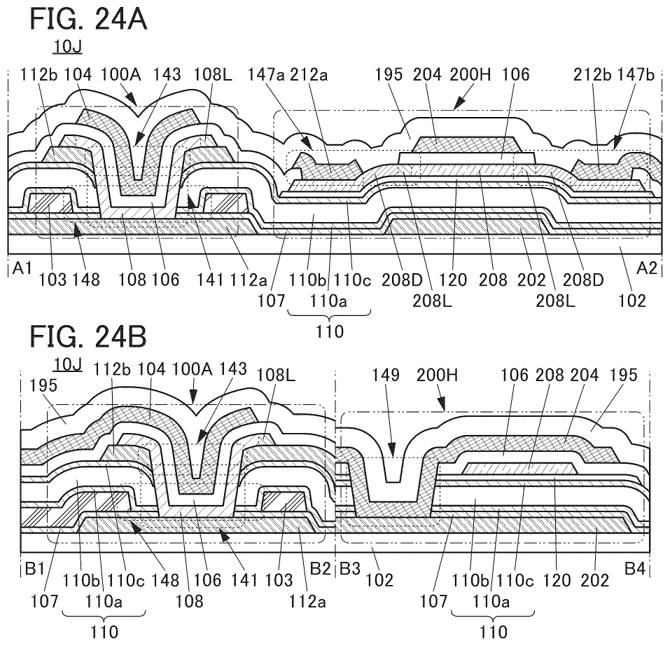

Cross-sectional views of a semiconductor device 10J that is one embodiment of the present invention are illustrated in FIG. 24A and FIG. 24B. FIG. 1A can be referred to for a top view of the semiconductor device 10J. FIG. 24A is a cross-sectional view of a cross section along the dashed-dotted line A1-A2 in FIG. 1A, and FIG. 24B is a cross-sectional view of cross sections along the dashed-dotted line B1-B2 and the dashed-dotted line B3-B4 in FIG. 1A.

The semiconductor device 10J includes the transistor 100A and a transistor 200H. The semiconductor device 10J is different from the semiconductor device 10A illustrated in FIG. 10A and the like mainly in that the semiconductor layer 108 included in the transistor 100A and the semiconductor layer 208 included in the transistor 200H contain different materials. In FIG. 24A and FIG. 24B, the semiconductor layer 108 and the semiconductor layer 208 are illustrated with different hatching patterns.

The semiconductor layer 108 and the semiconductor layer 208 are formed through different steps. For example, the semiconductor layer 208 can be formed after the semiconductor layer 108 is formed. Alternatively, the semiconductor layer 108 may be formed after the semiconductor layer 208 is formed. Note that the semiconductor layer 108 and the semiconductor layer 208 may be formed using the same material through different steps. As described above, electrical characteristics and reliability of a transistor depend on the material used for the semiconductor layer. For example, in the case where a first metal oxide is used for the semiconductor layer 108 and a second metal oxide is used for the semiconductor layer 208, the indium content percentage of the first metal oxide can be higher than the indium content percentage of the second metal oxide. This can increase the on-state current of the transistor 100A. When the indium content percentage of the second metal oxide is lower than the indium content percentage of the first metal oxide, the saturation of the Id-Vd characteristics of the transistor 200H can be improved. Specifically, an In—Ga—Zn oxide having an atomic ratio of 4:2:3 or in the neighborhood thereof can be used as the first metal oxide, and an In—Ga—Zn oxide having an atomic ratio of 1:1:1 or in the neighborhood thereof can be used as the second metal oxide. Alternatively, an In—Zn oxide having an atomic ratio of 1:1 or in the neighborhood thereof can be used as the first metal oxide, and an In—Ga—Zn oxide having an atomic ratio of 1:1:1 or in the neighborhood thereof can be used as the second metal oxide. Alternatively, an In—Zn oxide having an atomic ratio of 4:1 or in the neighborhood thereof can be used as the first metal oxide, and an In—Ga—Zn oxide having an atomic ratio of 1:1:1 or in the neighborhood thereof can be used as the second metal oxide.

In the case where the semiconductor device of one embodiment of the present invention is used for a display device, the transistor 100A can be suitably used for a driver circuit (e.g., one or both of a gate line driver circuit and a source line driver circuit) which requires a high on-state current. The transistor 200H can be suitably used for a pixel circuit which requires favorable saturation. For example, in a pixel circuit of a display device including a light-emitting device, a transistor having a function of controlling a current flowing through the light-emitting device (hereinafter also referred to as a driving transistor) is required to have favorable saturation. The transistor 200H can be suitably used as the driving transistor.

The indium content percentage of the second metal oxide may be higher than the indium content percentage of the first metal oxide. Accordingly, the transistor 200H can have a higher on-state current. Thus, the saturation of the Id-Vd characteristics of the transistor 100A can be improved.

When the channel lengths and materials used for the semiconductor layers are adjusted in accordance with the electrical characteristics and reliability required for the transistor 100A and the transistor 200H, the semiconductor device can have both excellent electrical characteristics and high reliability.

A difference in indium content percentage between the semiconductor layer 108 and the semiconductor layer 208 can be confirmed by EDX, for example. In EDX, the atomic proportion of each element contained in the metal oxide can be calculated. The proportion (content percentage) of the number of indium atoms in the calculated total number of atoms of all the metal elements is compared between the semiconductor layer 108 and the semiconductor layer 208, whereby the difference in indium content percentage can be confirmed. In EDX, the number of counts (the detected value) of a characteristic X-ray corresponds to the proportion of an element contained in a metal oxide. Thus, from the peak heights of indium of the semiconductor layer 108 and the semiconductor layer 208, the difference in indium content percentage can be confirmed. For example, in the case where the indium content percentage of the semiconductor layer 208 is higher than the indium content percentage of the semiconductor layer 108, the number of counts of a characteristic X-ray derived from indium of the semiconductor layer 208 is higher than the number of counts of a characteristic X-ray derived from indium of the semiconductor layer 108. Note that in EDX, the peak of a certain element refers to a point at which the number of counts of the element reaches a local maximum value in a spectrum where the horizontal axis represents the energy of a characteristic X-ray and the vertical axis represents the number of counts of the characteristic X-ray. Alternatively, the number of counts at an energy of a characteristic

X-ray unique to the element may be used to confirm the difference in content percentage. For example, the number of counts at 3.287 keV (In-Lα) can be used for indium.

Although the description has been given by taking the indium content percentage as an example here, the same applies to the content percentages of other elements. In the case where the difference in the content percentage is confirmed using the number of counts at an energy of a characteristic X-ray unique to the element, the number of counts at 9.243 keV (Ga-Kα) can be used for gallium and the number of counts at 8.632 keV (Zn-Kα) can be used for zinc, for example.

Note that the structures of the semiconductor layer 108 and the semiconductor layer 208 described in <Structure Example 13> can also be applied to other structure examples.

Although the transistor 100 to the transistor 100K each include the conductive layer 103 in the structures described above, one embodiment of the present invention is not limited thereto. The conductive layer 103 is not necessarily provided. Similarly, although the transistor 200 to the transistor 200H each include the conductive layer 202 in the structures described above, one embodiment of the present invention is not limited thereto. A structure not provided with the conductive layer 202 may be employed. Furthermore, one or more of the transistor 100 to the transistor 100K including the conductive layer 103, one or more of the transistor 100 to the transistor 100K not including the conductive layer 103, one or more of the transistor 200 to the transistor 200H including the conductive layer 202, and one or more of the transistor 200 to the transistor 200H not including the conductive layer 202 can be combined.

This embodiment can be combined with the other embodiments as appropriate. In this specification, in the case where a plurality of structure examples are shown in one embodiment, the structure examples can be combined as appropriate.

### Embodiment 2

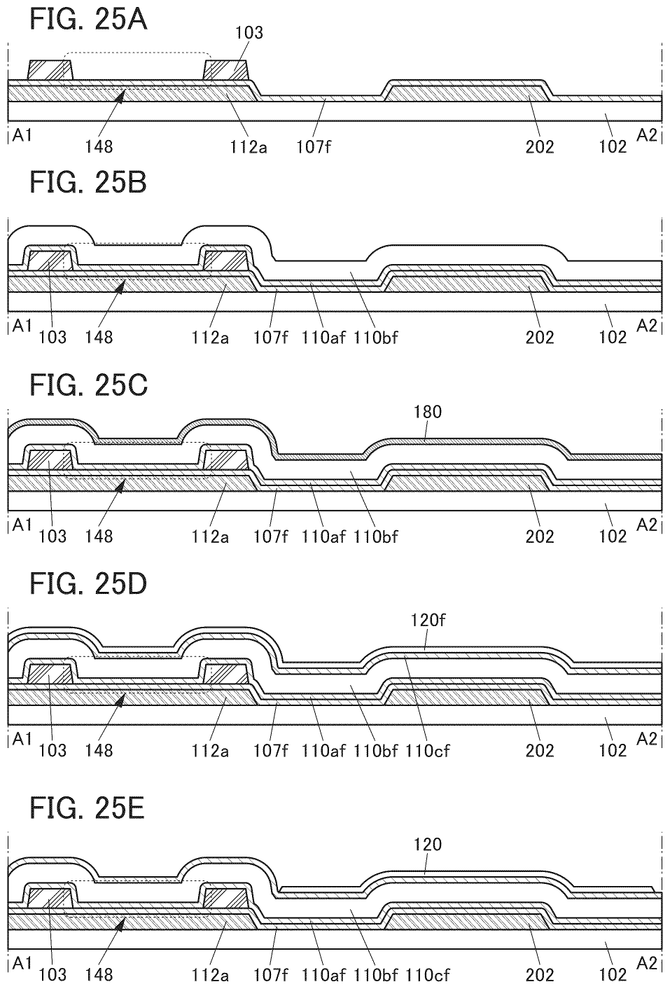

In this embodiment, a method for manufacturing a semiconductor device that is one embodiment of the present invention is described with reference to FIG. 25 to FIG. 34. Note that as for a material and a formation method of each component, portions similar to those described in Embodiment 1 are not described in some cases.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a PECVD method and a thermal CVD method. An example of a thermal CVD method is a metal organic CVD (MOCVD) method.

Thin films included in the semiconductor device (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

When the thin films that form the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of a photolithography method. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for light exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Light exposure may be performed by liquid immersion exposure technique. As the light for the light exposure, extreme ultraviolet (EUV) light or X-rays may also be used. Furthermore, instead of the light used for the light exposure, an electron beam can also be used. EUV light, X-rays, or an electron beam is preferably used to enable extremely minute processing. Note that a photomask is not needed when light exposure is performed by scanning with a beam such as an electron beam.

For etching of thin films, a dry etching method, a wet etching method, a sandblast method, or the like can be used.

### Manufacturing Method Example 1

The manufacturing method is described below taking the semiconductor device 10A illustrated in FIG. 10A or the like as an example.

Each of FIG. 25A to FIG. 28C is a drawing illustrating the method for manufacturing the semiconductor device 10A. Each diagram is a cross-sectional view of a cross section along the dashed-dotted line A1-A2.

First, the conductive layer 112a and the conductive layer 202 are formed over the substrate 102, an insulating film 107f to be the insulating layer 107 is formed over the conductive layer 112a and the conductive layer 202, and the conductive layer 103 is formed over the insulating film 107f (FIG. 25A). The conductive layer 103 is provided with the opening 148 reaching the insulating film 107f.

For the formation of the conductive film to be the conductive layer 112a and the conductive layer 202 and the conductive film to be the conductive layer 103, a sputtering method can be suitably used, for example. A conductive layer can be formed in the following manner: a resist mask is formed over a conductive film by a photolithography process and then, the conductive film is processed. The conductive film can be processed by either or both of a wet etching method and a dry etching method.

Note that in formation of the conductive layer 103, either the step of processing the conductive film to be the conductive layer 103 into a desired shape such as an island shape or the step of providing the opening 148 may be performed first or these steps may be performed at the same time.

Note that part of the insulating film 107f is removed at the time of processing the conductive film to be the conductive layer 103 in some cases. Thus, the thickness of the insulating layer 107 in a region overlapping with the opening 148 is sometimes smaller than the thickness of the insulating layer 107 in a region overlapping with the conductive layer 103 (FIG. 7A). Alternatively, the insulating film 107f may be processed at the time of processing the conductive film to be the conductive layer 103, to form the insulating layer 107 illustrated in FIG. 7B.

For the formation of the insulating film 107f, a sputtering method or a PECVD method can be suitably used, for example.

The substrate temperature at the time of forming the insulating film 107f is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., further preferably higher than or equal to 350° C. and lower than or equal to 400° C. When the substrate temperature at the time of forming the insulating film 107f is in the above-described range, impurities (e.g., water and hydrogen) released from the insulating film 107f itself can be reduced, which inhibits the diffusion of the impurities into the semiconductor layer 108. Consequently, a transistor with favorable electrical characteristics and high reliability can be provided.

Next, an insulating film 110af to be the insulating layer 110a and an insulating film 110bf to be the insulating layer 110b are formed over the conductive layer 103 and the insulating film 107f (FIG. 25B).

For the formation of the insulating film 110af and the insulating film 110bf, a sputtering method or a PECVD method can be suitably used, for example. It is preferable that the insulating film 110bf be formed in a vacuum successively after the formation of the insulating film 110af, without exposure of a surface of the insulating film 110af to the air. By forming the insulating film 110af and the insulating film 110bf successively, attachment of impurities derived from the air to the surface of the insulating film 110af can be inhibited. Examples of the impurities include water and organic substances.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af and the insulating film 110bf are in the above-described range, impurities (e.g., water and hydrogen) released from the insulating films themselves can be reduced, which inhibits diffusion of the impurities into the semiconductor layer 108. Consequently, a transistor with favorable electrical characteristics and high reliability can be provided.

After the insulating film 110bf is formed, oxygen may be supplied to the insulating film 110bf. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include a PECVD apparatus, a plasma etching apparatus, and a plasma ashing apparatus. The plasma treatment is preferably performed in an atmosphere including oxygen. For example, plasma treatment is preferably performed in an atmosphere including one or more of oxygen, dinitrogen monoxide (N₂O), nitrogen dioxide (NO₂), carbon monoxide, and carbon dioxide.

Note that the plasma treatment may be successively performed in a vacuum without exposure of the surface of the insulating film 110bf to the air. For example, in the case where a PECVD apparatus is used to form the insulating film 110bf, the plasma treatment is preferably performed with the PECVD apparatus. Accordingly, the productivity can be increased.

Next, a metal oxide layer 180 is preferably formed over the insulating film 110bf (FIG. 25C). The formation of the metal oxide layer 180 enables oxygen supply to the insulating film 110bf.

There is no limitation on the conductivity of the metal oxide layer 180. As the metal oxide layer 180, at least one of an insulating film, a semiconductor film, and a conductive film can be used. For the metal oxide layer 180, aluminum oxide, hafnium oxide, hafnium aluminate, indium oxide, indium tin oxide (ITO), or indium tin oxide containing silicon (ITSO) can be used, for example.

An oxide material containing one or more kinds of elements that are the same as those in the semiconductor layer 108 and the semiconductor layer 208 is preferably used for the metal oxide layer 180. It is particularly preferable to use an oxide semiconductor material that can be used for the semiconductor layer 108 and the semiconductor layer 208.

At the time of forming the metal oxide layer 180, the amount of oxygen supplied to the insulating film 110af can be increased with a higher flow rate ratio of an oxygen gas of the film formation gas introduced into a processing chamber of a film formation apparatus or with higher oxygen partial pressure in the processing chamber. The oxygen flow rate ratio or the oxygen partial pressure is, for example, higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferred that the oxygen flow rate ratio be 100% and the oxygen partial pressure be as close to 100% as possible.

When the metal oxide layer 180 is formed by a sputtering method in an oxygen-containing atmosphere in the above manner, oxygen can be supplied to the insulating film 110bf and release of oxygen from the insulating film 110bf can be prevented during the formation of the metal oxide layer 180. As a result, a large amount of oxygen can be enclosed in the insulating film 110bf. Moreover, a large amount of oxygen can be supplied to the semiconductor layer 108 by heat treatment performed later. Consequently, the amount of oxygen vacancies and VoH in the semiconductor layer 108 can be reduced, whereby a transistor with favorable electrical characteristics and high reliability can be provided.

After the metal oxide layer 180 is formed, heat treatment may be performed. By the heat treatment performed after the formation of the metal oxide layer 180, oxygen can be effectively supplied from the metal oxide layer 180 to the insulating film 110bf.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating film 107f and the insulating film 110af can be prevented as much as possible. An oven, a rapid thermal annealing (RTA) apparatus, or the like can be used for the heat treatment. With the RTA apparatus, the heat treatment time can be shortened.

After the formation of the metal oxide layer 180 or after the above-described heat treatment, oxygen may be further supplied to the insulating film 110bf through the metal oxide layer 180. As a method for supplying oxygen, an ion implantation method, an ion doping method, a plasma immersion ion implantation method, or plasma treatment can be used, for example. The above description can be referred to for the plasma treatment: thus, the detailed description thereof is omitted.

Then, the metal oxide layer 180 is removed. Although there is no particular limitation on a method for removing the metal oxide layer 180, a wet etching method can be suitably used. With use of a wet etching method, the insulating film 110bf can be inhibited from being etched during the removal of the metal oxide layer 180. This can inhibit a reduction in the thickness of the insulating film 110bf and the thickness of the insulating layer 110a can be uniform.

The treatment for supplying oxygen to the insulating film 110bf is not limited to the above-described methods. For example, an oxygen radical, an oxygen atom, an oxygen atomic ion, an oxygen molecular ion, or the like is supplied to the insulating film 110bf by an ion doping method, an ion implantation method, plasma treatment, or the like. Alternatively, a film that inhibits oxygen release may be formed over the insulating film 110bf, and then oxygen may be supplied to the insulating film 110bf through the film. It is preferable to remove the film after supply of oxygen. As the above-described film that inhibits oxygen release, a conductive film or a semiconductor film including one or more of indium, zinc, gallium, tin, aluminum, chromium, tantalum, titanium, molybdenum, nickel, iron, cobalt, and tungsten can be used.

Next, an insulating film 110cf to be the insulating layer 110c and an insulating film 120f to be the insulating layer 120 are formed over the insulating film 110bf (FIG. 25D). Accordingly, a stacked-layer structure of the insulating film 107f, the insulating film 110af, the insulating film 110bf, and the insulating film 110cf is formed over the conductive layer 112a and the conductive layer 202.

For the formation of the insulating film 110cf and the insulating film 120f, a sputtering method or a PECVD method can be suitably used, for example. It is preferable that the insulating film 120f be formed in a vacuum successively after the formation of the insulating film 110cf, without exposure of a surface of the insulating film 110cf to the air. By forming the insulating film 110cf and the insulating film 120f successively, attachment of impurities derived from the air to the surface of the insulating film 110af can be inhibited. Examples of the impurities include water and organic substances.

Next, the insulating film 120f is processed to form the insulating layer 120 (FIG. 25E). The insulating layer 120 is provided in a region where the semiconductor layer 208 is provided. For the formation of the insulating layer 120, either or both of a wet etching method and a dry etching method can be used. In particular, a dry etching method can be suitably used.

Note that in the case where the insulating film 120f is not processed, the transistor 100 and the transistor 200 illustrated in FIG. 1B and the like can be formed.

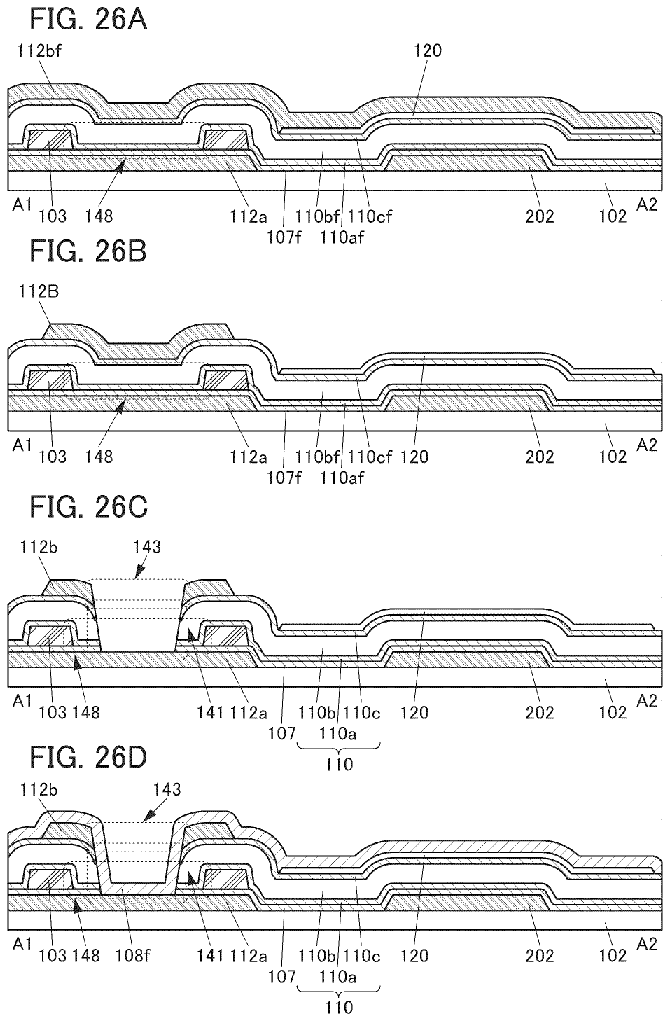

Next, a conductive film 112bf to be the conductive layer 112b is formed over the insulating film 110cf and the insulating layer 120 (FIG. 26A). For the formation of the conductive film 112bf, a sputtering method can be suitably used, for example.

Next, the conductive film 112bf is processed to form a conductive layer 112B (FIG. 26B). The conductive layer 112B becomes the conductive layer 112b later. For the formation of the conductive layer 112B, a wet etching method can be suitably used, for example.

Next, the conductive layer 112B is partly removed, whereby the conductive layer 112b having the opening 143 is formed. The opening 143 is provided in a region overlapping with the opening 148. For the formation of the conductive layer 112b, either or both of a wet etching method and a dry etching method can be used. In particular, a wet etching method can be suitably used.

Next, the insulating film 107f, the insulating film 110af, the insulating film 110bf, and the insulating film 110cf are partly removed, whereby the insulating layer 107 and the insulating layer 110 having the opening 141 are formed (FIG. 26C). The opening 141 is provided in a region overlapping with the opening 143. The opening 141 is provided in a region overlapping with the opening 148, and the conductive layer 112a is exposed by the formation of the opening 141. For the formation of the insulating layer 110, either or both of a wet etching method and a dry etching method can be used. In particular, a dry etching method can be suitably used.

The opening 141 can be formed using the resist mask used for the formation of the opening 143, for example. Specifically, a resist mask is formed over the conductive layer 112B, part of the conductive layer 112B is removed with the use of the resist mask to form the opening 143, and the insulating film 107f, the insulating film 110af, the insulating film 110bf, and the insulating film 110cf are partly removed with the use of the resist mask, whereby the opening 141 can be formed. The opening 143 may be formed using a resist mask that is different from the resist mask used for the formation of the opening 141.

Note that in the formation of the opening 141 or after the formation of the opening 141, the conductive layer 112a in a region overlapping with the opening 141 may be partly removed. When the thickness of the region that is of the conductive layer 112a and in contact with the bottom surface of the semiconductor layer 108 is smaller than the thickness of the region that is of the conductive layer 112a and is not in contact with the semiconductor layer 108, the electric field of the gate electrode applied to the channel formation region in the vicinity of the conductive layer 112a can be intensified and the on-state current of the transistor can be increased. Next, a metal oxide film 108f to be the semiconductor layer 108 and the semiconductor layer 208 is formed so as to cover the opening 141 and the opening 143 (FIG. 26D). The metal oxide film 108f is provided in contact with the top and side surfaces of the conductive layer 112b, the top and side surfaces of the insulating layer 120, the top and side surfaces of the insulating layer 110, and the top surface of the conductive layer 112a.

The metal oxide film 108f is preferably formed by a sputtering method using a metal oxide target. The metal oxide film 108f is preferably formed by an ALD method.

The metal oxide film 108f is preferably a dense film with as few defects as possible. The metal oxide film 108f is preferably a highly purified film in which impurities containing hydrogen elements are reduced as much as possible. It is particularly preferable to use a metal oxide film having crystallinity as the metal oxide film 108f.

In forming the metal oxide film 108f, an oxygen gas is preferably used. In the case of using an oxygen gas at the time of forming the metal oxide film 108f, oxygen can be favorably supplied into the insulating layer 110 and the insulating layer 120. For example, in the case of using an oxide or an oxynitride for the insulating layer 110b, oxygen can be favorably supplied into the insulating layer 110b.

By the supply of oxygen to the insulating layer 110b, oxygen is supplied to the semiconductor layer 108 in a later step, so that the amount of oxygen vacancies and VoH in the semiconductor layer 108 can be reduced. Similarly, by the supply of oxygen to the insulating layer 120, oxygen is supplied to the semiconductor layer 208 in a later step, so that the amount of oxygen vacancies and V_{O}H in the semiconductor layer 208 can be reduced.

In forming the metal oxide film 108f, an oxygen gas and an inert gas (e.g., a helium gas, an argon gas, or a xenon gas) may be mixed. At the time of forming the metal oxide film, the crystallinity of the metal oxide film can be increased and a transistor with higher reliability can be obtained with a higher flow rate ratio of oxygen to the film formation gas or with a higher oxygen partial pressure in a processing chamber. In contrast, when the oxygen flow rate ratio or the oxygen partial pressure is lower, the crystallinity of the metal oxide film is lower and a transistor with higher on-state current can be obtained. For example, with use of different oxygen flow rate ratios or different oxygen partial pressures, a stacked-layer structure of two or more metal oxide layers having different crystallinities can be formed.

In forming the metal oxide film, as the substrate temperature is higher, a denser metal oxide film having higher crystallinity can be formed. In contrast, as the substrate temperature is lower, a metal oxide film having lower crystallinity and higher electric conductivity can be formed.

The substrate temperature during the formation of the metal oxide film 108f is preferably higher than or equal to room temperature and lower than or equal to 250° C., further preferably higher than or equal to room temperature and lower than or equal to 200° C., still further preferably higher than or equal to room temperature and lower than or equal to 140° C. For example, the substrate temperature is preferably higher than or equal to room temperature and lower than or equal to 140° C., in which case productivity is increased. Furthermore, when the metal oxide film is formed with the substrate temperature set at room temperature or without heating the substrate, the crystallinity can be made low.

In the case of employing an ALD method for the formation of the metal oxide film 108f, a film formation method such as a thermal ALD method or a plasma enhanced ALD (PEALD) method is preferably employed. The thermal ALD method is preferable because of its capability of forming a film with extremely high step coverage. The PEALD method is preferable because of its capability of forming a film at low temperatures, in addition to its capability of forming a film with high step coverage.

For example, the metal oxide film can be formed by an ALD method using a precursor including a constituent metal element and an oxidizer.

For example, in the case where an In—Ga—Zn oxide is formed, three precursors, which are a precursor including indium, a precursor including gallium, and a precursor including zinc, can be used. Alternatively, two precursors, which are a precursor including indium and a precursor including gallium and zinc, may be used.

Examples of the precursor including indium include trimethylindium, tris(2,2,6,6-tetramethyl-3,5-heptanedionato) indium, cyclopentadienylindium, indium (III) chloride, and (3-(dimethylamino) propyl)dimethylindium.

Examples of the precursor including gallium include trimethylgallium, triethylgallium, gallium trichloride, tris(dimethylamido) gallium (III), gallium (III) acetylacetonate, tris(2,2,6,6-tetramethyl-3,5-heptanedionato) gallium, dimethylchlorogallium, and diethylchlorogallium. Examples of the precursor including zinc include dimethylzinc, diethylzinc, bis(2,2,6,6-tetramethyl-3,5-heptanedionato) zinc, and zinc chloride.

As examples of the oxidizing agent, ozone, oxygen, and water can be given.

As a method for controlling the composition of a film to be obtained, adjusting one or more of the kinds of source gases, the flow rate ratio of source gases, the flowing time of the source gases, and the order in which the source gases flow is given. By adjusting them, a film whose composition is continuously changed can be formed. Furthermore, films having different compositions can be formed successively.

In the case where the semiconductor layer 108 has a stacked-layer structure, an upper metal oxide film is preferably formed successively after the formation of a lower metal oxide film without exposure of a surface of the lower metal oxide film to the air.

Before the formation of the metal oxide film 108f, at least one of treatment for desorbing water, hydrogen, an organic substance, and the like adsorbed on the surfaces of the insulating layer 110 and the insulating layer 120, and treatment for supplying oxygen into the insulating layer 110 is preferably performed. For example, heat treatment can be performed at a temperature higher than or equal to 70° C. and lower than or equal to 200° C. in a reduced-pressure atmosphere. Alternatively, plasma treatment in an oxygen-containing atmosphere may be performed. Alternatively, oxygen may be supplied to the insulating layer 110 by performing plasma treatment in an atmosphere containing an oxidizing gas such as dinitrogen monoxide (N₂O). When plasma treatment is performed using a dinitrogen monoxide gas, an organic substance on the surface of the insulating layer 110 can be favorably removed and oxygen can be supplied. The metal oxide film 108f is preferably formed successively after such treatment without exposure of the surface of the insulating layer 110 to the air.

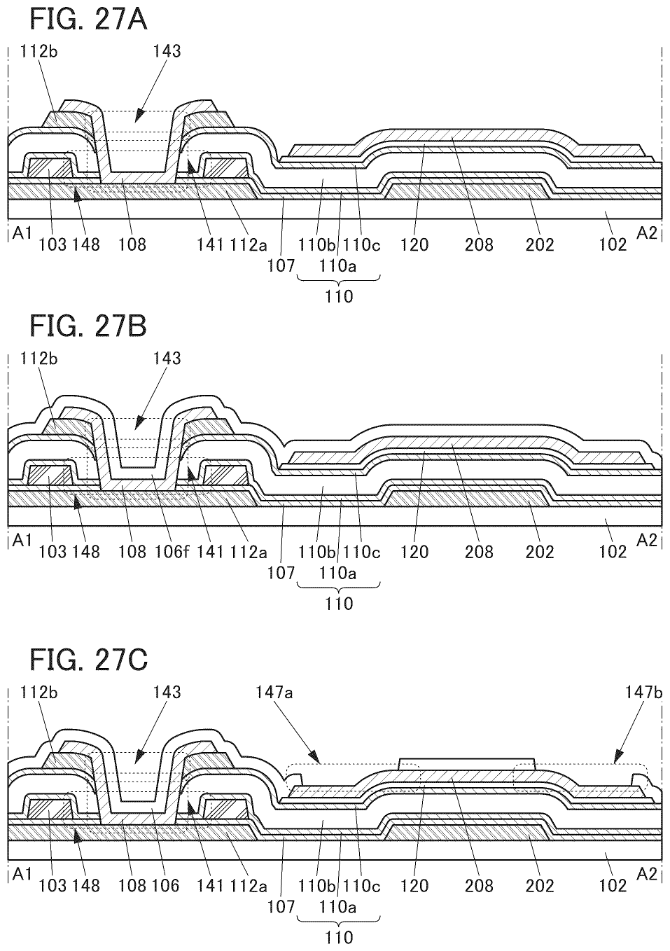

Next, the metal oxide film 108f is processed into an island shape, so that the semiconductor layer 108 and the semiconductor layer 208 are formed (FIG. 27A).

For the formation of the semiconductor layer 108 and the semiconductor layer 208, either or both of a wet etching method and a dry etching method can be used, and for example, a wet etching method can be suitably used. At this time, part of the conductive layer 112b in the region not overlapping with the semiconductor layer 108 is etched and thinned in some cases. Similarly, part of the insulating layer 110 in the region overlapping with none of the semiconductor layer 108 and the conductive layer 112b is etched and thinned in some cases. For example, in the insulating layer 110, the insulating layer 110c is removed by etching and the surface of the insulating layer 110b is exposed, in some cases. Note that in etching of the metal oxide film 108f, a reduction in the thickness of the insulating layer 110c can be inhibited when a material having high selectivity with respect to the insulating layer 110c is used.

It is preferable that heat treatment be performed after the metal oxide film 108f is formed or after the metal oxide film 108f is processed into the semiconductor layer 108 and the semiconductor layer 208. By the heat treatment, hydrogen and water contained in the metal oxide film 108f or the semiconductor layer 108 and the semiconductor layer 208 or adsorbed onto the surface thereof can be removed. Furthermore, the film quality of the metal oxide film 108f or the semiconductor layer 108 and the semiconductor layer 208 is improved (e.g., the number of defects is reduced or the crystallinity is increased) by the heat treatment in some cases.

Oxygen can be supplied from the insulating layer 110b and the insulating layer 120 to the metal oxide film 108f or the semiconductor layer 108 and the semiconductor layer 208 by heat treatment. In this case, it is further preferable that the heat treatment be performed after the metal oxide film 108f is formed but before the metal oxide film 108f is processed into the semiconductor layer 108. This enables the area of the region where the insulating layer 120 and the metal oxide film 108f are in contact with each other to be increased and oxygen to be effectively supplied from the insulating layer 120 to the metal oxide film 108f. The above description can be referred to for the heat treatment: thus, the detailed description thereof is omitted.

Note that the heat treatment is not necessarily performed. Alternatively, the heat treatment is not performed, and heat treatment performed in a later step may also serve as the heat treatment. Alternatively, treatment at a high temperature (e.g., film formation step) in a later step can also serve as the heat treatment in some cases.

Next, an insulating film 106f to be the insulating layer 106 is formed so as to cover the semiconductor layer 108, the semiconductor layer 208, the conductive layer 112b, the insulating layer 120, and the insulating layer 110 (FIG. 27B). For the formation of the insulating film 106f, a PECVD method or an ALD method can be suitably used, for example.

In the case where the semiconductor layer 108 is formed using an oxide semiconductor, the insulating layer 106 preferably functions as a barrier film that inhibits diffusion of oxygen. The insulating layer 106 having a function of inhibiting diffusion of oxygen inhibits diffusion of oxygen into the conductive layer 104 from above the insulating layer 106 and thus can inhibit oxidation of the conductive layer 104. Consequently, a transistor with favorable electrical characteristics and high reliability can be provided.

Note that in this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

When the temperature at the time of forming the insulating film 106f to be the insulating layer 106 functioning as a gate insulating layer is increased, an insulating layer with few defects can be obtained. However, the high temperature at the time of forming the insulating film 106f sometimes allows release of oxygen from the semiconductor layer 108 and the semiconductor layer 208, which increases the amount of oxygen vacancies and VoH in the semiconductor layer 108 and the semiconductor layer 208 in some cases. The substrate temperature at the time of forming the insulating film 106f is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating film 106f is in the above-described range, release of oxygen from the semiconductor layer 108 and the semiconductor layer 208 can be inhibited while defects in the insulating layer 106 can be reduced. Consequently, a transistor with favorable electrical characteristics and high reliability can be provided.

It is preferable to perform plasma treatment on the surfaces of the semiconductor layer 108 and the semiconductor layer 208 before the formation of the insulating film 106f. By the plasma treatment, impurities such as water adsorbed on the surfaces of the semiconductor layer 108 and the semiconductor layer 208 can be reduced. Therefore, impurities at the interface between the semiconductor layer 108 and the insulating layer 106 and the interface between the semiconductor layer 208 and the insulating layer 106 can be reduced, and highly reliable transistors can be provided. The plasma treatment is particularly suitable in the case where the surfaces of the semiconductor layer 108 and the semiconductor layer 208 are exposed to the air in a period between the formation of the semiconductor layer 108 and the semiconductor layer 208 and the formation of the insulating layer 106. The plasma treatment can be performed in an atmosphere of oxygen, ozone, nitrogen, dinitrogen monoxide, argon, or the like, for example. The plasma treatment and the formation of the insulating film 106f are preferably performed successively without exposure to the air.

Next, the insulating film 106f is processed to form the insulating layer 106 (FIG. 27C). The opening 147a and the opening 147b reaching the semiconductor layer 208 are provided in the insulating layer 106. For the formation of the insulating layer 106, either or both of a wet etching method and a dry etching method can be used. In particular, a dry etching method can be suitably used.

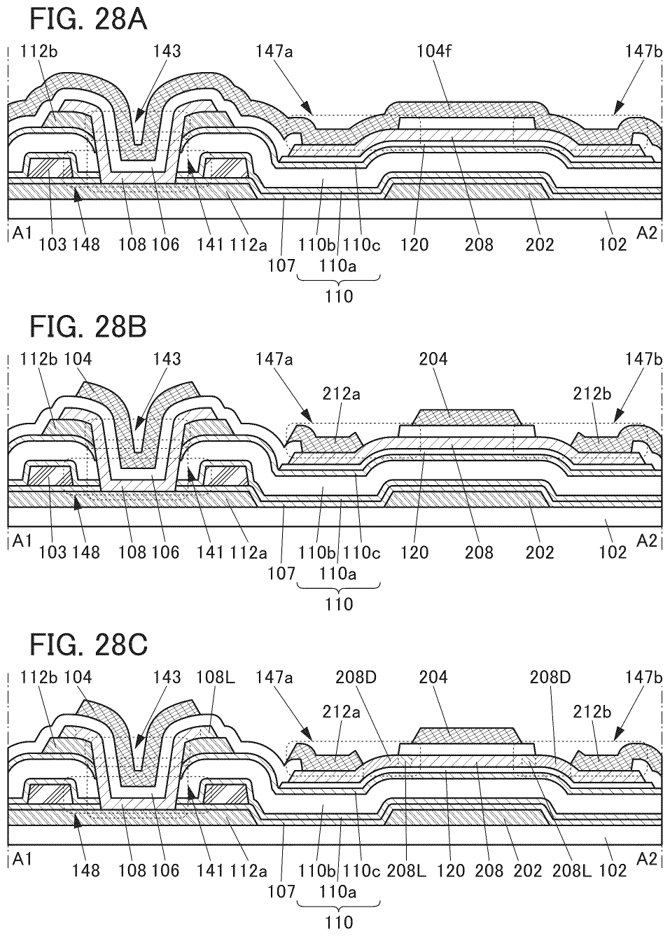

Next, a conductive film 104f to be the conductive layer 104, the conductive layer 204, the conductive layer 212a, and the conductive layer 212b is formed over the insulating layer 106 (FIG. 28A). The conductive film 104f is provided so as to cover the opening 147a and the opening 147b. For the formation of the conductive film 104f, a sputtering method or an ALD method can be suitably used, for example.

Next, the conductive film 104f is processed to form the conductive layer 104, the conductive layer 204, the conductive layer 212a, and the conductive layer 212b (FIG. 28B). For the formation of the conductive layer 104, the conductive layer 204, the conductive layer 212a, and the conductive layer 212b, either or both of a wet etching method and a dry etching method can be used.

Next, an impurity is supplied (or can be expressed as “added” or “injected”) to the semiconductor layer 208 using the conductive layer 204, the conductive layer 212a, and the conductive layer 112b as masks. Thus, the regions 208D are formed in regions that are of the semiconductor layer 208 and overlap with none of the conductive layer 204, the conductive layer 212a, the conductive layer 212b, and the insulating layer 106; and the regions 208L are formed in regions that are of the semiconductor layer 208 and overlap with none of the conductive layer 204, the conductive layer 212a, and the conductive layer 212b and overlap with the insulating layer 106 (FIG. 28C). At this time, the conditions of the treatment for supplying the impurity are preferably determined in consideration of the material and thickness of the conductive layer 204 serving as the mask so that the impurity is supplied as little as possible to the region that is of the semiconductor layer 208 and overlaps with the conductive layer 204. Thus, a channel formation region with a sufficiently reduced impurity concentration can be formed in the region that is of the semiconductor layer 208 and overlaps with the conductive layer 204. Similarly, the semiconductor layer 108 may be supplied with an impurity using the conductive layer 104 as a mask. The region 108L is formed in a region that is of the semiconductor layer 108 and does not overlap with the conductive layer 104 and overlaps with the insulating layer 106.

A plasma ion doping method or an ion implantation method can be suitably used for the supply of the impurity. In these methods, the concentration profile in the depth direction can be controlled with high accuracy by the acceleration voltage and the dosage of ions, or the like. The use of a plasma ion doping method can increase productivity. In addition, the use of an ion implantation method with mass separation can increase the purity of an impurity to be supplied. The conditions of the impurity supply are preferably adjusted so that the impurity concentration at the surface of the semiconductor layer 208 or a portion close to the surface is the highest.

As a source material used for supplying the impurity, a gas containing the above-described impurity element can be used, for example. In the case where boron is supplied, typically, one or more of a B₂H₆ gas and a BF₃ gas can be used. In the case where phosphorus is supplied, typically, a PH₃ gas can be used. A mixed gas in which any of these source gases is diluted with a noble gas may be used.

For example, any of CH₄, N₂, NH₃, AlH₃, AlCl₃, SiH₄, Si₂H₆, F₂, HF, H₂, (C₅H₅)₂Mg, and a noble gas can be used as the source gas for supplying the impurity. Note that the source material is not limited to a gas, and a solid or liquid may be heated and vaporized.

The supply of the impurity can be controlled by setting the conditions such as the acceleration voltage and the dosage in consideration of the compositions, densities, thicknesses, and the like of the insulating layer 106 and the semiconductor layer 208.

For example, in the case where boron is supplied by an ion implantation method or a plasma ion doping method, the acceleration voltage can be, for example, higher than or equal to 5 kV and lower than or equal to 100 kV, preferably higher than or equal to 7 kV and lower than or equal to 70 kV, further preferably higher than or equal to 10 kV and lower than or equal to 50 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

In the case where phosphorus is supplied by an ion implantation method or a plasma ion doping method, the acceleration voltage can be, for example, higher than or equal to 10 kV and lower than or equal to 100 kV, preferably higher than or equal to 30 kV and lower than or equal to 90 kV, further preferably higher than or equal to 40 kV and lower than or equal to 80 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

Note that a method for supplying the impurity is not limited thereto: plasma treatment, treatment using thermal diffusion by heating, or the like may be used, for example. In the case of a plasma treatment method, the impurity can be supplied in such a manner that plasma is generated in a gas atmosphere containing the impurity to be supplied and plasma treatment is performed. A dry etching apparatus, an ashing apparatus, a plasma CVD apparatus, a high-density plasma CVD apparatus, or the like can be used as an apparatus for generating the plasma.

For example, when plasma treatment is performed with a plasma CVD apparatus in an atmosphere containing a hydrogen gas, hydrogen can be supplied as the impurity to the semiconductor layer 208 in a region that does not overlap with the conductive layer 204. With use of a plasma CVD apparatus for the supply of the impurity and the formation of the insulating layer 195, the supply of the impurity and the formation of the insulating layer 195 can be successively performed in the apparatus, so that the productivity can be increased.

Next, the insulating layer 195 is formed to cover the conductive layer 104, the conductive layer 204, the conductive layer 212a, the conductive layer 212b, the insulating layer 106, and the semiconductor layer 208 (FIG. 10A and FIG. 10B). For the formation of the insulating layer 195, a PECVD method can be suitably used.

If the film formation temperature of the insulating layer 195 is too high, impurities contained in the region 108D and the region 208D might diffuse into peripheral portions of the semiconductor layer 108 and the semiconductor layer 208, which include the channel formation regions. Furthermore, electric resistance of the region 108D and the region 208D might be increased. Thus, the film formation temperature of the insulating layer 195 is preferably determined in consideration of the impurity diffusion.

The film formation temperature of the insulating layer 195 is higher than or equal to 150° C. and lower than or equal to 400° C., preferably higher than or equal to 180° C. and lower than or equal to 360° C., further preferably higher than or equal to 200° C. and lower than or equal to 250° C., for example. Film formation of the insulating layer 195 at a low temperature enables the transistors to have favorable electrical characteristics even when they have short channel lengths.

Heat treatment may be performed after the formation of the insulating layer 195. The heat treatment can allow the region 108D and the region 208D to have lower electric resistance, in some cases. For example, by the heat treatment, an impurity diffuses moderately, so that the region 108D and the region 208D each having an ideal concentration gradient of the impurity can be formed. The above description can be referred to for the heat treatment; thus, the detailed description thereof is omitted. Note that when the temperature of the heat treatment is too high (e.g., higher than or equal to 500° C.), an impurity is also diffused into the channel formation region and might cause degradation of the electrical characteristics and reliability of the transistors.

Note that the heat treatment is not necessarily performed. Alternatively, the heat treatment is not performed, and heat treatment performed in a later step may also serve as the heat treatment. Alternatively, in the case where treatment at a high temperature (e.g., film formation step) is performed in a later step, such treatment can also serve as the heat treatment in some cases.

Through the above process, the semiconductor device 10A can be manufactured.

### Manufacturing Method Example 2

A manufacturing method that is different from the above-described method for manufacturing the semiconductor device 10A in <Manufacturing Method Example 1> is described. Note that description of the same portions as those described above is omitted and different portions are described.

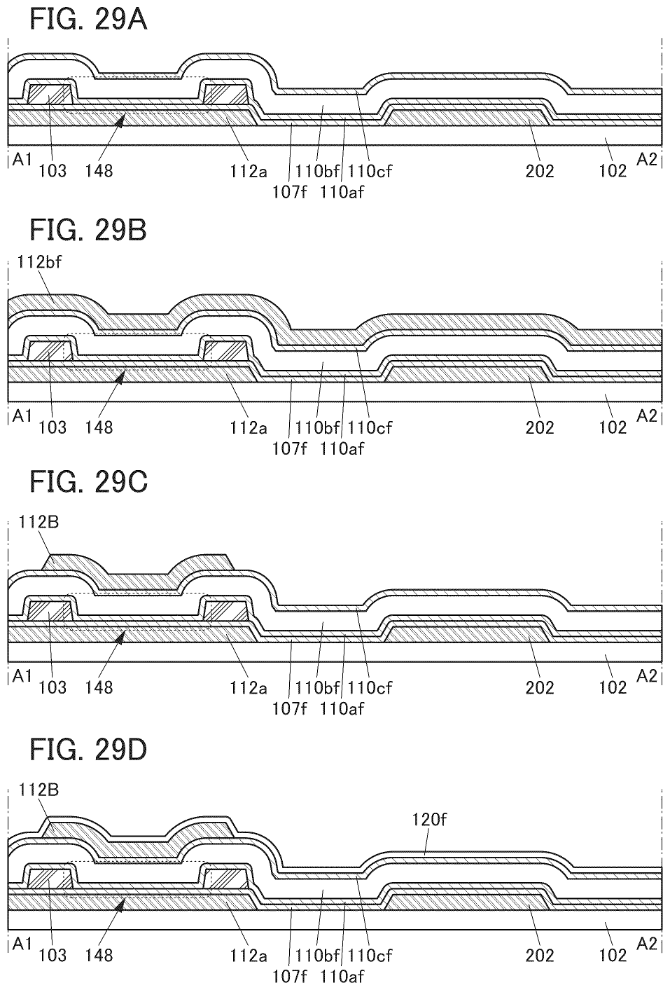

Each of FIG. 29A to FIG. 29D is a drawing illustrating the method for manufacturing the semiconductor device 10A. Each diagram is a cross-sectional view of a cross section along the dashed-dotted line A1-A2.

First, as in <Manufacturing Method Example 1>, the steps up to the formation of the insulating film 110bf are performed. The description of FIG. 25A and FIG. 25B can be referred to for the steps up to the formation of the insulating film 110bf: thus, the detailed description thereof is omitted.

Next, oxygen may be supplied to the insulating film 110bf. The description in <Manufacturing Method Example 1> can be referred to for the method for supplying oxygen: thus, the detailed description thereof is omitted.

Next, the insulating film 110cf to be the insulating layer 110c is formed over the insulating film 110bf (FIG. 29A).

Next, the conductive film 112bf to be the conductive layer 112b is formed over the insulating film 110cf (FIG. 29B).

Next, the conductive film 112bf is processed to form the conductive layer 112B (FIG. 29C).

Next, the insulating film 120f to be the insulating layer 120 is formed over the conductive layer 112B and the insulating film 110cf (FIG. 29D).

Next, the insulating film 120f is processed to form the insulating layer 120 (FIG. 26B). The description in <Manufacturing Method Example 1> can be referred to for the steps from the formation of the insulating film 110cf up to the formation of the insulating layer 120; thus, the detailed description thereof is omitted.

Next, part of the conductive layer 112B is removed to form the conductive layer 112b having the opening 143; and the insulating film 107f, the insulating film 110af, the insulating film 110bf, and the insulating film 110cf are partly removed to form the insulating layer 107 and the insulating layer 110 having the opening 141 (FIG. 26C). The above description in <Manufacturing Method Example 1> can be referred to for the steps after the formation of the opening 141 and the opening 143; thus, the detailed description thereof is omitted.

Through the above process, the semiconductor device 10A can be manufactured.

### Manufacturing Method Example 3

The manufacturing method is described taking the semiconductor device 10B illustrated in FIG. 13A or the like as an example.

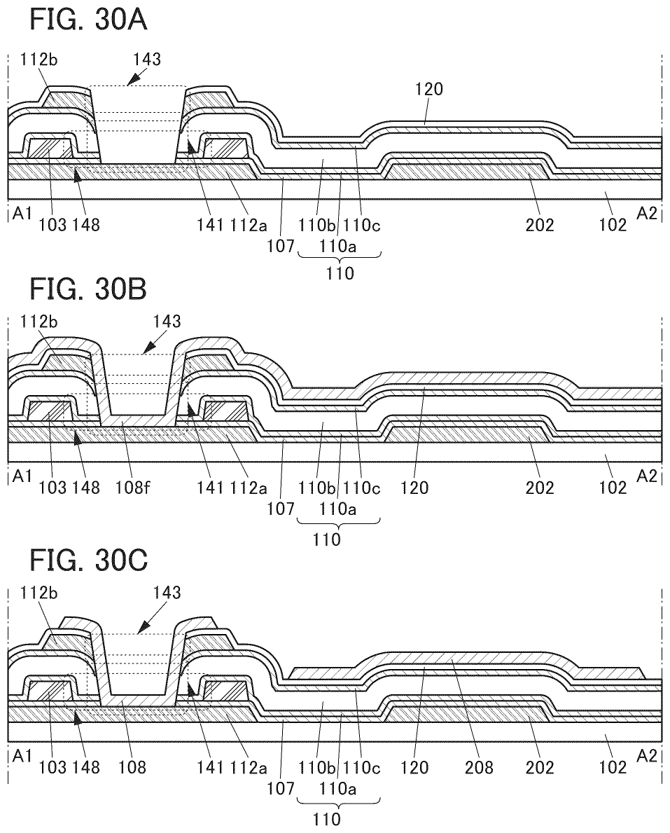

Each of FIG. 30A to FIG. 30C is a drawing illustrating the method for manufacturing the semiconductor device 10B. Each diagram is a cross-sectional view of a cross section along the dashed-dotted line A1-A2.

First, as in <Manufacturing Method Example 2>, the steps up to the formation of the insulating film 120f are performed. The description of FIG. 25A and FIG. 25B and FIG. 29A to FIG. 29D can be referred to for the steps up to the formation of the insulating film 120f; thus, the detailed description thereof is omitted.

Next, the insulating film 120f and the conductive layer 112B are partly removed, whereby the insulating layer 120 and the conductive layer 112b having the opening 143 are formed. For the formation of the insulating layer 120 and the conductive layer 112b, either or both of a wet etching method and a dry etching method can be used. A dry etching method can be particularly suitably used for the formation of the insulating layer 120. A wet etching method can be particularly suitably used for the formation of the conductive layer 112b. Note that the method for forming the insulating layer 120 and the method for forming the conductive layer 112b may be the same or different from each other.

Next, the insulating film 107f, the insulating film 110af, the insulating film 110bf, and the insulating film 110cf are partly removed, whereby the insulating layer 107 and the insulating layer 110 having the opening 141 are formed (FIG. 30A).

Next, the metal oxide film 108f to be the semiconductor layer 108 and the semiconductor layer 208 is formed so as to cover the opening 141 and the opening 143 (FIG. 30B). The metal oxide film 108f is provided in contact with the top and side surfaces of the insulating layer 120, the side surface of the conductive layer 112b, the side surface of the insulating layer 107, the side surface of the insulating layer 110, and the top surface of the conductive layer 112a.

Next, the metal oxide film 108f is processed into an island shape, so that the semiconductor layer 108 and the semiconductor layer 208 are formed (FIG. 30C).

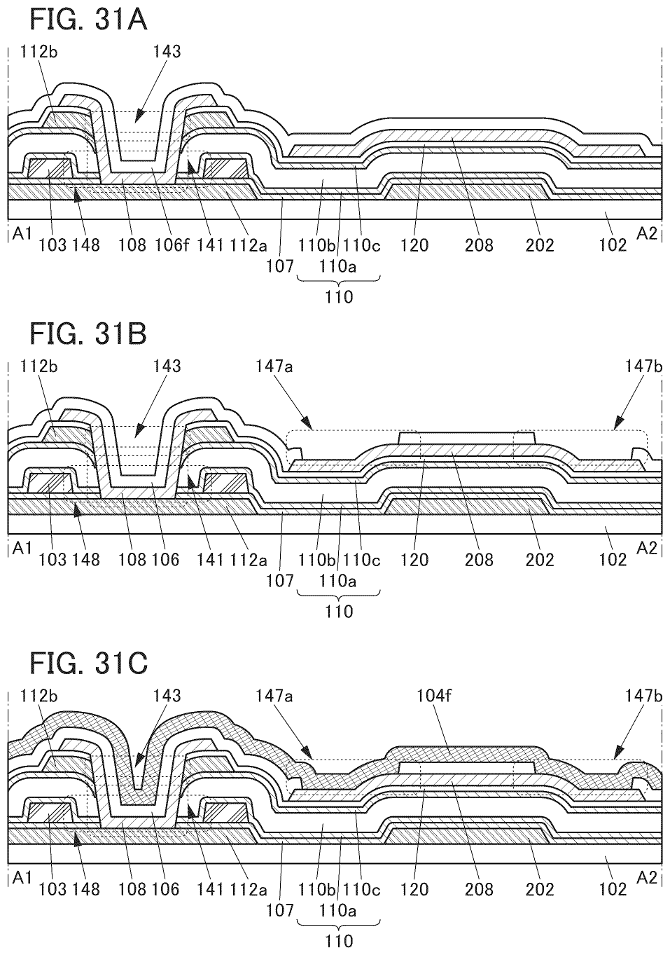

Next, the insulating film 106f to be the insulating layer 106 is formed so as to cover the semiconductor layer 108, the semiconductor layer 208, and the insulating layer 120 (FIG. 31A). Next, the insulating film 106f is processed to form the insulating layer 106 having the opening 147a and the opening 147b (FIG. 31B).

Next, the conductive film 104f to be the conductive layer 104, the conductive layer 204, the conductive layer 212a, and the conductive layer 212b is formed over the insulating layer 106 (FIG. 31C).

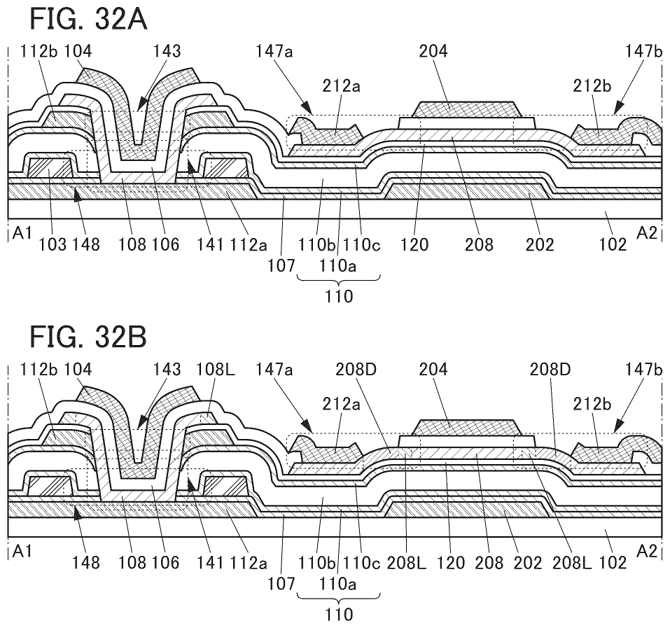

Next, the conductive film 104f is processed to form the conductive layer 104, the conductive layer 204, the conductive layer 212a, and the conductive layer 212b (FIG. 32A).

Next, an impurity is supplied to the semiconductor layer 208 using the conductive layer 204, the conductive layer 212a, and the conductive layer 212b as masks. Consequently, the region 208D and the region 208L are formed in the semiconductor layer 208 (FIG. 32B). The region 108L in the semiconductor layer 108 is also formed in a manner similar to the above.

The description in <Manufacturing Method Example 1> and <Manufacturing Method Example 2> can be referred to for the steps from the formation of the opening 141 up to the supply of the impurity: thus, the detailed description thereof is omitted.

Next, the insulating layer 195 is formed so as to cover the conductive layer 104, the conductive layer 204, the conductive layer 212a, the conductive layer 212b, the insulating layer 106, and the semiconductor layer 208 (FIG. 13A and FIG. 13B). The above description in <Manufacturing Method Example 1> can be referred to for the steps after the formation of the insulating layer 195; thus, the detailed description thereof is omitted.

Through the above process, the semiconductor device 10B can be manufactured.

### Manufacturing Method Example 4

The manufacturing method is described taking the semiconductor device 10F illustrated in FIG. 21B or the like as an example.

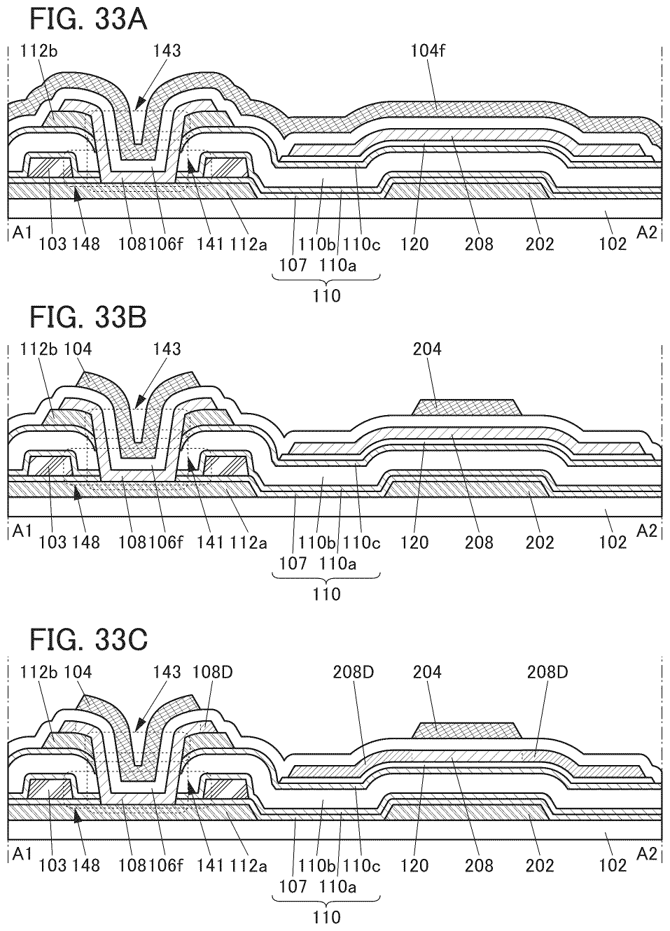

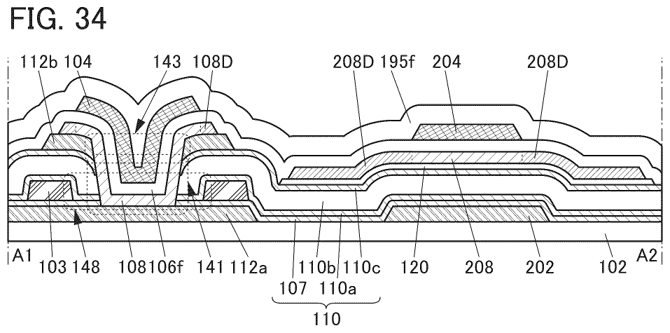

Each of FIG. 33A to FIG. 34 is a drawing illustrating the method for manufacturing the semiconductor device 10F. Each diagram is a cross-sectional view of a cross section along the dashed-dotted line A1-A2.

First, as in <Manufacturing Method Example 1> and <Manufacturing Method Example 2>, the steps up to the formation of the insulating film 106f are performed. The description of FIG. 25A and FIG. 27B and FIG. 29A to FIG. 29D can be referred to for the steps up to the formation of the insulating film 106f; thus, the detailed description thereof is omitted.

Next, the conductive film 104f to be the conductive layer 104 and the conductive layer 204 is formed over the insulating layer 106 (FIG. 33A).

Next, the conductive film 104f is processed to form the conductive layer 104 and the conductive layer 204 (FIG. 33B).

Next, an impurity is supplied to the semiconductor layer 208 through the insulating film 106f with use of the conductive layer 204 as a mask. Consequently, the region 208D is formed in a region that is of the semiconductor layer 208 and does not overlap with the conductive layer 204 (FIG. 33C). In this manner, the region 108D is formed in a region that is of the semiconductor layer 108 and does not overlap with the conductive layer 104.

The description in <Manufacturing Method Example 1> can be referred to for the steps from the formation of the conductive film 104f up to the supply of the impurity: thus, the detailed description thereof is omitted.

Next, an insulating film 195f to be the insulating layer 195 is formed to cover the conductive layer 104, the conductive layer 204, and the insulating film 106f (FIG. 34). For the formation of the insulating film 195f, a PECVD method can be suitably used.

Heat treatment may be performed after the formation of the insulating film 195f. The heat treatment can allow the region 108D and the region 208D to have lower electric resistance, in some cases. The description in <Manufacturing Method Example 1> can be referred to for the heat treatment; thus, the detailed description thereof is omitted. Note that the heat treatment is not necessarily performed.

Next, the insulating film 106f and the insulating film 195f are processed to form the insulating layer 106 and the insulating layer 195 which have the opening 147a and the opening 147b that reach the regions 208D. For the processing of the insulating film 106f and the insulating film 195f, either or both a wet etching method and a dry etching method can be used. Next, a conductive film is formed over the insulating layer 195 so as to cover the opening 147a and the opening 147b, and the conductive film is processed, so that the conductive layer 212a and the conductive layer 212b are formed (FIG. 21A).

Through the above process, the semiconductor device 10F of one embodiment of the present invention can be manufactured.

### Manufacturing Method Example 5

The manufacturing method is described taking the semiconductor device 10J illustrated in FIG. 24A or the like as an example.

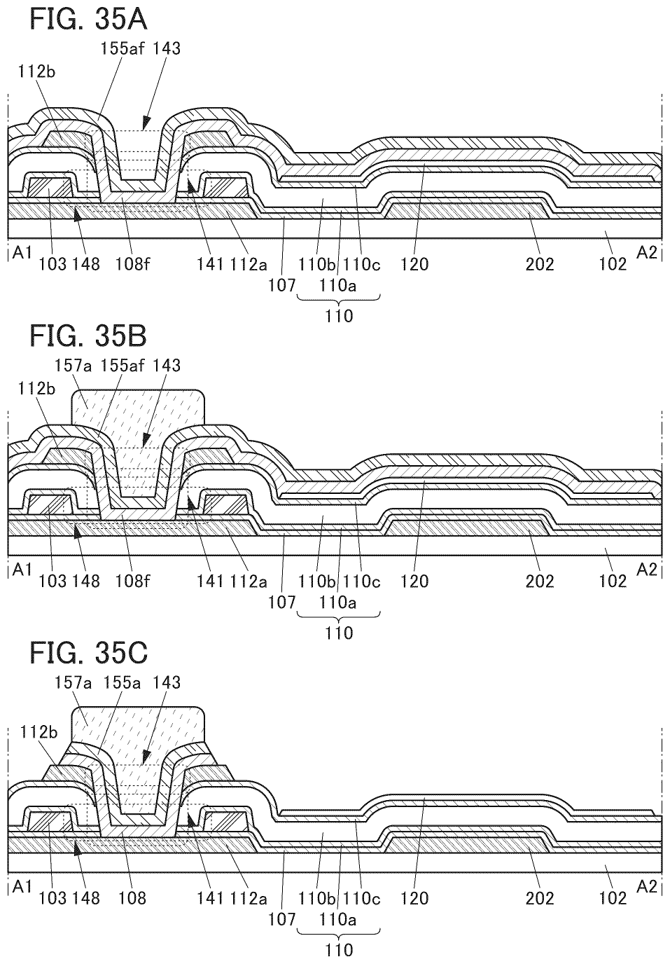

Each of FIG. 35A to FIG. 37C is a drawing illustrating the method for manufacturing the semiconductor device 10J. Each diagram is a cross-sectional view of a cross section along the dashed-dotted line A1-A2.

First, as in <Manufacturing Method Example 1> and <Manufacturing Method Example 2>, the steps up to the formation of the metal oxide film 108f are performed. The description of FIG. 25A and FIG. 26D and FIG. 29A to FIG. 29D can be referred to for the steps up to the formation of the metal oxide film 108f: thus, the detailed description thereof is omitted.

Next, a mask film 155af is formed over the metal oxide film 108f (FIG. 35A).

For the formation of the mask film 155af, a sputtering method or a vacuum evaporation method can be used, for example. The mask film 155af is preferably formed successively without exposure to the air after the formation of the metal oxide film 108f.

The mask film 155af is preferably formed using a metal that is unlikely to diffuse into the oxide semiconductor included in the metal oxide film 108f. This can reduce the carrier concentration in the semiconductor layer 108 formed later. Furthermore, the mask film 155af is preferably formed using a material whose etching rate is different from that of the metal oxide film 108f. Specifically, the ratio (hereinafter also referred to as a selectivity) of the etching rate of the mask film 155af to the etching rate of the metal oxide film 108f is preferably high. As the mask film 155af that does not easily diffuse into the oxide semiconductor and has high etching rate selectivity, one or more of a tungsten film, a molybdenum film, and a titanium film can be suitably used, for example.

Next, a resist mask 157a is formed over the mask film 155af (FIG. 35B).

Next, a region that is of the mask film 155af and is not covered with the resist mask 157a is removed by etching to expose part of the top surface of the metal oxide film 108f. Consequently, an island-shaped mask layer 155a is formed first.

Etching of the mask film 155af is preferably performed by a dry etching method. In particular, a highly anisotropic dry etching method is preferably employed. This prevents a phenomenon in which the pattern of the mask layer 155a is made smaller than that of the resist mask 157a due to etching of the side surface of the mask layer 155a.

Next, the metal oxide film 108f in a region not covered with the mask layer 155a is removed by etching to expose part of the top surfaces of the insulating layer 110, the insulating layer 120, and the conductive layer 112b (FIG. 35C). Although a dry etching method can be used, a wet etching method is preferably used for etching the metal oxide film 108f, in which case the etching damage on the semiconductor layer 108 can be reduced.

Consequently, the island-shaped mask layer 155a and the island-shaped semiconductor layer 108 are formed.

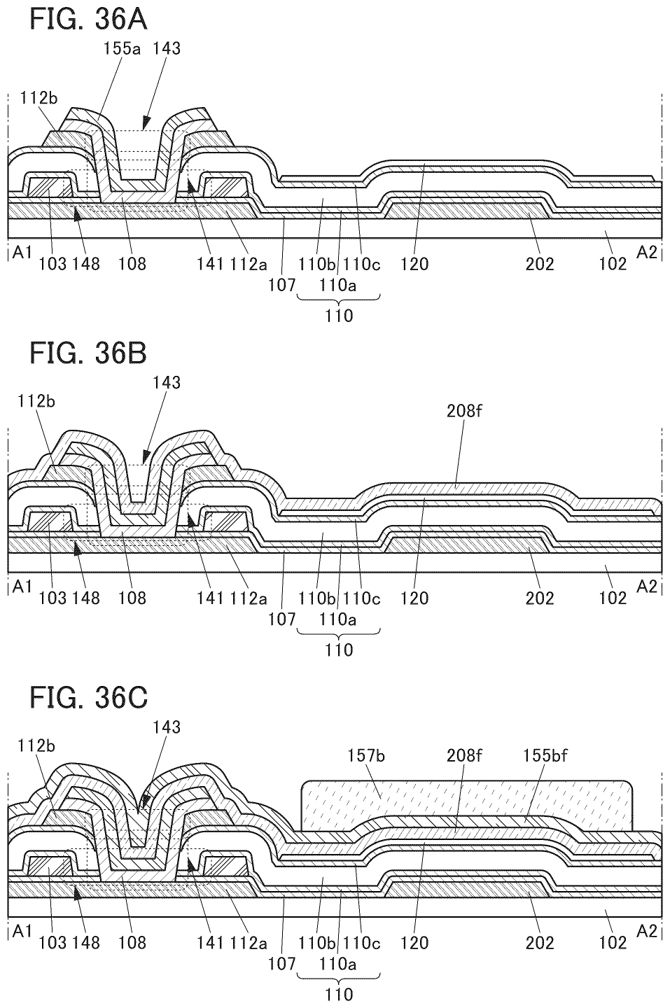

Next, the resist mask 157a is removed (FIG. 36A). The removal of the resist mask 157a can be performed by a wet etching method or a dry etching method.

Note that the resist mask 157a may be removed after the formation of the mask layer 155a but before the etching of the metal oxide film 108f. In that case, the metal oxide film 108f can be etched with the mask layer 155a used as an etching mask (also referred to as a hard mask). This prevents the side surface of the semiconductor layer 108 from being subjected to the etching of the resist mask 157a and thus reduces damage on the semiconductor layer 108.

Next, a metal oxide film 208f to be the semiconductor layer 208 is formed over the mask layer 155a, the semiconductor layer 108, the insulating layer 110, the insulating layer 120, and the conductive layer 112b.

The metal oxide film 208f can be formed using a sputtering target different from that used for the metal oxide film 108f, for example. For the formation of the metal oxide film 208f, the description of the metal oxide film 108f can be referred to.

Next, a mask film 155bf is formed over the metal oxide film 208f (FIG. 36B).

The mask film 155bf is preferably formed using the same material and the same conditions as those for the mask film 155af, for example. Furthermore, the mask film 155bf is preferably formed to have the same thickness as the mask film 155af.

Next, a resist mask 157b is formed in a region that is over the mask film 155bf and does not overlap with the mask layer 155a (FIG. 36C).

Next, a region that is of the mask film 155bf and is not covered with the resist mask 157b is removed by etching to expose part of the top surface of the metal oxide film 208f. Consequently, an island-shaped mask layer 155b is formed first.

Like the etching of the mask film 155af, etching of the mask film 155bf is preferably performed by a dry etching method.

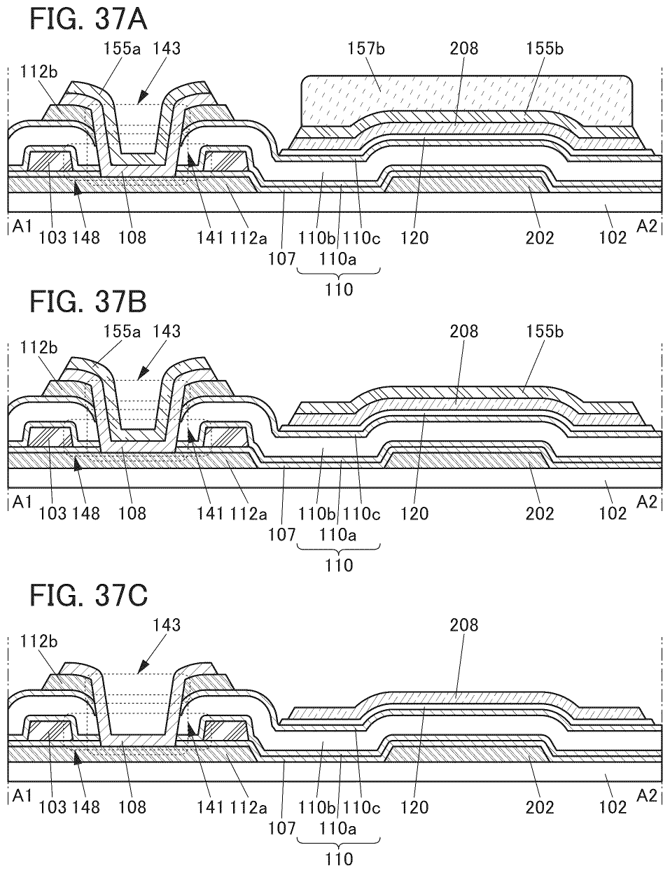

Next, the metal oxide film 208f in a region not covered with the mask layer 155b is removed by etching to expose part of the mask layer 155a, the semiconductor layer 108, the conductive layer 112b, the insulating layer 110, and the insulating layer 110 (FIG. 37A). Like the etching of the metal oxide film 108f, etching of the metal oxide film 208f is preferably performed by a wet etching method.

At this time, the mask layer 155a functions as a protective layer that prevents the semiconductor layer 108 from being etched in etching the metal oxide film 208f. It is thus preferable that the mask film 155af and the metal oxide film 208f should not be etched collectively under the same conditions but be etched separately by etching the mask film 155af under the conditions with a high etching rate selectivity with respect to the metal oxide film 208f. As a result, the metal oxide film 208f can be etched under the conditions with a high etching rate selectivity with respect to the mask layer 155a, which prevents the mask layer 155a functioning as the protective layer from being etched in etching the metal oxide film 208f.

Then, the resist mask 157b is removed (FIG. 37B).

Like the etching of the resist mask 157a, the resist mask 157b may also be removed after the formation of the mask layer 155b but before the etching of the metal oxide film 208f. In that case, the metal oxide film 208f can be etched with the mask layer 155b used as an etching mask (also referred to as a hard mask). This prevents the side surfaces of the semiconductor layer 208 and the semiconductor layer 108 from being subjected to the etching of the resist mask 157b and thus reduces damage on the semiconductor layer 108 and the semiconductor layer 208.

Next, the mask layer 155a and the mask layer 155b are removed by etching (FIG. 37C).

In the case where the mask layer 155a and the mask layer 155b are formed using the same material under the same conditions, the mask layer 155a and the mask layer 155b can be removed in the same step. It is further preferable that the mask layer 155a and the mask layer 155b be formed to have the same thickness. In that case, the mask layer 155a and the mask layer 155b do not need to be removed separately, which can simplify the process.

The mask layer 155a and the mask layer 155b are preferably removed by a wet etching method. If the mask layers are removed by a dry etching method, the semiconductor layer 108 and the semiconductor layer 208 might be damaged by plasma to be modified in film quality.

Using a wet etching method allows formation of the transistors with favorable electrical characteristics and high reliability.

Through the above process, the semiconductor layer 108 and the semiconductor layer 208 including different materials from each other can be formed.

Although the semiconductor layer 208 is formed here after the formation of the semiconductor layer 108, the formation order is not limited thereto. The semiconductor layer 108 may be formed after the formation of the semiconductor layer 208.

Next, the insulating film 106f to be the insulating layer 106 is formed to cover the semiconductor layer 108 and the semiconductor layer 208. The above description in <Manufacturing Method Example 1> can be referred to for the steps after the formation of the insulating film 106f: thus, the detailed description thereof is omitted.

Through the above steps, the semiconductor device 10J of one embodiment of the present invention can be manufactured.

This embodiment can be combined with the other embodiments as appropriate.

### Embodiment 3

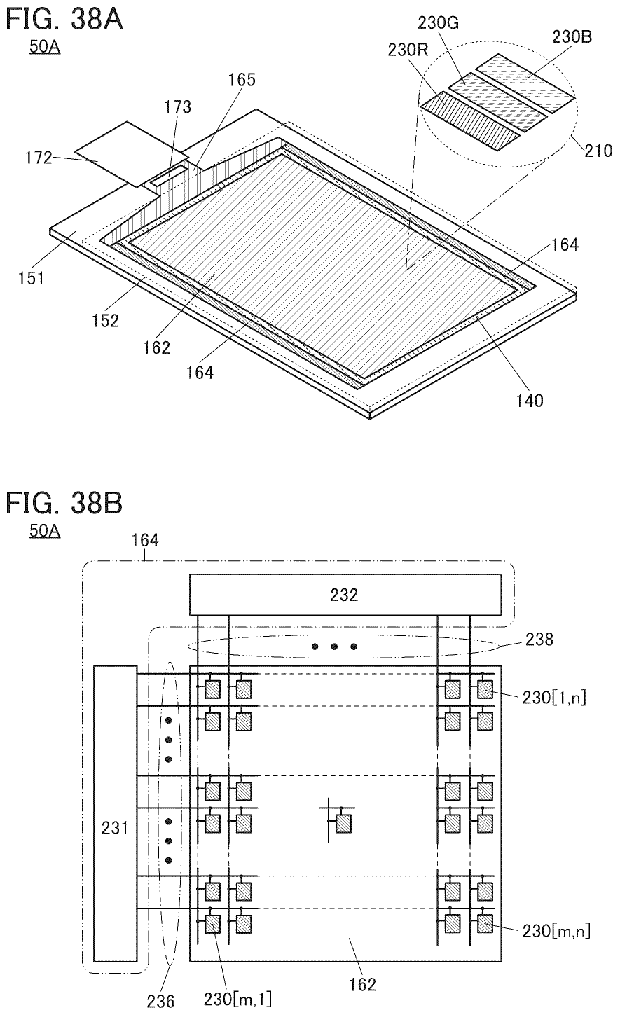

In this embodiment, display devices in which the semiconductor device of one embodiment of the present invention can be used are described with reference to FIG. 38 to FIG. 48.

The display device of this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

The display device of this embodiment can be a high-resolution display device. Accordingly, the display device in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display device or a module including the display device. Examples of the module including the display device are a module in which a connector such as a flexible printed circuit board (hereinafter referred to as an FPC) or a tape carrier package (TCP) is attached to the display device, a module which is mounted with an integrated circuit (IC) by a chip on glass (COG) method, a chip on film (COF) method, or the like, and the like.

FIG. 38A is a perspective view of a display device 50A.

In the display device 50A, a substrate 152 and a substrate 151 are bonded to each other. In FIG. 38A, the substrate 152 is indicated by a dashed line.

The display device 50A includes a display portion 162, a connection portion 140, a peripheral circuit portion 164, a wiring 165, and the like. FIG. 38A illustrates an example where an IC 173 and an FPC 172 are mounted on the display device 50A. Thus, the structure illustrated in FIG. 38A can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 38A illustrates an example where the connection portion 140 is provided to surround the four sides of the display portion. In the connection portion 140, a common electrode of a display element is electrically connected to a conductive layer so that a potential can be supplied to the common electrode.

The peripheral circuit portion 164 includes a scan line driver circuit (also referred to as a gate driver), for example. The peripheral circuit portion 164 may include both a scan line driver circuit and a signal line driver circuit (also referred to as a source driver).

The wiring 165 has a function of supplying a signal and power to the display portion 162 and the peripheral circuit portion 164. The signal and power are input to the wiring 165 from the outside through the FPC 172 or input to the wiring 165 from the IC 173.

FIG. 38A illustrates an example where the IC 173 is provided on the substrate 151 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method or the like.

The transistor of one embodiment of the present invention can be used for one or both of the display portion 162 and the peripheral circuit portion 164 of the display device 50A, for example.

The display portion 162 of the display device 50A is a region where an image is to be displayed, and includes a plurality of pixels 210 that are periodically arranged. An enlarged view of one pixel 210 is illustrated in FIG. 38A.

There is no particular limitation on the arrangement of the pixels in the display device of this embodiment, and a variety of methods can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 38A includes a pixel 230R that emits red light, a pixel 230G that emits green light, and a pixel 230B that emits blue light. The pixel 230R, the pixel 230G, and the pixel 230B each function as a subpixel.

The pixel 230R, the pixel 230G, and the pixel 230B each include a display element and a circuit for controlling the driving of the display element.

A variety of elements can be used as the display element, and a liquid crystal element or a light-emitting element can be used, for example. Alternatively, it is also possible to use, for example, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like. Alternatively, a QLED (Quantum-dot LED) employing a light source and color conversion technology using quantum dot materials may be used.

As examples of a display device using a liquid crystal element, a transmissive liquid crystal display device, a reflective liquid crystal display device, and a transflective liquid crystal display device can be given.

Examples of the light-emitting element include a self-luminous light-emitting element such as an LED (Light Emitting Diode), an OLED (Organic LED), and a semiconductor laser. Examples of the LED include a mini LED and a micro LED.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The emission color of the light-emitting element can be infrared, red, green, blue, cyan, magenta, yellow, white, or the like. When the light-emitting element has a microcavity structure, the color purity can be increased.

One electrode of the pair of electrodes included in the light-emitting element functions as an anode, and the other electrode functions as a cathode.

In this embodiment, the case where a light-emitting element is used as the display element is mainly described as an example.

FIG. 38B is a block diagram illustrating the display device 50A. The display device 50A includes the display portion 162 and the peripheral circuit portion 164. The display portion 162 includes a plurality of pixels 230 arranged periodically. The peripheral circuit portion includes a first driver circuit portion 231 and a second driver circuit portion 232.

A circuit included in the first driver circuit portion 231 functions as, for example, a scan line driver circuit. A circuit included in the second driver circuit portion 232 functions as, for example, a signal line driver circuit. Some sort of circuit may be provided at a position facing the first driver circuit portion 231 with the display portion 162 therebetween. Some sort of circuit may be provided at a position facing the second driver circuit portion 232 with the display portion 162 therebetween.

Any of a variety of circuits such as a shift register circuit, a level shifter circuit, an inverter circuit, a latch circuit, an analog switch circuit, a demultiplexer circuit, and a logic circuit can be used for the peripheral circuit portion 164. A transistor, a capacitor, and the like can be used in the peripheral circuit portion 164. Transistors included in the peripheral circuit portion 164 may be formed in the same step as transistors included in the pixels 230.

The display device 50A includes wirings 236 that are arranged substantially parallel to each other and whose potentials are controlled by the circuit included in the first driver circuit portion 231, and wirings 238 that are arranged substantially parallel to each other and whose potentials are controlled by the circuit included in the second driver circuit portion 232. Note that FIG. 38B illustrates an example in which the wirings 236 and the wirings 238 are connected to the pixels 230. Note that the wirings 236 and the wirings 238 are examples, and the wirings connected to the pixels 230 are not limited to the wirings 236 and the wirings 238.

### Structure Example of Driver Circuit

A structure example of a circuit that can be used as the driver circuit is described, taking a latch circuit as an example.

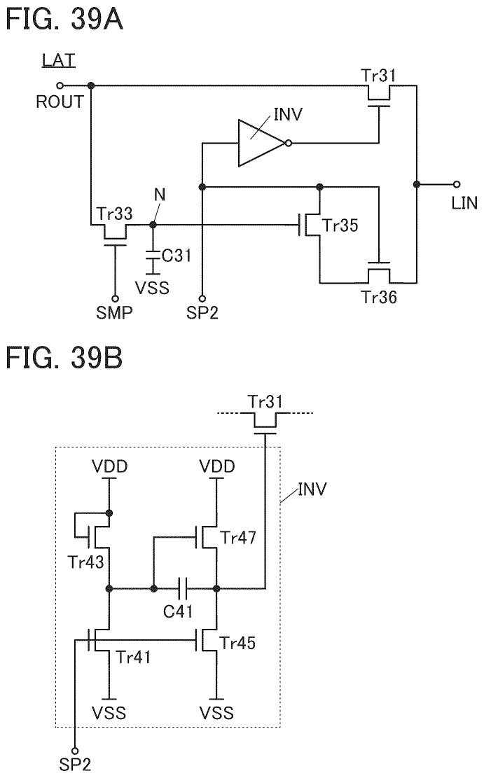

FIG. 39A is a circuit diagram illustrating a structure example of a latch circuit LAT. The latch circuit LAT illustrated in FIG. 39A includes a transistor Tr31, a transistor Tr33, a transistor Tr35, a transistor Tr36, a capacitor C31, and an inverter circuit INV. In FIG. 39A, a node where one of a source and a drain of the transistor Tr33, a gate of the transistor Tr35, and one electrode of the capacitor C31 are electrically connected to each other is referred to as a node N.

In the latch circuit LAT illustrated in FIG. 39A, when a high potential signal is input to a terminal SMP, the transistor Tr33 is turned on. Thus, the potential of the node N becomes a potential corresponding to the potential of a terminal ROUT, and data corresponding to a signal input to the latch circuit LAT is written from the terminal ROUT to the latch circuit LAT. After data is written to the latch circuit LAT, the potential of the terminal SMP is set to a low potential, whereby the transistor Tr33 is turned off. Accordingly, the potential of the node N is retained, and the data written to the latch circuit LAT is retained. Specifically, for example, in the case where the potential of the node N is a low potential, data having a value “0” can be regarded as being retained in the latch circuit LAT, and in the case where the potential of the node N is a high potential, data having a value “1” can be regarded as being retained in the latch circuit LAT.

As the transistor Tr33, a transistor having a low off-state current is preferably used. An OS transistor can be suitably used as the transistor Tr33. This enables long-term data retention in the latch circuit LAT. Thus, the frequency of rewriting data to the latch circuit LAT can be lowered.

In this specification and the like, writing data to the latch circuit LAT such that a signal input from a terminal SP2 is output to the terminal LIN is simply referred to as “writing data to the latch circuit LAT”, in some cases. That is, writing data having a value “1”, for example, to the latch circuit LAT is simply referred to as “writing data to the latch circuit LAT”, in some cases.

The semiconductor device of one embodiment of the present invention can be suitably used for the latch circuit LAT. For example, the transistor 100 or the transistor 200 illustrated in FIG. 1B or the like can be used as one or more of the transistor Tr31, the transistor Tr33, the transistor Tr35, and the transistor Tr36.

FIG. 39B illustrates a structure example of the inverter circuit INV. The inverter circuit INV includes a transistor Tr41, a transistor Tr43, a transistor Tr45, a transistor Tr47, and a capacitor C41.

When the latch circuit LAT has the structure illustrated in FIG. 39A and the inverter circuit INV has the structure illustrated in FIG. 39B, all the transistors included in the latch circuit LAT can have the same polarity and can be, for example, n-channel transistors. Thus, not only the transistor Tr33 but also the transistor Tr31, the transistor Tr35, the transistor Tr36, the transistor Tr41, the transistor Tr43, the transistor Tr45, and the transistor Tr47 can be OS transistors, for example. Thus, all the transistors included in the latch circuit LAT can be formed in the same process.

The semiconductor device of one embodiment of the present invention can be suitably used for the inverter circuit INV. For example, the transistor 100 or the transistor 200 illustrated in FIG. 1B or the like can be used as one or more of the transistor Tr41, the transistor Tr43, the transistor Tr45, and the transistor Tr47.

With the use of one or more kinds selected from the transistors 100 to 100H and 100J, the occupied area can be reduced, so that a display device with a narrow bezel can be provided. In addition, one or more kinds selected from the transistors 100 to 100H and 100J can be suitably used as a transistor that is required to have a high on-state current. Furthermore, one or more kinds selected from the transistors 200 to 200F can be suitably used as a transistor that is required to have favorable saturation. Thus, the display device can show high performance.

### Structure Example of Pixel Circuit

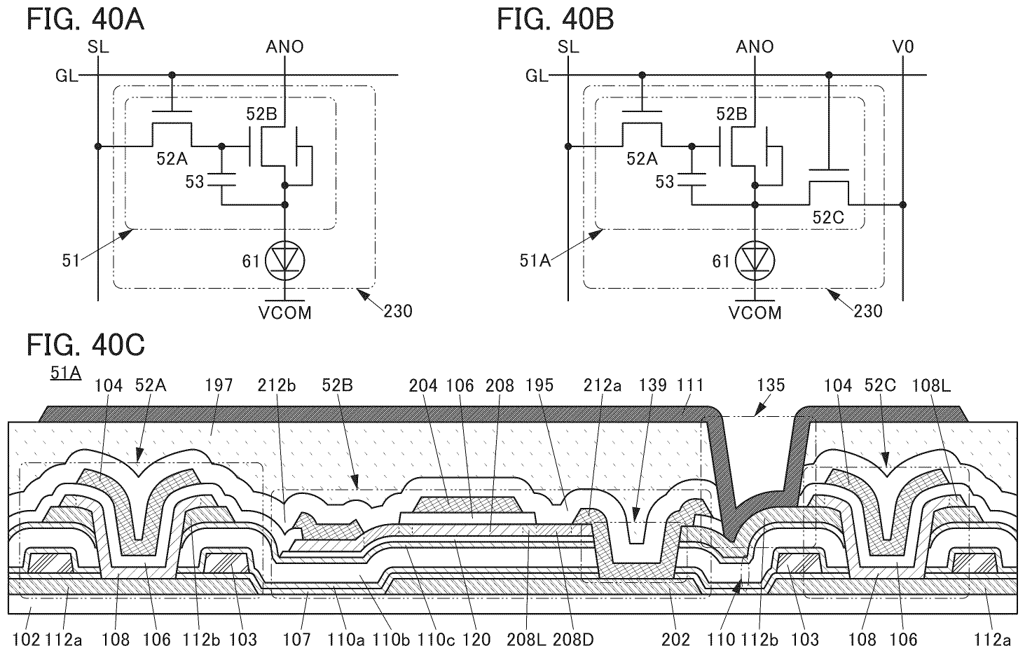

FIG. 40A illustrates a structure example of the pixel 230. The pixel 230 includes a pixel circuit 51 and a light-emitting device 61.

The pixel circuit 51 illustrated in FIG. 40A includes a transistor 52A, a transistor 52B, and a capacitor 53. The pixel circuit 51 is a 2Tr1C-type pixel circuit including two transistors and one capacitor.

One of a source and a drain of the transistor 52A is electrically connected to a gate of the transistor 52B and one terminal of the capacitor 53, and the other of the source and the drain is electrically connected to a wiring SL. A gate of the transistor 52A is electrically connected to a wiring GL. One of a source and a drain of the transistor 52B and the other terminal of the capacitor 53 are electrically connected to an anode of the light-emitting device 61. The other of the source and the drain of the transistor 52B is electrically connected to a wiring ANO. A cathode of the light-emitting device 61 is electrically connected to a wiring VCOM.

The wiring GL corresponds to the wiring 236, and the wiring SL corresponds to the wiring 238. The wiring VCOM is a wiring that supplies a potential for supplying a current to the light-emitting device 61. The transistor 52A has a function of controlling the conduction state or the non-conduction state between the wiring SL and the gate of the transistor 52B on the basis of the potential of the wiring GL. For example, VDD is supplied to the wiring ANO, and VSS is supplied to the wiring VCOM.

The transistor 52B has a function of controlling the amount of current flowing through the light-emitting device 61. The capacitor 53 has a function of retaining a gate potential of the transistor 52B. The intensity of light emitted from the light-emitting device 61 is controlled in accordance with an image signal supplied to the gate of the transistor 52B.

Some or all of the transistors included in the pixel circuit 51 may be provided with back gates. In the pixel circuit 51 illustrated in FIG. 40A, the transistor 52B includes a back gate, and the back gate is electrically connected to one of the source and the drain of the transistor 52B. Note that a structure in which the back gate of the transistor 52B is electrically connected to the gate of the transistor 52B may be employed as well.

The above-described semiconductor device can be suitably used for the pixel circuit 51. For example, the transistor 100 illustrated in FIG. 1B or the like can be used as the transistor 52A, and the transistor 200 can be used as the transistor 52B.

FIG. 40B illustrates a structure example of the pixel 230 that is different from that illustrated in FIG. 40A. The pixel 230 includes a pixel circuit 51A and the light-emitting device 61.

The pixel circuit 51A illustrated in FIG. 40B is different from the pixel circuit 51 illustrated in FIG. 40A mainly in including a transistor 52C. The pixel circuit 51A includes the transistor 52A, the transistor 52B, the transistor 52C, and the capacitor 53. The pixel circuit 51 is a 3Tr1C-type pixel circuit including three transistors and one capacitor.

One of a source and a drain of the transistor 52C is electrically connected to one of the source and the drain of the transistor 52B. The other of the source and the drain of the transistor 52C is electrically connected to a wiring V0. For example, a reference potential is supplied to the wiring V0.

The transistor 52C has a function of controlling the conduction state or the non-conduction state between the one of the source and the drain of the transistor 52B and the wiring V0 on the basis of the potential of the wiring GL. A variation in the gate-source potential of the transistor 52B can be inhibited by the reference potential of the wiring V0 supplied through the transistor 52C.

A current value that can be used for setting pixel parameters can be obtained using the wiring V0. Specifically, the wiring V0 can function as a monitor line for outputting a current flowing through the transistor 52B or a current flowing through the light-emitting device 61 to the outside. The current output to the wiring V0 can be converted into a voltage by a source follower circuit and output to the outside. Alternatively, the current output to the wiring V0 can be converted into a digital signal by an AD converter and output to the outside.

The above-described semiconductor device can be suitably used for the pixel circuit 51A. For example, the transistor 100A illustrated in FIG. 10A or the like can be used as each of the transistor 52A and the transistor 52C, and the transistor 200A can be used as the transistor 52B.

Note that there is no particular limitation on the pixel circuit that can be used in the display device of one embodiment of the present invention.

FIG. 40C illustrates a structure example of the pixel circuit 51A. FIG. 40C is a cross-sectional view of the pixel circuit 51A.

FIG. 40C illustrates a structure in which the semiconductor device 10A illustrated in FIG. 10A or the like is used for the pixel circuit 51A. Specifically, in the structure, the transistor 100A is used as each of the transistor 52A and the transistor 52C, and the transistor 200A is used as the transistor 52B.

The transistor 52B functioning as a driving transistor that controls a current flowing through the light-emitting device 61 preferably has more favorable saturation than the transistor 52A functioning as a selection transistor for controlling the selection state of the pixel 230. The use of the transistor 200A having a long channel length as the transistor 52B enables the display device to have high reliability. Furthermore, when the transistor 100A is used as each of the transistor 52A and the transistor 52C, the area occupied by the pixel circuit 51A can be reduced, so that the display device can have high resolution.

Note that the transistor 100A may also be used as the transistor 52B. The use of the transistor 100A having a short channel length as the transistor 52B enables the display device to have high luminance. Furthermore, the area occupied by the pixel circuit 51A can be reduced, so that the display device can have high resolution.

The conductive layer 212a included in the transistor 52B is electrically connected to the conductive layer 202 through an opening 139 provided in the insulating layer 120 and the insulating layer 110. The conductive layer 212a is electrically connected to the conductive layer 112b included in the transistor 52C. Note that the electrical connection between the transistor 52A and the transistor 52B is not illustrated in FIG. 40C. For example, a first opening reaching the conductive layer 112b included in the transistor 52A and a second opening reaching the conductive layer 204 included in the transistor 52B are provided in the insulating layer 195. When a first wiring is provided over the insulating layer 195 so as to cover the first opening and the second opening, the conductive layer 112b included in the transistor 52A and the conductive layer 204 included in the transistor 52B can be electrically connected to each other through the first wiring.

In FIG. 40C, the capacitor 53 is omitted. The capacitor 53 can be formed in a region where the insulating layer 106 is interposed between the conductive layer 204 functioning as the gate of the transistor 52B and the conductive layer 112b functioning as the one of the source and the drain of the transistor 52C, for example. Note that there is no particular limitation on the structure of the capacitor 53.

The insulating layer 195 is provided so as to cover the transistor 52A, the transistor 52B, the transistor 52C, and the capacitor 53, and an insulating layer 197 is provided to cover the insulating layer 195. The light-emitting device 61 can be provided over the insulating layer 197. FIG. 40C illustrates a pixel electrode 111 functioning as one electrode of the light-emitting device 61. The pixel electrode 111 is electrically connected to the conductive layer 112b included in the transistor 52C through an opening 135 provided in the insulating layer 195 and the insulating layer 197. The above description can be referred to for the insulating layer 195; thus, the detailed description thereof is omitted. The insulating layer 197 has a function of reducing unevenness due to the transistor 52A, the transistor 52B, and the transistor 52C to make the formation surface of the light-emitting device 61 flatter. Note that in this specification and the like, the insulating layer 197 is referred to as a planarization layer in some cases.

As the insulating layer 197, an insulating layer containing an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic-based polymers in a broad sense in some cases.

For the insulating layer 197, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used, for example. An organic material such as polyvinyl alcohol (PVA), polyvinyl butyral, polyvinyl pyrrolidone, polyethylene glycol, polyglycerin, pullulan, water-soluble cellulose, or an alcohol-soluble polyamide resin may be used for the insulating layer 127. A photoresist may be used as a photosensitive resin. As the photosensitive organic resin, either a positive material or a negative material may be used.

The insulating layer 197 may have a stacked-layer structure of an organic insulating layer and an inorganic insulating layer. For example, the insulating layer 197 can have a stacked-layer structure of an organic insulating layer and an inorganic insulating layer over the organic insulating layer. An inorganic insulating layer provided on the outermost surface of the insulating layer 197 can function as an etching protective layer. This can inhibit poor flatness of the insulating layer 197 due to etching of part of the insulating layer 197 at the time of forming the pixel electrode 111.

The pixel electrode 111 is electrically connected to the conductive layer 112b through an opening provided in the insulating layer 197, the insulating layer 195, and the insulating layer 106.

The display device of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

### Structure Example 1 of Display Device

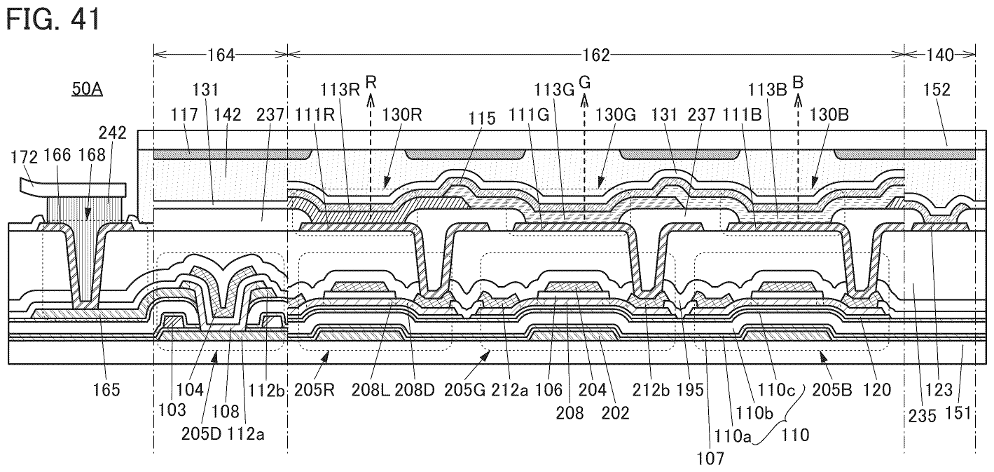

FIG. 41A illustrates an example of cross sections of part of a region including the FPC 172, part of the peripheral circuit portion 164, part of the display portion 162, part of the connection portion 140, and part of a region including an end portion of the display device 50A.

The display device 50A illustrated in FIG. 41A includes transistors 205D, 205R, 205G, and 205B, a light-emitting element 130R, a light-emitting element 130G, a light-emitting element 130B, and the like between the substrate 151 and the substrate 152. The light-emitting element 130R is a display element included in the pixel 230R that emits red light, the light-emitting element 130G is a display element included in the pixel 230G that emits green light, and the light-emitting element 130B is a display element included in the pixel 230B that emits blue light.

The display device 50A employs an SBS structure. The SBS structure can optimize materials and structures of light-emitting elements and thus can increase the degree of freedom in selecting materials and structures, so that the luminance and the reliability can be easily improved.

The display device 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

The transistor 205D, the transistor 205R, the transistor 205G, and the transistor 205B are each formed over the substrate 151. Some of the formation steps can be the same among these transistors.

OS transistors can be suitably used as the transistor 205D, the transistor 205R, the transistor 205G, and the transistor 205B. The transistor of one embodiment of the present invention can be used as the transistor 205D, the transistor 205R, the transistor 205G, and the transistor 205B. In other words, the display device 50A includes the transistor of one embodiment of the present invention in both the display portion 162 and the peripheral circuit portion 164. When the transistor of one embodiment of the present invention is used in the display portion 162, the pixel size can be reduced and high resolution can be achieved. When the transistor of one embodiment of the present invention is used in the peripheral circuit portion 164, the area occupied by the peripheral circuit portion 164 can be reduced and a narrower bezel can be achieved. The description in the above embodiment can be referred to for the transistor of one embodiment of the present invention.

A transistor provided in the peripheral circuit portion 164 sometimes requires a higher on-state current than a transistor provided in the display portion 162. A transistor having a short channel length is preferably used for the peripheral circuit portion 164. For example, one or more kinds selected from the above-described transistors 100 to 100H and 100J can be suitably used in the peripheral circuit portion 164. When one or more kinds selected from the transistors 100 to 100H and 100J are used in the peripheral circuit portion 164, the occupied area can be reduced, so that a display device with a narrow bezel can be provided. As the transistor provided in the display portion 162, one or more kinds selected from the above-described transistors 200 to 200F can be suitably used. FIG. 41 illustrates a structure in which the above-described transistor 100A is used as the transistor 205D and the transistor 200A is used as each of the transistor 205R, the transistor 205G, and the transistor 205B. Note that one or more kinds selected from the transistors 100 to 100H and 100J may be used in the display portion 162, and one or more kinds selected from the transistors 200 to 200F may be used in the peripheral circuit portion 164.

Note that the transistor included in the display device of this embodiment is not limited to the transistor of one embodiment of the present invention. For example, the display device of this embodiment may include the transistor of one embodiment of the present invention and a transistor having another structure in combination. The display device of this embodiment may include any one or more of a planar transistor, a staggered transistor, and an inverted staggered transistor. A transistor included in the display device of this embodiment may have either a top-gate structure or a bottom-gate structure. Alternatively, gates may be provided above and below the semiconductor layer where a channel is formed.

A transistor including silicon in its channel formation region (a Si transistor) may be included in the display device of this embodiment. Examples of silicon include single crystal silicon, polycrystalline silicon, and amorphous silicon. In particular, a transistor including LTPS in its semiconductor layer (hereinafter also referred to as an LTPS transistor) can be used. The LTPS transistor has high field-effect mobility and excellent frequency characteristics.

To increase the emission luminance of the light-emitting element included in the pixel circuit, the amount of current flowing through the light-emitting element needs to be increased. To increase the amount of current, the source-drain voltage of a driving transistor included in the pixel circuit needs to be increased. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting element can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made to flow through an OS transistor than through a Si transistor. Thus, by using an OS transistor as the driving transistor, a stable current can be made to flow through a light-emitting element even when the current-voltage characteristics of an EL element vary, for example. In other words, when the OS transistor operates in the saturation region, the source-drain current hardly changes with a change in the source-drain voltage: hence, the emission luminance of the light-emitting element can be stable.

The transistors included in the peripheral circuit portion 164 and the transistors included in the display portion 162 may have the same structure or different structures. A plurality of transistors included in the peripheral circuit portion 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. A structure in which an LTPS transistor and an OS transistor are used in combination is referred to as LTPO in some cases. As a more suitable example, a structure in which the OS transistor is used as a transistor or the like functioning as a switch for controlling conduction or non-conduction between wirings, and the LTPS transistor is used as a transistor or the like for controlling current, can be given.

For example, one of the transistors included in the display portion 162 functions as a transistor for controlling a current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps): thus, power consumption can be reduced by stopping the driver in displaying a still image.

The insulating layer 195 is provided so as to cover the transistor 205D, the transistor 205R, the transistor 205G, and the transistor 205B, and an insulating layer 235 is provided over the insulating layer 195.

The insulating layer 235 preferably functions as a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. Accordingly, a depressed portion can be inhibited from being formed in the insulating layer 235 in processing a pixel electrode 111R, a pixel electrode 111G, and a pixel electrode 111B, for example. Alternatively, a depressed portion may be formed in the insulating layer 235 in processing the pixel electrode 111R, the pixel electrode 111G, and the pixel electrode 111B, for example.

The light-emitting element 130R, the light-emitting element 130G, and the light-emitting element 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 41 emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 41 emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 41 emits blue light (B). The EL layer 113B includes a light-emitting layer that emits blue light.

Although the EL layers 113R, 113G, and 113B have the same thickness in FIG. 41, the present invention is not limited thereto. The EL layers 113R, 113G, and 113B may have different thicknesses. For example, the thicknesses of the EL layers 113R, 113G, and 113B are preferably set in accordance with an optical path length that intensifies light emitted from each EL layer. Accordingly, a microcavity structure is achieved, and the color purity of light emitted from each light-emitting element can be improved.

The pixel electrode 111R is electrically connected to the conductive layer 112b included in the transistor 205R through an opening provided in the insulating layer 195 and the insulating layer 235. In a similar manner, the pixel electrode 111G is electrically connected to the conductive layer 112b included in the transistor 205G, and the pixel electrode 111B is electrically connected to the conductive layer 112b included in the transistor 205B.

End portions of the pixel electrodes 111R, 111G, and 111B are covered with an insulating layer 237. The insulating layer 237 functions as a partition wall (also referred to as an embankment, a bank, or a spacer). The insulating layer 237 can be provided to have a single-layer structure or a stacked-layer structure using one or both of an inorganic insulating material and an organic insulating material. A material that can be used for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other.

The common electrode 115 is a continuous film shared by the light-emitting elements 130R, 130G, and 130B. The common electrode 115 shared by the plurality of light-emitting elements is electrically connected to a conductive layer 123 provided in the connection portion 140. The conductive layer 123 is preferably formed using a conductive layer formed using the same material and the same step as the pixel electrodes 111R, 111G, and 111B.

In the display device of one embodiment of the present invention, a conductive film transmitting visible light is used for the electrode through which light is extracted, which is either the pixel electrode or the common electrode. A conductive film reflecting visible light is preferably used for the electrode through which light is not extracted.

A conductive film transmitting visible light may be used also for the electrode through which light is not extracted. In that case, this electrode is preferably provided between a reflective layer and the EL layer. In other words, light emitted by the EL layer may be reflected by the reflective layer to be extracted from the display device.

As a material that forms the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have an electric resistivity lower than or equal to 1×10⁻² Ωcm.

The EL layers 113R, 113G, and 113B are each provided to have an island shape. In FIG. 41, an end portion of the EL layer 113R and an end portion of the EL layer 113G that are adjacent to each other overlap with each other, an end portion of the EL layer 113G and an end portion of the EL layer 113B that are adjacent to each other overlap with each other, and an end portion of the EL layer 113R and an end portion of the EL layer 113B that are adjacent to each other overlap with each other. When island-shaped EL layers are formed using a fine metal mask, end portions of the EL layers adjacent to each other may overlap with each other as illustrated in FIG. 41: however, the present invention is not limited thereto. That is, it is also possible that the EL layers adjacent to each other do not overlap with each other and are apart from each other. Furthermore, both a portion where the EL layers adjacent to each other overlap with each other and a portion where the EL layers adjacent to each other do not overlap with each other and are apart from each other may exist in the display device.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellowish green, yellow; orange, red, or the like is appropriately used. Alternatively; as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a bipolar material and a TADF material.

Either a low molecular compound or a high molecular compound can be used for the light-emitting element, and an inorganic compound may also be contained. Each of the layers included in the light-emitting element can be formed by an evaporation method (including a vacuum evaporation method), a transfer method, a printing method, an inkjet method, a coating method, or the like.

For the light-emitting element, a single structure (a structure including only one light-emitting unit) or a tandem structure (a structure including a plurality of light-emitting units) may be employed. The light-emitting unit includes at least one light-emitting layer. In a tandem structure, a plurality of light-emitting units are connected in series with a charge-generation layer therebetween. The charge-generation layer has a function of injecting electrons into one of the two light-emitting units and injecting holes into the other when a voltage is applied between the pair of electrodes. The tandem structure enables a light-emitting element capable of high-luminance light emission. Furthermore, the tandem structure allows the amount of current needed for obtaining the same luminance to be reduced as compared to the case of using a single structure, and thus can improve the reliability. The tandem structure may be referred to as a stack structure.

In the case of using a light-emitting element having a tandem structure in FIG. 41, it is preferable that the EL layer 113R include a plurality of light-emitting units emitting red light, the EL layer 113G include a plurality of light-emitting units emitting green light, and the EL layer 113B include a plurality of light-emitting units emitting blue light.

A protective layer 131 is provided over the light-emitting elements 130R, 130G, and 130B. The protective layer 131 and the substrate 152 are bonded to each other with an adhesive layer 142 therebetween. The substrate 152 is provided with a light-blocking layer 117. For example, a solid sealing structure or a hollow sealing structure can be employed to seal the light-emitting elements. In FIG. 41, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting element. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the peripheral circuit portion 164. It is further preferable that the protective layer 131 be provided to extend to the end portion of the display device 50A. Meanwhile, a connection portion 168 has a portion not provided with the protective layer 131 so that the FPC 172 and a conductive layer 166 are electrically connected to each other.

By providing the protective layer 131 over the light-emitting element 130R, the light-emitting element 130G, and the light-emitting element 130B, the reliability of the light-emitting elements can be increased.

The protective layer 131 may have a single-layer structure or a stacked-layer structure of two or more layers. There is no limitation on the conductivity of the protective layer 131. As the protective layer 131, at least one type of insulating films, semiconductor films, and conductive films can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example: thus, the reliability of the display device can be improved.

As the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film containing ITO, In—Zn oxide, Ga—Zn oxide, Al—Zn oxide, IGZO, or the like can be used as the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high property of transmitting visible light. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 168 is provided in a region of the substrate 151 not overlapping with the substrate 152. In the connection portion 168, the wiring 165 is electrically connected to the FPC 172 through the conductive layer 166 and a connection layer 242. An example in which the conductive layer 166 is a single conductive layer obtained by processing the same conductive film as the pixel electrode 111R, the pixel electrode 111G, and the pixel electrode 111B is shown. On the top surface of the connection portion 168, the conductive layer 166 is exposed. Thus, the connection portion 168 and the FPC 172 can be electrically connected to each other through the connection layer 242.

The wiring 165 is electrically connected to the transistor included in the peripheral circuit portion 164. FIG. 41 illustrates a structure in which the conductive layer 112b included in the transistor 205D extends and functions as the wiring 165. Note that the structure of the wiring 165 is not limited thereto.

The display device 50A has a top-emission structure. Light emitted from the light-emitting element is emitted toward the substrate 152 side. For the substrate 152, a material having a high visible-light-transmitting property is preferably used. The pixel electrode 111R, the pixel electrode 111G, and the pixel electrode 111B include a material that reflects visible light, and the counter electrode (the common electrode 115) includes a material that transmits visible light.

The light-blocking layer 117 is preferably provided on the surface of the substrate 152 that faces the substrate 151. The light-blocking layer 117 can be provided between adjacent light-emitting elements, in the connection portion 140, and in the peripheral circuit portion 164, for example.

A coloring layer such as a color filter may be provided on the surface of the substrate 152 that faces the substrate 151 or over the protective layer 131. When the color filter is provided so as to overlap with the light-emitting element, the color purity of light emitted from the pixel can be increased.

A variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer side of the substrate 152. For example, it is preferable to provide, as the surface protective layer, a glass layer or a silica layer (SiOₓ layer) because the surface contamination and generation of damage can be inhibited. For the surface protective layer, DLC (diamond-like carbon), aluminum oxide (AlOₓ), a polyester-based material, a polycarbonate-based material, or the like may be used. For the surface protective layer, a material having a high visible-light transmittance is preferably used. For the surface protective layer, a material with high hardness is preferably used.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 151 and the substrate 152 are formed using a flexible material, the flexibility of the display device can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used as at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (i.e., a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability; such as an epoxy resin, is preferable. A two-liquid-mixture-type resin may be used. An adhesive sheet or the like may be used.

As the connection layer 242, an anisotropic conductive film (ACF), an anisotropic conductive paste (ACP), or the like can be used.

### Structure Example 2 of Display Device

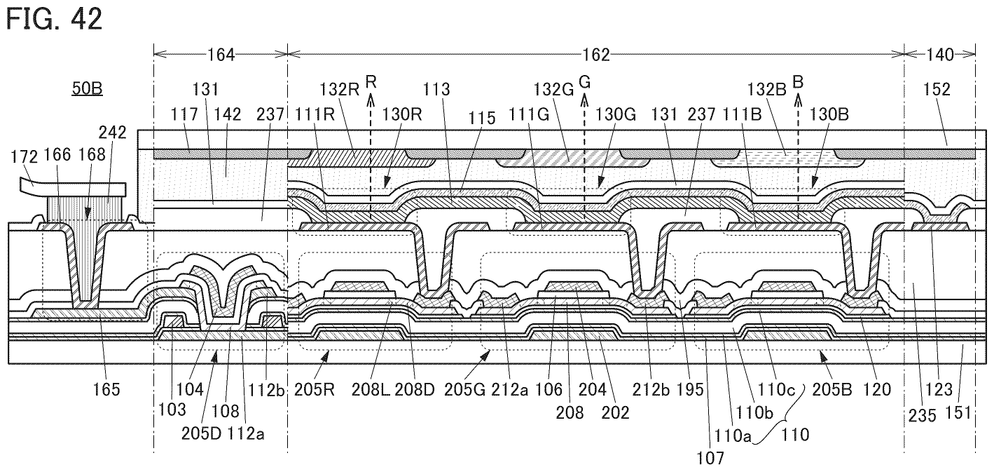

A display device 50B illustrated in FIG. 42 is different from the display device 50A mainly in that an EL layer 113 shared between the light-emitting elements and coloring layers (color filters or the like) are used for the subpixels of different colors. As for the description of the display device below; description of portions similar to those of the above-described display device is omitted in some cases.

The display device 50B illustrated in FIG. 42 includes the transistors 205D, 205R, 205G, and 205B, the light-emitting elements 130R, 130G, and 130B, the coloring layer 132R transmitting red light, the coloring layer 132G transmitting green light, the coloring layer 132B transmitting blue light, and the like between the substrate 151 and the substrate 152.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 50B through the coloring layer 132B.

The EL layer 113 and the common electrode 115 are shared between the light-emitting elements 130R, 130G, and 130B. The number of manufacturing steps can be smaller in the structure where the EL layer 113 is provided to be shared between the subpixels of different colors than the structure where the subpixels of different colors are provided with different EL layers.

The light-emitting elements 130R, 130G, and 130B illustrated in FIG. 42 emit white light, for example. When white light emitted from the light-emitting elements 130R, 130G, and 130B passes through the coloring layers 132R, 132G, and 132B, light of desired colors can be obtained.

The light-emitting element that emits white light preferably includes two or more light-emitting layers. When white light emission is obtained using two light-emitting layers, the two light-emitting layers are selected such that emission colors of the light-emitting layers are complementary colors. For example, when an emission color of a first light-emitting layer and an emission color of a second light-emitting layer are complementary colors, the light-emitting element can be configured to emit white light as a whole. In the case where three or more light-emitting layers are used to obtain white light, the light-emitting element is configured to emit white light as a whole by combining emission colors of the three or more light-emitting layers.

The EL layer 113 preferably includes a light-emitting layer containing a light-emitting substance that emits blue light and a light-emitting layer containing a light-emitting substance that emits visible light having a longer wavelength than blue light, for example. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specifically: examples of applicable structures are as follows: a two-unit tandem structure including a light-emitting unit emitting yellow light and a light-emitting unit emitting blue light: a two-unit tandem structure including a light-emitting unit emitting red light and green light and a light-emitting unit emitting blue light: a three-unit tandem structure in which a light-emitting unit emitting blue light, a light-emitting unit emitting yellow: yellow-green, or green light, and a light-emitting unit emitting blue light are stacked in this order; and a three-unit tandem structure in which a light-emitting unit emitting blue light, a light-emitting unit emitting yellow: yellow-green, or green light and red light, and a light-emitting unit emitting blue light are stacked in this order. Examples of the number of stacked light-emitting units and the order of colors from the anode side 20) include a two-unit structure of B and Y: a two-unit structure of B and a light-emitting unit X: a three-unit structure of B. Y. and B; and a three-unit structure of B. X. and B. Examples of the number of light-emitting layers stacked in the light-emitting unit X and the order of colors from an anode side include a two-layer structure of R and Y; a two-layer structure of R and G: a two-layer structure of G and R: a three-layer structure of G, R, and G; and a three-layer structure of R. G. and R. Another layer may be provided between two light-emitting layers.

Alternatively: the light-emitting elements 130R. 130G, and 130B illustrated in FIG. 42 emit blue light, for example. In this case, the EL layer 113 includes one or more light-emitting layers that emit blue light. In the pixel 230B that emits blue light, blue light emitted from the light-emitting element 130B can be extracted. In each of the pixel 230R that emits red light and the pixel 230G that emits green light, a color conversion layer is provided between the light-emitting element 130R or the light-emitting element 130G and the substrate 152 so that blue light emitted from the light-emitting element 130R or 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

### Structure Example 3 of Display Device

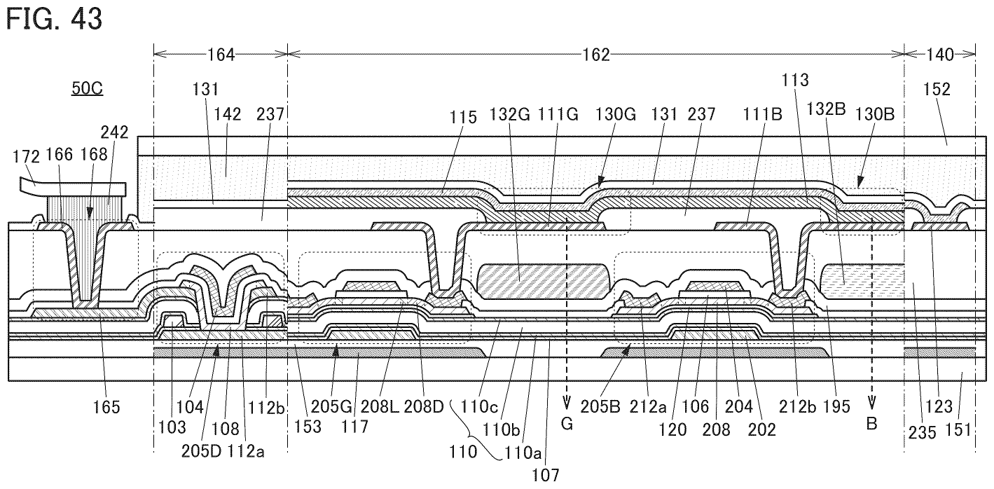

A display device 50C illustrated in FIG. 43 is different from the display device 50B mainly in having a bottom-emission structure.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 43 illustrates an example where the light-blocking layers 117 are provided over the substrate 151, the insulating layer 153 is provided over the light-blocking layers 117, and the transistor 205D, the transistor 205R (not illustrated), the transistor 205G, the transistor 205B and the like are provided over the insulating layer 153. In addition, the coloring layer 132R (not illustrated), the coloring layer 132G, and the coloring layer 132B are provided over the insulating layer 195, and the insulating layer 235 is provided over the coloring layer 132R (not illustrated), the coloring layer 132G, and the coloring layer 132B.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a high visible-light-transmitting property is used for each of the pixel electrodes 111G and 111B. A material reflecting visible light is preferably used for the common electrode 115. In the display device having a bottom-emission structure, a metal or the like having low resistivity can be used for the common electrode 115: thus, a voltage drop due to the electric resistance of the common electrode 115 can be inhibited and a high display quality can be achieved.

The transistor of one embodiment of the present invention can be miniaturized and the area occupied by the transistor can be reduced, so that the aperture ratio of the pixel can be increased or the pixel size can be reduced in the display device having a bottom-emission structure.

### Structure Example 4 of Display Device

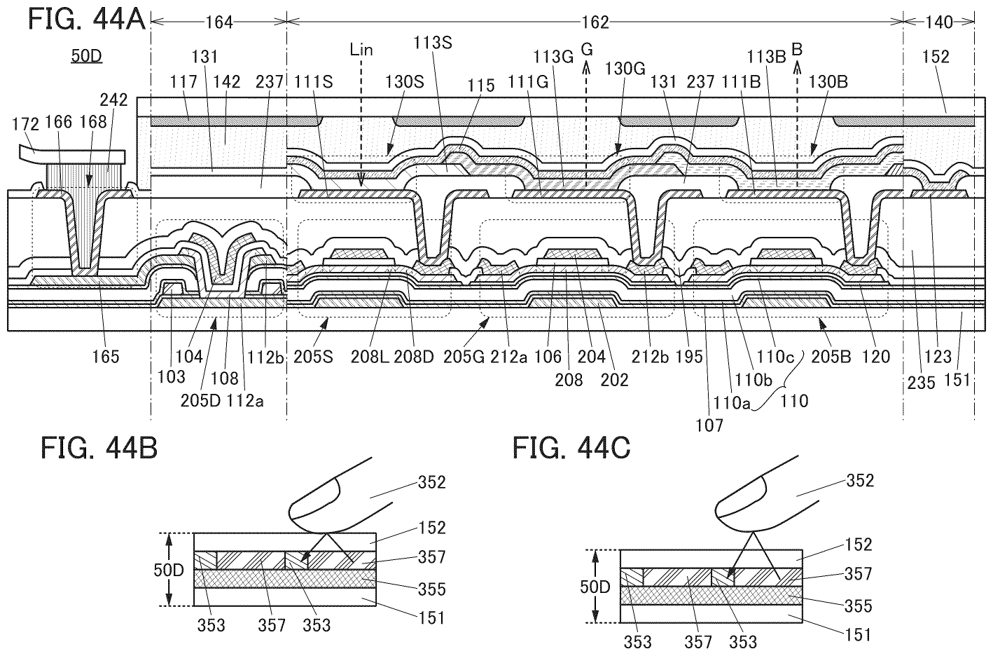

A display device 50D illustrated in FIG. 44A is different from the display device 50A mainly in including a light-receiving element 130S.

The display device 50D includes light-emitting elements and a light-receiving element in a pixel. In the display device 50D, organic EL elements are preferably used as the light-emitting elements and an organic photodiode is preferably used as the light-receiving element. The organic EL elements and the organic photodiodes can be formed over the same substrate. Thus, the organic photodiodes can be incorporated in a display device including the organic EL elements.

In the display device 50D including light-emitting elements and a light-receiving element in each pixel, the pixel has a light-receiving function: thus, the display device can detect a contact or approach of an object while displaying an image. Accordingly, the display portion 162 has one or both of an image capturing function and a sensing function in addition to a function of displaying an image. For example, all the subpixels included in the display device 50D can display an image: alternatively, some of the subpixels can emit light as a light source, some of the rest of the subpixels can detect light, and the other subpixels can display an image.

Accordingly, a light-receiving portion and a light source do not need to be provided separately from the display device 50D: hence, the number of components of an electronic device can be reduced. For example, a biometric authentication device provided in the electronic device, a capacitive touch panel for scroll operation, or the like is not necessarily provided separately. Thus, with the use of the display device 50D, the electronic device can be provided at lower manufacturing costs.

When the light-receiving elements are used as an image sensor, the display device 50D can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

The light-receiving element can be used for a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect an object even when the object is not in contact with the display device.

The light-receiving element 130S includes a pixel electrode 111S over the insulating layer 235, a functional layer 113S over the pixel electrode 111S, and the common electrode 115 over the functional layer 113S. Light Lin enters the functional layer 113S from the outside of the display device 50D.

The pixel electrode 111S is electrically connected to the conductive layer 112b included in a transistor 205S through an opening provided in the insulating layer 195 and the insulating layer 235.

An end portion of the pixel electrode 111S is covered with the insulating layer 237.

The common electrode 115 is a continuous film provided to be shared by the light-receiving element 130S, the light-emitting element 130R (not illustrated), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example where an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

In addition to the active layer, the functional layer 113S may further include a layer containing a substance having a high hole-transport property, a substance having a high electron-transport property, a substance having a bipolar property (a substance with a high electron-transport property and a high hole-transport property), or the like. Without limitation to the above, the functional layer 113S may further include a layer containing a substance having a high hole-injection property, a hole-blocking material, a substance having a high electron-injection property, an electron-blocking material, or the like. Layers other than the active layer included in the light-receiving element can be formed using a material that can be used for the light-emitting element, for example.

Either a low molecular compound or a high molecular compound can be used for the light-receiving element, and an inorganic compound may be included. Each of the layers included in the light-receiving element can be formed by an evaporation method (including a vacuum evaporation method), a transfer method, a printing method, an inkjet method, a coating method, or the like.

The display device 50D illustrated in FIG. 44B and FIG. 44C includes, between the substrate 151 and the substrate 152, a layer 353 including a light-receiving element, a circuit layer 355, and a layer 357 including light-emitting elements.

The layer 353 includes the light-receiving element 130S, for example. The layer 357 includes the light-emitting elements 130R, 130G, and 130B, for example.

The functional layer 355 includes a circuit for driving the light-receiving element and a circuit for driving the light-emitting element. The circuit layer 355 includes the transistors 205R, 205G, and 205B, for example. One or more of a switch, a capacitor, a resistor, a wiring, a terminal, and the like can be provided in the circuit layer 355.

FIG. 44B illustrates an example where the light-receiving element 130S is used as a touch sensor. Light emitted from the light-emitting element in the layer 357 is reflected by a finger 352 that touches the display device 50D as illustrated in FIG. 44B, and the light-receiving element in the layer 353 detects the reflected light. Thus, the touch of the finger 352 on the display device 50D can be detected.

FIG. 44C is an example where the light-receiving element 130S is used as a contactless sensor. Light emitted from the light-emitting element in the layer 357 is reflected by the finger 352 that is approaching (i.e., that is not in contact with) the display device 50D as illustrated in FIG. 44C, and the light-receiving element in the layer 353 detects the reflected light.

### Structure Example 5 of Display Device

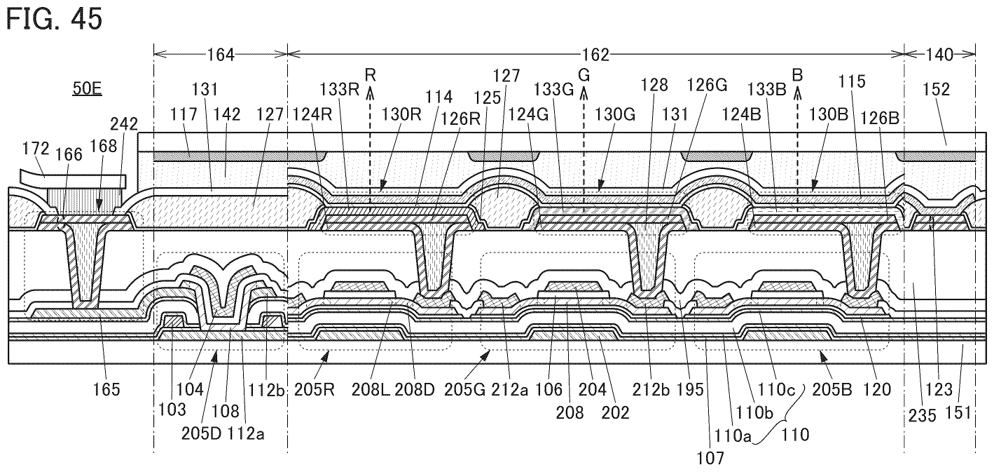

A display device 50E illustrated in FIG. 45 is an example of a display device having an MML (metal maskless) structure. In other words, the display device 50E includes a light-emitting element that is formed without using a fine metal mask. The stacked-layer structure from the substrate 151 to the insulating layer 235 and the stacked-layer structure from the protective layer 131 to the substrate 152 are similar to those in the display device 50A: thus, the description thereof is omitted.

In FIG. 45, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 45 emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 45 emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 45 emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. Note that in this specification and the like, the layer 133R, the layer 133G, and the layer 133B are sometimes referred to as island-shaped EL layers, EL layers formed in an island shape, or the like, in which case the common layer 114 is not included.

The layer 133R, the layer 133G, and the layer 133B are separated from one another. When the EL layer is provided to have an island shape for each light-emitting element, a leakage current between adjacent light-emitting elements can be inhibited. This can prevent unintended light emission due to crosstalk, so that a display device with extremely high contrast can be obtained.

Although the layers 133R, 133G, and 133B have the same thickness in FIG. 45, the present invention is not limited thereto. The layers 133R, 133G, and 133B may have different thicknesses.

The conductive layer 124R is electrically connected to the conductive layer 112b included in the transistor 205R through an opening provided in the insulating layer 195 and the insulating layer 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressed portions of the conductive layers 124R, 124G, and 124B.

The layer 128 has a planarization function for the depressed portions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressed portions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 45 illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle less than 90°. In the case where the end portion of the pixel electrode has a tapered shape, the layer 133R provided along the side surface of the pixel electrode has a tapered shape. When the side surface of the pixel electrode has a tapered shape, coverage with an EL layer provided along the side surface of the pixel electrode can be favorable.

Since the conductive layers 124G and 126G and the conductive layers 124B and 126B are similar to the conductive layers 124R and 126R, the detailed description thereof is omitted.

The top surface and the side surface of the conductive layer 126R are covered with the layer 133R. Similarly, top surface and the side surface of the conductive layers 126G are covered with the layer 133G, and the top surface and the side surface of the conductive layers 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layer 133R, the layer 133G, and the layer 133B are covered with the insulating layers 125 and 127. The common layer 114 is provided over the layer 133R, the layer 133G, and the layer 133B and the insulating layers 125 and 127, and the common electrode 115 is provided over the common layer 114. The common layer 114 and the common electrode 115 are each a continuous film shared by a plurality of light-emitting elements.

In FIG. 45, the insulating layer 237 illustrated in FIG. 41 or the like is not provided between the conductive layer 126R and the layer 133R. That is, an insulating layer (also referred to as a partition wall, a bank, a spacer, or the like) in contact with the pixel electrode and covering an upper end portion of the pixel electrode is not provided in the display device 50E. Thus, the distance between adjacent light-emitting elements can be extremely narrowed. Accordingly, the display device can have high resolution or high definition. In addition, a mask for forming the insulating layer is not needed, which leads to a reduction in manufacturing cost of the display device.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display device of one embodiment of the present invention, the step can be reduced with the insulating layer 125 and the insulating layer 127, and the coverage with the common layer 114 and the common electrode 115 can be improved. Thus, connection defects caused by step disconnection can be inhibited. Alternatively, an increase in electrical resistance caused by local thinning of the common electrode 115 due to level difference can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a convex shape with a large radius of curvature.

The insulating layer 125 can be an insulating layer including an inorganic material. For the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer or a gettering function, entry of impurities (typically, at least one of water and oxygen) that might diffuse into the light-emitting elements from the outside can be inhibited. With this structure, a highly reliable light-emitting element and a highly reliable display device can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 115.

As the insulating layer 127, an insulating layer containing an organic material can be favorably used. As the organic material, a photosensitive organic resin is preferably used, and for example, a photosensitive resin composite including an acrylic resin is preferably used. Note that in this specification and the like, an acrylic resin refers to not only a polymethacrylic acid ester or a methacrylic resin, but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used, for example. Examples of organic materials used for the insulating layer 127 include polyvinyl alcohol (PVA), polyvinyl butyral, polyvinyl pyrrolidone, polyethylene glycol, polyglycerin, pullulan, water-soluble cellulose, and an alcohol-soluble polyamide resin. A photoresist may be used for the photosensitive resin. As the photosensitive organic resin, either a positive material or a negative material may be used.

For the insulating layer 127, a material absorbing visible light may be used. When the insulating layer 127 absorbs light emitted from the light-emitting element, leakage of light (stray light) from the light-emitting element to an adjacent light-emitting element through the insulating layer 127 can be inhibited. Thus, the display quality of the display device can be improved. Furthermore, since the display quality can be increased even when a polarizing plate is not used in the display device, a lightweight and thin display device can be achieved.

Examples of the material absorbing visible light include materials including pigment of black or the like, materials including dye, light-absorbing resin materials (e.g., polyimide), and resin materials that can be used for color filters (color filter materials). Using a resin material obtained by stacking or mixing color filter materials of two colors or three or more colors is particularly preferable, in which case the effect of blocking visible light can be enhanced. In particular, mixing color filter materials of three or more colors enables the formation of a black or nearly black resin layer.

### Structure Example 6 of Display Device

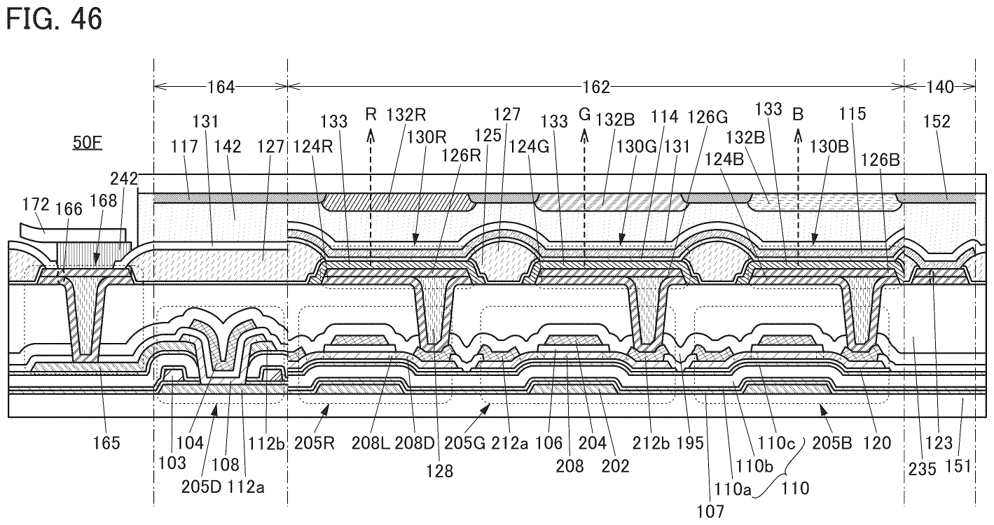

A display device 50F illustrated in FIG. 46 is different from the display device 50E mainly in that the subpixels of different colors are provided with coloring layers (color filters or the like).

In the display device 50F illustrated in FIG. 46, the transistors 205D, 205R, 205G, and 205B, the light-emitting elements 130R, 130G, and 130B, the coloring layer 132R transmitting red light, the coloring layer 132G transmitting green light, the coloring layer 132B transmitting blue light, and the like are provided between the substrate 151 and the substrate 152.

Light emitted from the light-emitting element 130R is extracted as red light to the outside of the display device 50F through the coloring layer 132R. Similarly, light emitted from the light-emitting element 130G is extracted as green light to the outside of the display device 50F through the coloring layer 132G. Light emitted from the light-emitting element 130B is extracted as blue light to the outside of the display device 50F through the coloring layer 132B.

The light-emitting elements 130R, 130G, and 130B each include the layer 133. The three layers 133 are formed using the same process and the same material. The three layers 133 are separated from each other. When the EL layer is provided to have an island shape for each light-emitting element, a leakage current between adjacent light-emitting elements can be inhibited. This can prevent unintended light emission due to crosstalk, so that a display device with extremely high contrast can be obtained.

The light-emitting elements 130R, 130G, and 130B illustrated in FIG. 46 emit white light, for example. When white light emitted from the light-emitting elements 130R, 130G, and 130B passes through the coloring layers 132R, 132G, and 132B, light of desired colors can be obtained.

Alternatively, the light-emitting elements 130R, 130G, and 130B illustrated in FIG. 46 emit blue light, for example. In this case, the layer 133 includes one or more light-emitting layers that emit blue light. In the pixel 230B that emits blue light, blue light emitted from the light-emitting element 130B can be extracted. In each of the pixel 230R that emits red light and the pixel 230G that emits green light, a color conversion layer is provided between the light-emitting element 130R or the light-emitting element 130G and the substrate 152 so that blue light emitted from the light-emitting element 130R or 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the intended color can be absorbed by the coloring layer, and color purity of light exhibited by a subpixel can be improved.

### Structure Example 7 of Display Device

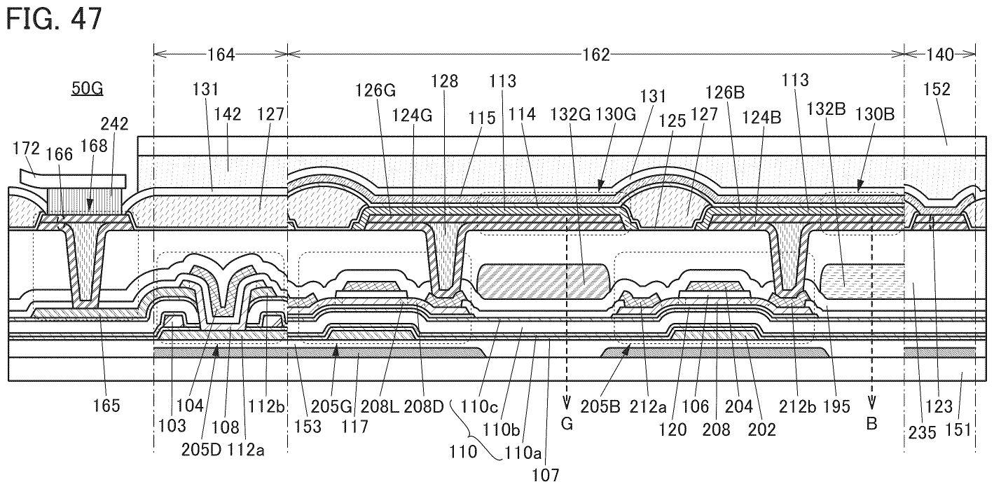

A display device 50G illustrated in FIG. 47 is different from the display device 50F mainly in having a bottom-emission structure.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 47 illustrates an example where the light-blocking layers 117 are provided over the substrate 151, the insulating layer 153 is provided over the light-blocking layers 117, and the transistor 205D, the transistor 205R (not illustrated), the transistor 205G, and the transistor 205B and the like are provided over the insulating layer 153. In addition, the coloring layer 132R (not illustrated), the coloring layer 132G, and the coloring layer 132B are provided over the insulating layer 195, and the insulating layer 235 is provided over the coloring layer 132R (not illustrated), the coloring layer 132G, and the coloring layer 132B.

The light-emitting element 130G overlapping with the coloring layer 132G includes the conductive layer 124G, the conductive layer 126G, the EL layer 113, the common layer 114, and the common electrode 115.

The light-emitting element 130B overlapping with the coloring layer 132B includes the conductive layer 124B, the conductive layer 126B, the EL layer 113, the common layer 114, and the common electrode 115.

A material having a high visible-light-transmitting property is used for each of the conductive layers 124G, 124B, 126G, and 126B. A material reflecting visible light is preferably used for the common electrode 115. In the display device having a bottom-emission structure, a metal or the like having low resistivity can be used for the common electrode 115; thus, a voltage drop due to the electric resistance of the common electrode 115 can be inhibited and a high display quality can be achieved.

The transistor of one embodiment of the present invention can be miniaturized and the area occupied by the transistor can be reduced, so that the aperture ratio of the pixel can be increased or the pixel size can be reduced in the display device having a bottom-emission structure.

### Manufacturing Method Example of Display Device

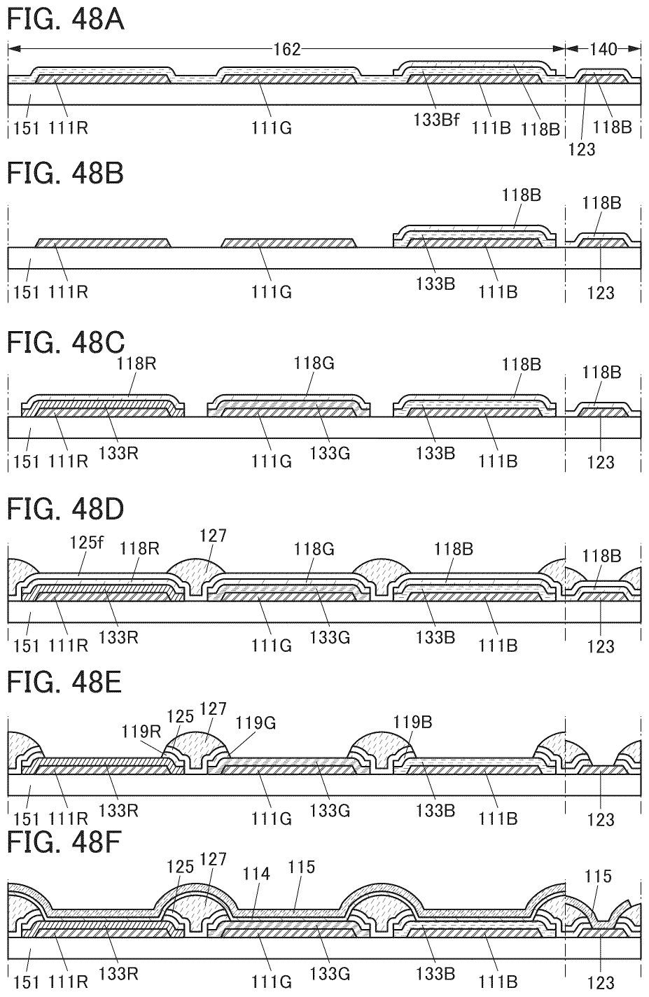

A method for manufacturing a display device having an MML (metal maskless) structure will be described below with reference to FIG. 48. Here, steps of manufacturing light-emitting elements without using a fine metal mask will be described in detail. In FIG. 48, cross-sectional views of three light-emitting elements included in the display portion 162 and the connection portion 140 in the manufacturing steps are illustrated.

For manufacture of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure method, or a micro-contact printing method).

In the method described below for manufacturing the display device, the island-shaped layer (the layer including the light-emitting layer) is formed not by using a fine metal mask but by forming a light-emitting layer on the entire surface and then processing the light-emitting layer by a photolithography method. Accordingly, a high-resolution display device or a display device with a high aperture ratio, which has been difficult to achieve, can be manufactured. Moreover, light-emitting layers can be formed separately for the respective colors, enabling the display device to perform extremely clear display with high contrast and high display quality. In addition, a sacrificial layer provided over a light-emitting layer can reduce damage to the light-emitting layer in the manufacturing process of the display device, increasing the reliability of the light-emitting element.

For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by forming a light-emitting layer and performing processing three times by photolithography. First, the pixel electrodes 111R, 111G, and 111B and the conductive layer 123 are formed over the substrate 151 provided with the transistors 205R, 205G, and 205B and the like (not illustrated) (FIG. 48A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. For the processing of the conductive film, one or both of a wet etching method and a dry etching method can be used.

Next, a film 133Bf to be the layer 133B later is formed over the pixel electrodes 111R, 111G, and 111B (FIG. 48A). The film 133Bf (to be the layer 133B later) includes a light-emitting layer that emits blue light.

Note that in an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding step.

In this case, the driving voltage of the light-emitting element of the color formed second or later might be high.

In view of this, in manufacture of the display device of one embodiment of the present invention, it is preferable that an island-shaped EL layer of a light-emitting element that emits light with the shortest wavelength (e.g., the blue-light-emitting element) be formed first. For example, it is preferable that island-shaped EL layers be formed in the order of blue, green, and red or in the order of blue, red, and green.

This enables the blue-light-emitting element to keep the favorable state of the interface between the pixel electrode and the EL layer and to be inhibited from having an increased driving voltage. Furthermore, the lifetime of the blue-light-emitting element can be prolonged and the reliability can be increased. Note that the red-light-emitting element and the green-light-emitting element have a smaller increase in driving voltage or the like than the blue-light-emitting element, resulting in a lower driving voltage and higher reliability of the whole display device.

Note that the formation order of the island-shaped EL layers is not limited to the above; for example, the island-shaped EL layers may be formed in the order of red, green, and blue.

As illustrated in FIG. 48A, the film 133Bf is not formed over the conductive layer 123. For example, by using an area mask, the film 133Bf can be formed only in a desired region. Employing a film formation step using an area mask and a processing step using a resist mask enables a light-emitting element to be manufactured by a relatively easy process.

The upper temperature limit of the compounds contained in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display device can be increased. Thus, the range of choices of the materials and the formation method of the display device can be widened, thereby improving the yield and the reliability.

The upper temperature limit, for example, can be any of the glass transition point, the softening point, the melting point, the thermal decomposition temperature, and the 5% weight loss temperature, preferably the lowest temperature thereof.

The film 133Bf can be formed by an evaporation method, specifically a vacuum evaporation method, for example. Alternatively, the film 133Bf may be formed by a transfer method, a printing method, an inkjet method, a coating method, or the like.

Next, a sacrificial layer 118B is formed over the film 133Bf and the conductive layer 123 (FIG. 48A). A resist mask is formed over a film to be the sacrificial layer 118B by a photolithography process, and then the film is processed, whereby the sacrificial layer 118B can be formed.

The sacrificial layer 118B provided over the film 133Bf can reduce damage to the film 133Bf in the manufacturing process of the display device, increasing the reliability of the light-emitting element.

The sacrificial layer 118B is preferably provided to cover the end portions of the pixel electrodes 111R, 111G, and 111B. Accordingly, an end portion of the layer 133B formed in a later step is positioned outward from the end portion of the pixel electrode 111B. The entire top surface of the pixel electrode 111B can be used as a light-emitting region, so that the aperture ratio of the pixel can be increased. The end portion of the layer 133B might be damaged in a step after the formation of the layer 133B, and thus is preferably positioned outward from the end portion of the pixel electrode 111B, i.e., not used as the light-emitting region. This can inhibit a variation in the characteristics of the light-emitting elements and can improve reliability.

When the layer 133B covers the top surface and the side surface of the pixel electrode 111B, the steps after the formation of the layer 133B can be performed in a state where the pixel electrode 111B is not exposed. When the end portion of the pixel electrode 111B is exposed, corrosion might occur in the etching step or the like. When corrosion of the pixel electrode 111B is inhibited, the yield and characteristics of the light-emitting element can be improved. The sacrificial layer 118B is preferably provided also at a position overlapping with the conductive layer 123. This can inhibit the conductive layer 123 from being damaged during the manufacturing process of the display device.

As the sacrificial layer 118B, a film that is highly resistant to the process conditions for the film 133Bf, specifically, a film having high etching selectivity with respect to the film 133Bf is used.

The sacrificial layer 118B is formed at a temperature lower than the upper temperature limit of each compound included in the film 133Bf. The typical substrate temperature in the formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The upper temperature limit of the compound included in the film 133Bf is preferably high, in which case the film formation temperature of the sacrificial layer 118B can be high. For example, the substrate temperature in formation of the sacrificial layer 118B can be higher than or equal to 100° C., higher than or equal to 120° C., or higher than or equal to 140° C. An inorganic insulating film can have higher density and a higher barrier property as the film formation temperature becomes higher. Thus, forming the sacrificial layer at such a temperature can further reduce damage to the film 133Bf and improve the reliability of the light-emitting element.

Note that the same can be applied to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the aforementioned wet film formation method may be used for the formation.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

The use of a wet etching method can reduce damage to the film 133Bf in processing of the sacrificial layer 118B, as compared with the case of employing a dry etching method. In the case of employing a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

As the sacrificial layer 118B, one or more kinds of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

For the sacrificial layer 118B, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more kinds selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with a high affinity for the semiconductor manufacturing process. Alternatively, an oxide or a nitride of the semiconductor material can be used. Alternatively, a non-metal material such as carbon or a compound thereof can be used. Alternatively, a metal, such as titanium, tantalum, tungsten, chromium, or aluminum, or an alloy containing one or more of them can be given. Alternatively, an oxide containing the above-described metal, such as titanium oxide or chromium oxide, or a nitride such as titanium nitride, chromium nitride, or tantalum nitride can be used.

As the sacrificial layer 118B, a variety of inorganic insulating films that can be used as the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. As the sacrificial layer 118B, an aluminum oxide film can be formed by an ALD method, for example. The use of an ALD method is preferable because damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used for both the sacrificial layer 118B and the insulating layer 125. Here, for the sacrificial layer 118B and the insulating layer 125, the same film-formation condition may be used or different film-formation conditions may be used. For example, when the sacrificial layer 118B is formed under conditions similar to those of the insulating layer 125, the sacrificial layer 118B can be an insulating layer having a high barrier property against at least one of water and oxygen. Meanwhile, the sacrificial layer 118B is a layer most or all of which is to be removed in a later step, and thus is preferably easy to process. Thus, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer.

For example, a stacked-layer structure of an organic film (e.g., a PVA film) formed by an evaporation method or any of the above-described wet film formation methods and an inorganic film (e.g., a silicon nitride film) formed by a sputtering method can be employed for the sacrificial layer 118B.

Note that in the display device of one embodiment of the present invention, part of the sacrificial film remains as the sacrificial layer in some cases.

Then, the film 133Bf is processed using the sacrificial layer 118B as a hard mask, so that the layer 133B is formed (FIG. 48B).

Accordingly, as illustrated in FIG. 48B, the stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching may be employed.

After that, steps similar to the formation step of the film 133Bf, the formation step of the sacrificial layer 118B, and the formation step of the layer 133B are repeated twice under the condition where at least light-emitting materials are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 48C). Specifically, the layer 133R and the layer 133G are formed to include a light-emitting layer that emits red light and a light-emitting layer that emits green light, respectively. The sacrificial layers 118R and 118G can be formed using a material that can be used for the sacrificial layer 118B, and the sacrificial layers 118R and 118G may be formed using the same material or different materials.

Note that the side surfaces of the layer 133B, the layer 133G, and the layer 133R are preferably perpendicular or substantially perpendicular to their formation surfaces. For example, the angle between the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between opposite end portions of two adjacent layers among the layer 133B, the layer 133G, and the layer 133R. When the distance between the island-shaped EL layers is shortened in this manner, a display device with a high resolution and a high aperture ratio can be provided.

Next, the insulating film 125f to be the insulating layer 125 later is formed to cover the pixel electrodes, the layer 133B, the layer 133G, the layer 133R, the sacrificial layer 118B, the sacrificial layer 118G, and the sacrificial layer 118R, and then the insulating layer 127 is formed over the insulating film 125f (FIG. 48D).

As the insulating film 125f, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. An ALD method is preferably used, in which case damage due to the film formation can be reduced and a film with high coverage can be formed. As the insulating film 125f, an aluminum oxide film is preferably formed by an ALD method, for example.

Alternatively, the insulating film 125f may be formed by a sputtering method, a CVD method, or a PECVD method that provides a higher film formation speed than an ALD method. In this case, a highly reliable display device can be manufactured with high productivity.

For example, the insulating film to be the insulating layer 127 is preferably formed by the aforementioned wet film formation method (e.g., spin coating) using a photosensitive resin composite containing an acrylic resin. After the formation, heat treatment (also referred to as pre-baking) is preferably performed to eliminate a solvent contained in the insulating film. Next, part of the insulating film is irradiated with visible light or ultraviolet rays, so that the insulating film is partly exposed to light. Subsequently, the region of the insulating film exposed to light is removed by development. After that, heat treatment (also referred to as post-baking) is performed. Accordingly, the insulating layer 127 illustrated in FIG. 48D can be formed. Note that the shape of the insulating layer 127 is not limited to the shape illustrated in FIG. 48D. For example, the top surface of the insulating layer 127 can include one or more of a convex surface, a concave surface, and a flat surface. The insulating layer 127 may cover the side surface of an end portion of at least one of the insulating layer 125, the sacrificial layer 118B, the sacrificial layer 118G, and the sacrificial layer 118R.

Next, as illustrated in FIG. 48E, etching treatment is performed using the insulating layer 127 as a mask to remove the insulating film 125f and parts of the sacrificial layers 118B, 118G, and 118R. Consequently, openings are formed in the sacrificial layers 118B, 118G, and 118R, and the top surfaces of the layer 133B, the layer 133G, the layer 133R, and the conductive layer 123 are exposed. Note that parts of the sacrificial layers 118B, 118G, and 118R may remain in positions overlapping with the insulating layer 127 and the insulating layer 125 (see sacrificial layers 119B, 119G, and 119R).

The etching treatment can be performed by dry etching or wet etching. Note that the insulating film 125f is preferably formed using a material similar to that for the sacrificial layers 118B, 118G, and 118R, in which case etching treatment can be performed collectively.

As described above, providing the insulating layer 127, the insulating layer 125, the sacrificial layer 118B, the sacrificial layer 118G, and the sacrificial layer 118R can inhibit the common layer 114 and the common electrode 115 between the light-emitting elements from having connection defects due to a disconnected portion and an increase in electric resistance due to a locally thinned portion. Thus, the display quality of the display device of one embodiment of the present invention can be improved.

Next, the common layer 114 and the common electrode 115 are formed in this order over the insulating layer 127, the layer 133B, the layer 133G, and the layer 133R (FIG. 48F).

The common layer 114 can be formed by a method such as an evaporation method (including a vacuum evaporation method), a transfer method, a printing method, an inkjet method, or a coating method.

The common electrode 115 can be formed by a sputtering method or a vacuum evaporation method, for example. Alternatively, a film formed by an evaporation method and a film formed by a sputtering method may be stacked.

As described above, in the method for manufacturing the display device of one embodiment of the present invention, the island-shaped layer 133B, the island-shaped layer 133G, and the island-shaped layer 133R are formed not by using a fine metal mask but by forming a film over the entire surface and processing the film: thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the layer 133B, the layer 133G, and the layer 133R can be inhibited from being in contact with each other in the adjacent subpixels. Accordingly, generation of a leakage current between the subpixels can be inhibited. This can prevent unintended light emission due to crosstalk, so that a display device with extremely high contrast can be obtained.

Provision of the insulating layer 127 having a tapered end portion between adjacent island-shaped EL layers can inhibit formation of step disconnection and prevent formation of a locally thinned portion in the common electrode 115 at the time of forming the common electrode 115. This can inhibit the common layer 114 and the common electrode 115 from having connection defects due to the disconnected portion and an increased electric resistance due to the locally thinned portion. Thus, the display device of one embodiment of the present invention can have both a higher resolution and higher display quality.

This embodiment can be combined with the other embodiments as appropriate.

### Embodiment 4

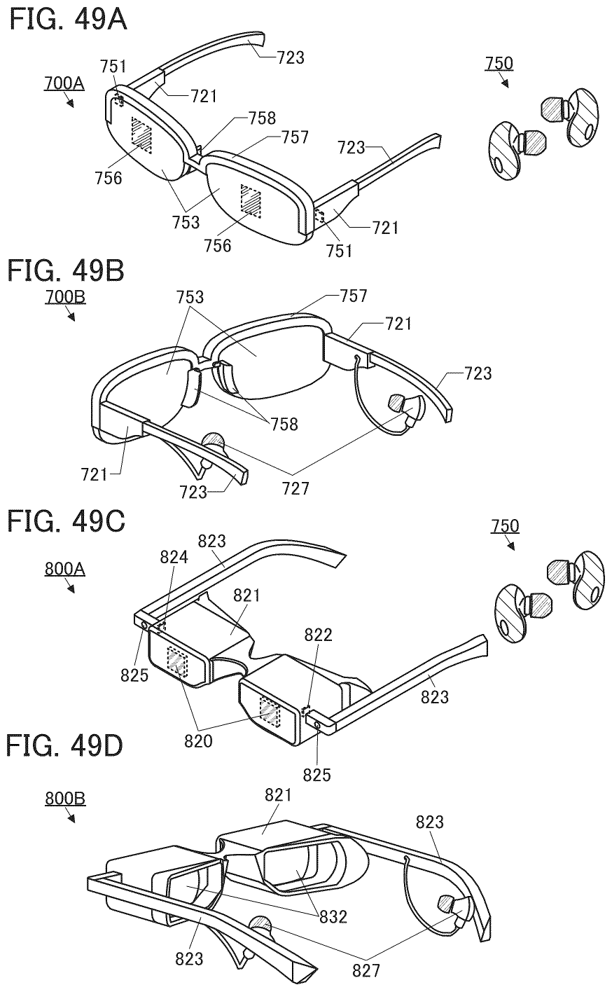

In this embodiment, electronic devices of one embodiment of the present invention will be described with reference to FIG. 49 to FIG. 51.

Electronic devices in this embodiment each include the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop computer, a monitor of a computer or the like, digital signage, and a large game machine such as a pachinko machine.

In particular, the display device of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840× 2160), or 8K (number of pixels: 7680×4320). In particular, the definition is preferably 4K, 8K, or higher. The pixel density (resolution) of the display device of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head are described with reference to FIG. 49A to FIG. 49D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 49A and an electronic device 700B illustrated in FIG. 49B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery (not illustrated) so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 49C and an electronic device 800B illustrated in FIG. 49D each include a pair of display portions 820, a housing 821, a communication portion 822, a pair of wearing portions 823, a control portion 824, a pair of image capturing portions 825, and a pair of lenses 832. Note that the display portions 820, the communication portion 822, and the image capturing portions 825 are omitted in FIG. 49D.

The display device of one embodiment of the present invention can be used for the display portions 820. Thus, the electronic device can perform display with extremely high resolution. This enables a user to feel high sense of immersion.

The display portions 820 are provided at a position inside the housing 821 so as to be seen through the lenses 832. When the pair of the display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 49C and the like illustrate examples where the wearing portion has a shape like a temple of glasses: however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring the distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 49A has a function of transmitting information to the earphones 750 with the wireless communication function. As another example, the electronic device 800A illustrated in FIG. 49C has a function of transmitting information to the earphones 750 with the wireless communication function.

The electronic device may include an earphone portion. The electronic device 700B illustrated in FIG. 49B includes earphone portions 727. For example, the earphone portion 727 and the control portion can be connected to each other by wire. Part of a wiring that connects the earphone portion 727 and the control portion may be placed inside the housing 721 or the wearing portion 723.

Similarly, the electronic device 800B illustrated in FIG. 49D includes earphone portions 827. For example, the earphone portion 827 and the control portion 824 can be connected to each other by wire. Part of a wiring that connects the earphone portion 827 and the control portion 824 may be placed inside the housing 821 or the wearing portion 823. The earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

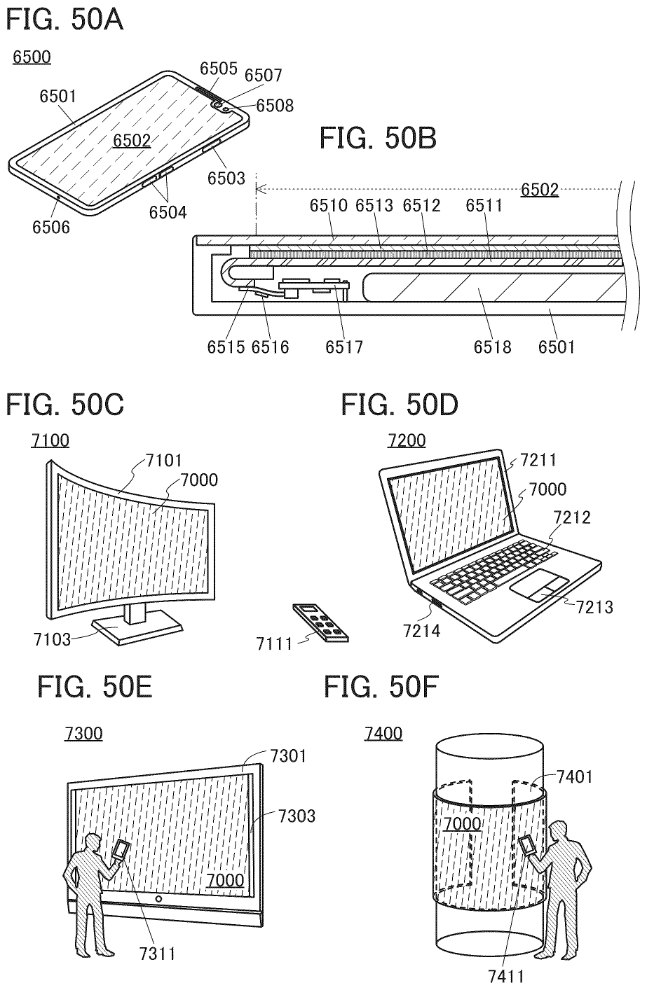

An electronic device 6500 illustrated in FIG. 50A is a portable information terminal that can be used as a smartphone.

The electronic device 6500 includes a housing 6501, a display portion 6502, a power button 6503, buttons 6504, a speaker 6505, a microphone 6506, a camera 6507, and a light source 6508. The display portion 6502 has a touch panel function.

The display device of one embodiment of the present invention can be used for the display portion 6502.

FIG. 50B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while an increase in thickness of the electronic device is suppressed. Moreover, part of the display panel 6511 is folded back so that a connection portion with the FPC 6515 is placed on the back side of the pixel portion, whereby an electronic device with a narrow bezel can be achieved.

FIG. 50C illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used for the display portion 7000.

Operation of the television device 7100 illustrated in FIG. 50C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 50D illustrates an example of a laptop computer. A laptop computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000.

FIG. 50E and FIG. 50F illustrate examples of digital signage.

Digital signage 7300 illustrated in FIG. 50E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 50F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in FIG. 50E and FIG. 50F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 50E and FIG. 50F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

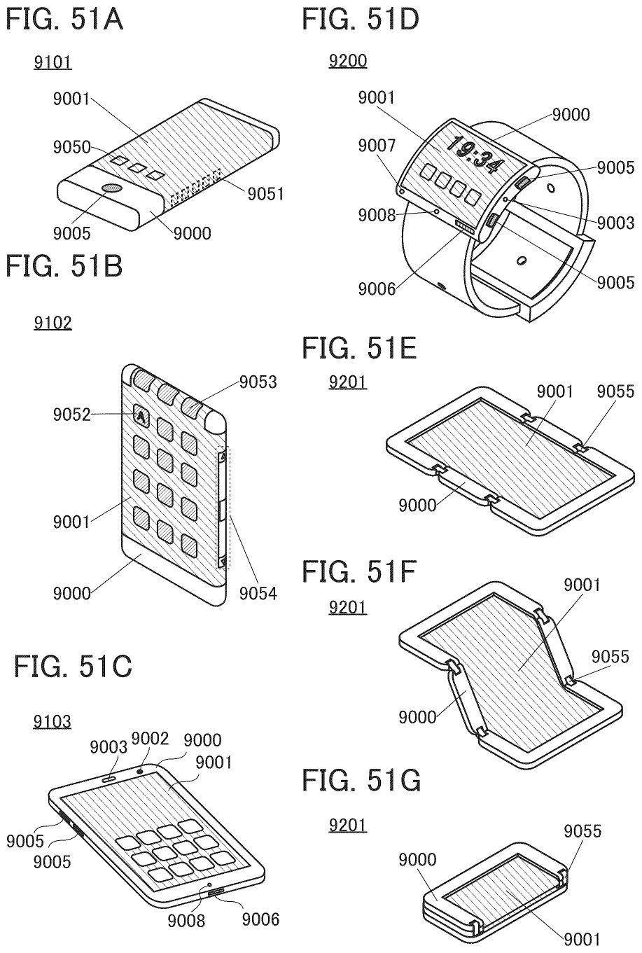

Electronic devices illustrated in FIG. 51A to FIG. 51G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display device of one embodiment of the present invention can be used for the display portion 9001 in FIG. 51A to FIG. 51G.

The electronic devices illustrated in FIG. 51A to FIG. 51G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices illustrated in FIG. 51A to FIG. 51G are described in detail below:

FIG. 51A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 51A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 51B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 51C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000: the operation keys 9005 as buttons for operation on the side surface of the housing 9000; and the connection terminal 9006 on the bottom surface of the housing 9000.

FIG. 51D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 51E to FIG. 51G are perspective views illustrating a foldable portable information terminal 9201. FIG. 51E is a perspective view of an opened state of the portable information terminal 9201, FIG. 51G is a perspective view of a folded state thereof, and FIG. 51F is a perspective view of a state in the middle of change from one of FIG. 51E and FIG. 51G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

10A: semiconductor device, 10B: semiconductor device, 10C: semiconductor device, 10D: semiconductor device, 10E: semiconductor device, 10F: semiconductor device, 10G: semiconductor device, 10H: semiconductor device, 10J: semiconductor device, 10: semiconductor device, 50A: display device, 50B: display device, 50C: display device, 50D: display device, 50E: display device, 50F: display device, 50G: display device, 51A: pixel circuit, 51: pixel circuit, 52A: transistor, 52B: transistor, 52C: transistor, 53: capacitor, 61: light-emitting device, 100A: transistor, 100B: transistor, 100C: transistor, 100D: transistor, 100E: transistor, 100F: transistor, 100G: transistor, 100H: transistor, 100J: transistor, 100K: transistor, 100: transistor, 102: substrate, 103a: conductive layer, 103: conductive layer, 104f: conductive film, 104: conductive layer, 106a: insulating layer, 106b: insulating layer, 106f: insulating film, 106: insulating layer, 107f: insulating film, 107: insulating layer, 108D: region, 108f: metal oxide film, 108L: region, 108: semiconductor layer, 110a: insulating layer, 110af: insulating film, 110b: insulating layer, 110bf: insulating film, 110c: insulating layer, 110cf: insulating film, 110: insulating layer, 111B: pixel electrode, 111G: pixel electrode, 111R: pixel electrode, 111S: pixel electrode, 111: pixel electrode, 112a: conductive layer, 112B: conductive layer, 112b: conductive layer, 112bf: conductive film, 113B: EL layer, 113G: EL layer, 113R: EL layer, 113S: functional layer, 113: EL layer, 114: common laver, 115: common electrode, 117: light-blocking layer, 118B: sacrificial layer, 118G: sacrificial layer, 118R: sacrificial layer, 119B: sacrificial layer, 119G: sacrificial layer, 119R: sacrificial layer, 120a: insulating layer, 120b: insulating layer, 120f: insulating film, 120: insulating layer, 123: conductive layer, 124B: conductive layer, 124G: conductive layer, 124R: conductive layer, 125f: insulating film, 125: insulating layer, 126B: conductive layer, 126G: conductive layer, 126R: conductive layer, 127: insulating layer, 128: layer, 130B: light-emitting element, 130G: light-emitting element, 130R: light-emitting element, 130S: light-receiving element, 131: protective layer, 132B: coloring layer, 132G: coloring layer, 132R: coloring layer, 133B: layer, 133Bf: film, 133G: layer, 133R: layer, 133: layer, 135: opening, 138: opening, 139: opening, 140: connection portion, 141: opening, 142: adhesive layer, 143: opening, 144: opening, 146: opening, 147a: opening, 147b: opening, 148: opening, 149: opening, 151: substrate, 152: substrate, 153: insulating layer, 155a: mask layer, 155af: mask film, 155b: mask layer, 155bf: mask film, 157a: resist mask, 157b: resist mask, 162: display portion, 164: peripheral circuit portion, 165: wiring, 166:30) conductive layer, 168: connection portion, 172: FPC, 173: IC, 180: metal oxide layer, 195f: insulating film, 195: insulating layer, 197: insulating layer, 200A: transistor, 200B: transistor, 200C: transistor, 200D: transistor, 200E: transistor, 200F: transistor, 200G: transistor, 200H: transistor, 200: transistor, 202: conductive layer, 204: conductive layer, 205B: transistor, 205D: transistor, 205G: transistor, 205R: transistor, 205S: transistor, 208D: region, 208f: metal oxide film, 208L: region, 208: semiconductor layer, 210: pixel, 212a: conductive layer, 212b: conductive layer, 230B: pixel, 230G: pixel, 230R: pixel, 230: pixel, 231: first driver circuit portion, 232: second driver circuit portion, 235: insulating layer, 236: wiring, 237: insulating layer, 238: wiring, 242: connection layer, 352: finger, 353: layer, 355: circuit layer, 357: layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1-2. (canceled)

3. A semiconductor device comprising:
a first transistor;
a second transistor; and
a substrate,
the first transistor comprising:
a first conductive layer over the substrate;
a first insulating layer over the first conductive layer;
a second conductive layer over the first insulating layer;
a second insulating layer over the second conductive layer;
a third conductive layer over the second insulating layer; and
a first semiconductor layer,
the second transistor comprising:
a fourth conductive layer over the substrate;
the first insulating layer over the fourth conductive layer;
the second insulating layer over the first insulating layer;
a third insulating layer over the second insulating layer; and
a second semiconductor layer over the third insulating layer,
wherein the second conductive layer comprises a first opening reaching the first insulating layer in a region overlapping with the first conductive layer,
wherein the second insulating layer is in contact with a top surface and a side surface of the second conductive layer and a top surface of the first insulating layer,
wherein the first insulating layer, the second insulating layer, and the third conductive layer comprise a second opening reaching the first conductive layer in a region overlapping with the first opening,
wherein in the second opening, the first semiconductor layer is in contact with a top surface of the first conductive layer, a side surface of the first insulating layer, a side surface of the second insulating layer, and a top surface and a side surface of the third conductive layer, and
wherein the second semiconductor layer comprises a region overlapping with the fourth conductive layer with the first insulating layer, the second insulating layer, and the third insulating layer therebetween.

4. The semiconductor device according to claim 3,
wherein the first conductive layer and the fourth conductive layer comprise the same material.

5. A semiconductor device comprising:
a first transistor;
a second transistor; and
a substrate,
the first transistor comprising:
a first conductive layer over the substrate;
a first insulating layer over the first conductive layer;
a second conductive layer over the first insulating layer;
a second insulating layer over the second conductive layer;
a third conductive layer over the second insulating layer;
a third insulating layer over the third conductive layer; and
a first semiconductor layer,
the second transistor comprising:
a fourth conductive layer over the substrate;
the first insulating layer over the fourth conductive layer;
the second insulating layer over the first insulating layer;
the third insulating layer over the second insulating layer; and
a second semiconductor layer over the third insulating layer,
wherein the second conductive layer comprises a first opening reaching the first insulating layer in a region overlapping with the first conductive layer,
wherein the second insulating layer is in contact with a top surface and a side surface of the second conductive layer and a top surface of the first insulating layer,
wherein the third insulating layer is in contact with a top surface and a side surface of the third conductive layer and a top surface of the second insulating layer,
wherein the first insulating layer, the second insulating layer, the third conductive layer, and the third insulating layer comprise a second opening reaching the first conductive layer in a region overlapping with the first opening,
wherein in the second opening, the first semiconductor layer is in contact with a top surface of the first conductive layer, a side surface of the first insulating layer, a side surface of the second insulating layer, a side surface of the third conductive layer, and a top surface and a side surface of the third insulating layer, and
wherein the second semiconductor layer comprises a region overlapping with the fourth conductive layer with the first insulating layer, the second insulating layer, and the third insulating layer therebetween.

6. The semiconductor device according to claim 5,
wherein the first conductive layer and the fourth conductive layer comprise the same material.

7. A semiconductor device comprising:
a first transistor;
a second transistor; and
a substrate,
the first transistor comprising:
a first conductive layer over the substrate;
a first insulating layer over the first conductive layer;
a second conductive layer over the first insulating layer;
a second insulating layer over the second conductive layer;
a third conductive layer over the second insulating layer; and
a first semiconductor layer,
the second transistor comprising:
a fourth conductive layer over the first insulating layer;
the second insulating layer over the fourth conductive layer;
a third insulating layer over the second insulating layer; and
a second semiconductor layer over the third insulating layer,
wherein the second conductive layer comprises a first opening reaching the first insulating layer in a region overlapping with the first conductive layer,
wherein the second insulating layer is in contact with a top surface and a side surface of the second conductive layer and a top surface of the first insulating layer,
wherein the first insulating layer, the second insulating layer, and the third conductive layer comprise a second opening reaching the first conductive layer in a region overlapping with the first opening,
wherein in the second opening, the first semiconductor layer is in contact with a top surface of the first conductive layer, a side surface of the first insulating layer, a side surface of the second insulating layer, and a top surface and a side surface of the third conductive layer,
wherein an end portion of the second semiconductor layer is in contact with a top surface of the third insulating layer, and
wherein the second semiconductor layer comprises a region overlapping with the fourth conductive layer with the second insulating layer and the third insulating layer therebetween.

8. The semiconductor device according to claim 7,
wherein the second conductive layer and the fourth conductive layer comprise the same material.

9. The semiconductor device according to claim 3,
wherein conductivity of the second conductive layer is higher than conductivity of the first conductive layer.

10. The semiconductor device according to claim 3,
wherein each of the first semiconductor layer and the second semiconductor layer comprises a metal oxide.

11. The semiconductor device according to claim 3,
wherein the first semiconductor layer and the second semiconductor layer comprise the same material.

12. The semiconductor device according to claim 3,
wherein the first semiconductor layer and the second semiconductor layer comprise different materials from each other.

13. The semiconductor device according to claim 3,
wherein the first transistor comprises a fourth insulating layer and a fifth conductive layer over the fourth insulating layer,
wherein the fifth conductive layer comprises a region overlapping with the first semiconductor layer with the fourth insulating layer therebetween,
wherein the second transistor comprises the fourth insulating layer and a sixth conductive layer over the fourth insulating layer, and
wherein the sixth conductive layer comprises a region overlapping with the second semiconductor layer with the fourth insulating layer therebetween.

14. The semiconductor device according to claim 13,
wherein the fifth conductive layer and the sixth conductive layer comprise the same material.

15. The semiconductor device according to claim 3,
the first transistor further comprising:
a third insulating layer,
wherein the first insulating layer, the second insulating layer, the third insulating layer, and the third conductive layer comprise the second opening reaching the first conductive layer in the region overlapping with the first opening, and
wherein in the second opening, the first semiconductor layer is in contact with the top surface of the first conductive layer, the side surface of the first insulating layer, the side surface of the second insulating layer, a side surface of the third insulating layer, and the top surface and the side surface of the third conductive layer.

16. The semiconductor device according to claim 3,
wherein an end portion of the second semiconductor layer is in contact with a top surface of the third insulating layer.

17. The semiconductor device according to claim 5,
wherein conductivity of the second conductive layer is higher than conductivity of the first conductive layer.

18. The semiconductor device according to claim 5,
wherein each of the first semiconductor layer and the second semiconductor layer comprises a metal oxide.

19. The semiconductor device according to claim 5,
wherein the first semiconductor layer and the second semiconductor layer comprise the same material.

20. The semiconductor device according to claim 5,
wherein the first semiconductor layer and the second semiconductor layer comprise different materials from each other.

21. The semiconductor device according to claim 5,
wherein the first transistor comprises a fourth insulating layer and a fifth conductive layer over the fourth insulating layer,
wherein the fifth conductive layer comprises a region overlapping with the first semiconductor layer with the fourth insulating layer therebetween,
wherein the second transistor comprises the fourth insulating layer and a sixth conductive layer over the fourth insulating layer, and
wherein the sixth conductive layer comprises a region overlapping with the second semiconductor layer with the fourth insulating layer therebetween.

22. The semiconductor device according to claim 21,
wherein the fifth conductive layer and the sixth conductive layer comprise the same material.
